(19) United States
(12) Patent Application Publication
(10) Pub. No.: US 2009/0226822 A1
(43) Pub. Date: Sep. 10, 2009

(54) RECORDING MEDIUM

(75) Inventors: Norikatsu SASAO, Tokyo (JP); Akiko Hirao, Yokohama-shi (JP); Rumiko Hayase, Yokohama-shi (JP); Satoshi Mikoshiba, Yamato-shi (JP); Kazuki Matsumoto, Kawasaki-shi (JP); Takahiro Kamikawa, Kawasaki-shi (JP); Masahiro Kanamaru, Fuchu-shi (JP)

Correspondence Address: Charles N.J. Ruggiero, Esq.;Ohlandt, Greeley, Ruggiero & Perle, L.L.P., 10th Floor, One Landmark Square, Stamford, CT, 06901-2682, US

(73) Assignee: Kabushiki Kaisha Toshiba

(21) Appl. No.: 12/369,573

(22) Filed: Feb. 11, 2009

(30) Foreign Application Priority Data
Mar. 7, 2008 (JP) 2008-057581

(51) Int. Cl. G03F 7/004

(52) U.S. Cl. 430/2

(57) ABSTRACT

A holographic recording medium is provided, which includes a recording layer including a radically polymerizable monomer having an ethylenically unsaturated bond, a photo-acid generator, a photo-radical polymerization initiator, and a polymeric matrix. The polymeric matrix includes a repeating unit expressed by any one of the following chemical formulae.

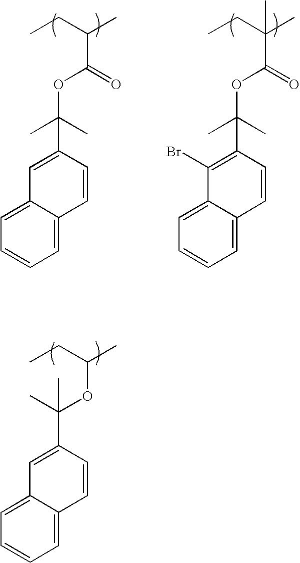

### CROSS-REFERENCE TO RELATED APPLICATIONS

This application is based upon and claims the benefit of priority from prior Japanese Patent Application No. 2008-057581, filed Mar. 7, 2008, the entire contents of which are incorporated herein by reference.

### BACKGROUND OF THE INVENTION

1. Field of the Invention

The present invention relates to a holographic recording medium.

2. Description of the Related Art

Holographic data storage that enables to store data in a form of holography is capable of recording data in high capacity. Therefore, much attention has been paid as the next-generation recording media. As for the photosensitive medium that is capable of recording holograms, radically polymerizable photopolymers are known. The photopolymer is composed mainly of, for example, radically polymerizable monomers, thermoplastic binder resins, photo-initiators, and sensitizing dyes. The photopolymer is formed into a film, which is then exposed under interference pattern. When interference pattern is exposed on to the photopolymer, radical polymerization proceeds in the bright region. At the same time, monomers at the dark regions diffuse to the bright regions to polymerize. As a result, disparities both in terms of density and refractive indices occur. The disparities follow the profile of the interference pattern. JP-A 11-352303 (KOKAI) proposes a medium composed of monomers dispersed in a three-dimensionally crosslinked polymeric matrix.

A medium composed of monomers dispersed in an epoxy matrix is proposed in “Epoxy-Photopolymer Composites: Thick Recording Media for Holographic Data storage”; Proceedings of SPIE, 2001, Vol. 4296, pp 259-266 by T. J. Trentler, J. E. Boid and V. L. Colvin. In these disclosed examples, the precursor of the polymeric matrix is a liquid. The monomers are dissolved in the precursor liquid to give a solution, which is then solidified to form a recording layer of the intended holographic recording medium.

However, according to the conventional method stated above, monomers may not be thoroughly dissolved in the liquid polymeric matrix precursor. It is known that the solubility of monomers in a polymeric matrix has great influence on the performance of the holographic recording medium. The performance will not be satisfactory if the solubility is low. Even if monomers are dissolved in the polymeric matrix precursor, due to the deterioration of miscibility as precursor polymeric matrix polymerize, an uneven dispersion of the monomers in the polymeric matrix could occur. This also leads to a poor performance of the optical recording medium.

### BRIEF SUMMARY OF THE INVENTION

A holographic recording medium according to one aspect of the present invention comprises a recording layer comprising a radically polymerizable monomer having an ethylenically unsaturated bond, a photo-acid generator, a photo-radical polymerization initiator, and polymeric matrix, the polymeric matrix having a repeating unit expressed by the general formula (1) or (2);

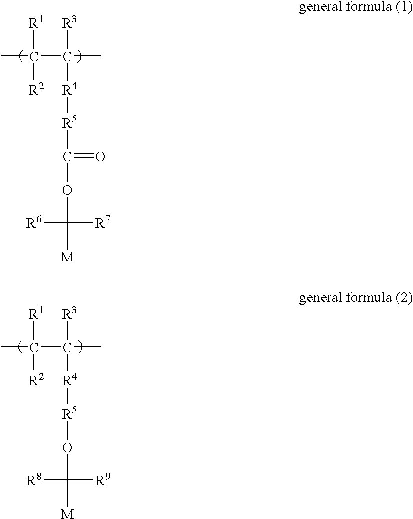

wherein R¹, R², and R³ each include a hydrogen atom or a hydrocarbon group having 10 or less carbon atoms,

R⁴ and R⁵ each include a single bond or a secondary hydrocarbon group having 20 or less carbon atoms,

R⁶ includes a hydrocarbon group having 10 or less carbon atoms, and R⁷ includes a hydrogen atom or a hydrocarbon group having 10 or less carbon atoms,

R⁸ and R⁹ each include a hydrocarbon group having 10 or less carbon atoms, and

M includes an aromatic group.

A holographic recording medium according to another aspect of the present invention comprises a recording layer comprising a radically polymerizable monomer having an ethylenically unsaturated bond, a photo-acid generator, a photo-radical polymerization initiator, and polymeric matrix, the radically polymerizable monomer being selected from the group consisting of unsaturated carboxylic acid, unsaturated carboxylic acid ester, unsaturated carboxylic acid amide, and vinyl compounds, the polymeric matrix having a repeating unit expressed by the general formula (1) or (2);

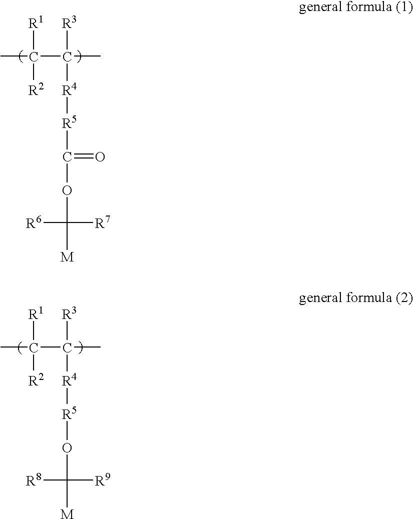

wherein R¹, R², and R³ each include a hydrogen atom or a hydrocarbon group having 10 or less carbon atoms,

R⁴ and R⁵ each include a single bond or a secondary hydrocarbon group having 20 or less carbon atoms,

R⁶ includes a hydrocarbon group having 10 or less carbon atoms, and R⁷ includes a hydrogen atom or a hydrocarbon group having 10 or less carbon atoms,

R⁸ and R⁹ each include a hydrocarbon group having 10 or less carbon atoms, and

M includes an aromatic group.

A holographic recording medium according to another aspect of the present invention comprises a recording layer comprising a radically polymerizable monomer having an ethylenically unsaturated bond, a photo-acid generator, a photo-radical polymerization initiator, and a three-dimensionally crosslinked polymeric matrix, the polymeric matrix having a repeating unit expressed by the general formula (3) and at least one of a repeating unit expressed by the general formula (1) and a repeating unit expressed by the general formula (2);

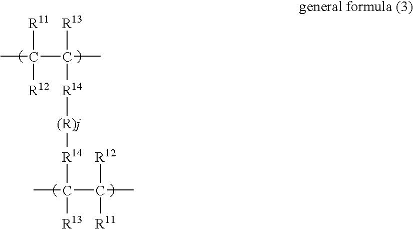

wherein R¹¹, R¹², and R¹³ may be the same or different from each other, and each include a hydrogen atom or a hydrocarbon group having 10 or less carbon atoms; R includes a crosslinking agent containing a crosslinking group, and j represents 0 or 1,

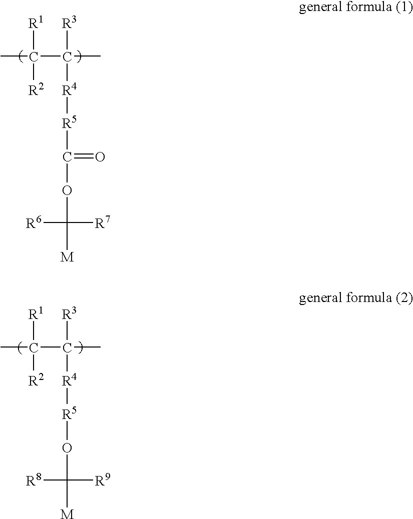

wherein R¹, R², and R³ each include a hydrogen atom or a hydrocarbon group having 10 or less carbon atoms,

R⁴ and R⁵ each include a single bond or a secondary hydrocarbon group having 20 or less carbon atoms,

R⁶ includes a hydrocarbon group having 10 or less carbon atoms, and R⁷ includes a hydrogen atom or a hydrocarbon group having 10 or less carbon atoms,

R⁸ and R⁹ each include a hydrocarbon group having 10 or less carbon atoms, and

M includes an aromatic group.

### BRIEF DESCRIPTION OF THE SEVERAL VIEWS OF THE DRAWING

FIG. 1 is a schematic cross sectional view of a holographic recording medium according to one embodiment;

FIG. 2 is a schematic cross sectional view of a holographic recording medium according to another embodiment;

FIG. 3 is a schematic view of a holographic information recording/reconstructing apparatus according to one embodiment;

FIG. 4 is a schematic view of a holographic information recording/reconstructing apparatus according to another embodiment; and

FIG. 5 is a schematic view of a holographic information recording/reconstructing apparatus according to another embodiment.

### DETAILED DESCRIPTION OF THE INVENTION

Embodiments will be described below.

The recording layer in the holographic recording medium according to one embodiment contains a radically polymerizable monomer having an ethylenically unsaturated bond, a photo-acid generator, photo-radical polymerization initiator, and a polymeric matrix.

Examples of a radically polymerizable monomer having an ethylenically unsaturated bond include unsaturated carboxylic acids, unsaturated carboxylic acid esters, unsaturated carboxylic acid amides, and vinyl compounds.

Specific examples thereof include acrylic acid, methyl acrylate, ethyl acrylate, propyl acrylate, butyl acrylate, isobutyl acrylate, 2-ethylhexyl acrylate, octyl acrylate, lauryl acrylate, stearyl acrylate, cyclohexyl acrylate, bicyclopentenyl acrylate, phenyl acrylate, 2,4,6-tribromophenyl acrylate, isobornyl acrylate, adamantyl acrylate, methacrylic acid, methyl methacrylate, propyl methacrylate, butyl methacrylate, phenyl methacrylate, phenoxyethyl acrylate, chlorophenyl acrylate, adamantyl methacrylate, isobornyl methacrylate, N-methylacrylamide, N,N-dimethylacrylamide, N,N-methylene bisacrylamide, acryloyl morpholine, vinylpyridine, styrene, bromostyrene, chlorostyrene, tribromophenyl acrylate, trichlorophenyl acrylate, tribromophenyl methacrylate, trichlorophenyl methacrylate, vinyl benzoate, 3,5-dichlorovinyl benzoate, vinylnaphthalene, vinylnaphthoate, naphthyl methacrylate, naphthyl acrylate, N-phenyl methacrylamide, N-phenyl acrylamide, N-vinyl pyrrolidinone, N-vinylcarbazole, 1-vinyl imidazole, bicyclopentenyl acrylate, 1,6-hexanediol diacrylate, pentaerythritol triacrylate, pentaerythritol tetraacrylate, dipentaerythritol hexaacrylate, diethylene glycol diacrylate, polyethylene glycol diacrylate, polyethylene glycol dimethacrylate, tripropylene glycol diacrylate, propylene glycol trimethacrylate, diallyl phthalate, and triallyl trimellitate.

Among radically polymerizable monomers, N-vinylcarbazole, vinylnaphthalene, bromostyrene, chlorostyrene, tribromophenyl acrylate, trichlorophenyl acrylate, tribromophenyl methacrylate, or trichlorophenyl methacrylate is preferable for its high reactivity and high refractive index.

The amount of the radically polymerizable monomer in the recording layer is between 1 to 50% by weight, preferably between 3 to 30% by weight. If the amount is less than 1% by weight, one cannot achieve sufficient disparity in refractive index. Having the amount of radically polymerizable monomer exceeding 50% by weight, the volume shrinkage increases, which deteriorates the resolution.

The photo-acid generator may be selected according to the wavelength of the recording light. Examples of photo-acid generators include aryl onium salts, naphthoquinone diazide compounds, diazonium salts, sulfonate compounds, sulfonium compounds, sulfamide compounds, iodonium compounds, and sulfonyl diazomethane compounds.

Specific examples of the compounds include triphenylsulfonium triflate, diphenyliodonium triflate, 2,3,4,4-tetrahydroxybenzophenone-4-naphthoquinone diazide sulfonate, 4-N-phenylamino-2-methoxyphenyl diazonium sulfate, 4-N-phenylamino-2-methoxyphenyl diazonium p-ethylphenyl sulfate, 4-N-phenylamino-2-methoxyphenyl diazonium 2-naphthyl sulfate, 4-N-phenylamino-2-methoxyphenyl diazonium phenyl sulfate, 2,5-diethoxy-4-N-4′-methoxyphenylcarbonylphenyl diazonium 3-carboxy-4-hydroxyphenyl sulfate, 2-methoxy-4-N-phenylphenyl diazonium 3-carboxy-4-hydroxyphenyl sulfate, diphenyl sulfonyl methane, diphenyl sulfonyl diazo methane, diphenyl disulfone, α-methylbenzoin tosilate, pyrogallol trimethylate, benzoin tosilate, MPI-103 manufactured by Midori Kagaku Co., Ltd. (CAS. NO. [87709-41-9]), BDS-105 manufactured by Midori Kagaku Co., Ltd. (CAS. NO. [145612-66-4]), NDS-103 manufactured by Midori Kagaku Co., Ltd. (CAS. NO. [110098-97-0]), MDS-203 manufactured by Midori Kagaku Co., Ltd. (CAS. NO. [127855-15-5]), pyrogallol tritosylate manufactured by Midori Kagaku Co., Ltd. (CAS. NO. [20032-64-8]), DTS-102 manufactured by Midori Kagaku Co., Ltd. (CAS. NO. [75482-18-7]), DTS-103 manufactured by Midori Kagaku Co., Ltd. (CAS. NO. [71449-78-0]), MDS-103 manufactured by Midori Kagaku Co., Ltd. (CAS. NO. [127279-74-7]), MDS-105 manufactured by Midori Kagaku Co., Ltd. (CAS. NO. [116808-67-4]), MDS-205 manufactured by Midori Kagaku Co., Ltd. (CAS. NO. [81416-37-7]), BMS-105 manufactured by Midori Kagaku Co., Ltd. (CAS. NO. [149934-68-9]), TMS-105 manufactured by Midori Kagaku Co., Ltd. (CAS. NO. [127820-38-6]), NB-101 manufactured by Midori Kagaku Co., Ltd. (CAS. NO. [20444-09-1]), NB-201 manufactured by Midori Kagaku Co., Ltd. (CAS. NO. [4450-68-4]), DNB-101 manufactured by Midori Kagaku Co., Ltd. (CAS. NO. [114719-51-6]), DNB-102 manufactured by Midori Kagaku Co., Ltd. (CAS. NO. [131509-55-2]), DNB-103 manufactured by Midori Kagaku Co., Ltd. (CAS. NO. [132898-35-2]), DNB-104 manufactured by Midori Kagaku Co., Ltd. (CAS. NO. [132898-36-3]), DNB-105 manufactured by Midori Kagaku Co., Ltd. (CAS. NO. [132898-37-4]), DAM-101 manufactured by Midori Kagaku Co., Ltd. (CAS. NO. [1886-74-4]), DAM-102 manufactured by Midori Kagaku Co., Ltd. (CAS. NO. [28343-24-0]), DAM-103 manufactured by Midori Kagaku Co., Ltd. (CAS. NO. [14159-45-6]), DAM-104 manufactured by Midori Kagaku Co., Ltd. (CAS. NO. [130290-80-1], CAS. NO. [130290-82-3]), DAM-201 manufactured by Midori Kagaku Co., Ltd. (CAS. NO. [28322-50-1]), CMS-105 manufactured by Midori Kagaku Co., Ltd., DAM-301 manufactured by Midori Kagaku Co., Ltd. (CAS. NO. [138529-81-4]), SI-105 manufactured by Midori Kagaku Co., Ltd. (CAS. NO. [34694-40-7]), NDI-105 manufactured by Midori Kagaku Co., Ltd. (CAS. NO. [133710-62-0]), and EPI-105 manufactured by Midori Kagaku Co., Ltd. (CAS. NO. [135133-12-9]).

The amount of the photo-acid generator is preferably in an amount such that the transmittance of the recording light through the optical recording medium lies within the range of 10% to 95%. Having the transmittance below 10%, the sensitivity and diffraction efficiency may deteriorate, and having the transmittance above 95%, the major part of the recording light passes through the medium, which may result in the failure of recording the information that is intended to be recorded. It is even more preferable that the transmittance of the recording light lies in between 20 to 90%.

The photo-acid generator described above may be used alone, or in a combination of two or more chosen from them. The amount of the photo-acid generator is preferably from 0.1 to 15% by weight to the recording layer. Having the amount of photo-acid generator below 0.1% by weight, acid generation by photo-irradiation is insufficient, which results in the failure to achieve sufficient sensitivity. On the other hand, if the amount of the photo-acid generator exceeds 15% by weight to the recording layer, the optical absorption becomes too high, which may result in the deterioration in sensitivity and diffraction efficiency. It is even more preferable that the amount of the photo-acid generator lies in between 0.5 to 10% by weight to the recording layer.

In addition to the photo-acid generator stated above, a sensitizer may be added to increase sensitivity, if necessary. Examples of sensitizers include benzophenone, 4-(methylphenylthio)-phenylphenylketone, isopropylthioxanthone, 2-chlorothioxanthone, and 4,4′bis(diethylamino)-benzophenone. The amount of the sensitizer is usually from about 0.5 to 10% by weight with reference to the recording layer.

In order to further increase the acid generated by photoirradiation acid, an acid amplifier may be added. Examples of preferable acid amplifiers include p-toluenesulfonic acid, cis-3-(octanesulfonyloxy)-2-pinanol, cis-3-((+)-10-camphor-sulfonyloxy)-2-pinanol, and cis-3-(p-toluenesulfonyloxy)-2-pinanol. The amount of the acid amplifier is usually from about 0.1 to 5% by weight with reference to the recording layer.

The photo-radical polymerization initiator may be selected according to the wavelength of the recording light. Examples of the photo-radical polymerization initiator include benzoin ethers, benzyl ketals, benzyl, acetophenone derivatives, aminoacetophenones, benzophenone derivatives, acylphosphine oxides, triazines, imidazole derivatives, organic azido compounds, titanocenes, organic peroxides, and thioxanthone derivatives.

Specific examples of the compounds include benzyl, benzoin, benzoin ethyl ether, benzoin isopropyl ether, benzoin butyl ether, benzoin isobutyl ether, 1-hydroxycyclohexylphenyl ketone, benzyl methyl ketal, benzyl ethyl ketal, benzylmethoxy ethyl ether, 2,2′-diethylacetophenone, 2,2′-dipropylacetophenone, 2-hydroxy-2-methylpropiophenone, p-tert-butyltrichloroacetophenone, thioxanthone, 1-chlorothioxanthone, 2-chlorothioxanthone, 2-methylthioxanthone, 2-isopropylthioxanthone, 3,3′4,4′-tetra(t-butylperoxycarbonyl)benzophenone, 2,4,6-tris(trichloromethyl)1,3,5-triazine, 2-(p-methoxyphenyl)-4,6-bis(trichloromethyl)1,3,5-triazine, 2-[(p-methoxyphenyl)ethylene]-4,6-bis(trichloromethyl)1,3,5-triazine, diphenyl-(2,4,6-trimethylbenzoyl)phosphine oxide, IRGACURE 149, 184, 369, 651, 784, 819, 907, 1700, 1800, and 1850 manufactured by Ciba Specialty Chemicals, di-t-butyl peroxide, dicumyl peroxide, t-butylcumyl peroxide, t-butyl peroxyacetate, t-butyl peroxyphthalate, t-butyl peroxybenzoate, acetyl peroxide, isobutyryl peroxide, decanoyl peroxide, lauroyl peroxide, benzoyl peroxide, t-butyl hydroperoxide, cumene hydroperoxide, methyl ethyl ketone peroxide, and cyclohexanone peroxide.

When blue semiconductor laser light is used as the recording light, the photo-radical polymerization initiator is preferably a titanocene compound such as IRGACURE 784 (manufactured by Ciba Specialty Chemicals).

The amount of the photo-radical polymerization initiator is preferably in an amount such that the transmittance of the recording light through the optical recording medium lies within the range of 10% to 95%. If the transmittance is below 10%, the sensitivity and diffraction efficiency may deteriorate, and if the transmittance is over 95%, the major part of the recording light passes through the medium, which may result in the failure of recording the information that is intended to be recorded. It is even more preferable that the transmittance of the recording light lies in between 20 to 90%.

The amount of the photo-radical polymerization initiator is preferably from 0.1 to 20% by weight with reference to the recording layer. If the amount is less than 1% by weight, one cannot achieve sufficient disparity in refractive index. On the other hand, if the amount exceeds 20% by weight, the optical absorption becomes too high, which may result in the deterioration of the sensitivity and diffraction efficiency. The amount of the photo-radical polymerization initiator is more preferably from 0.2 to 10% by weight with reference to the recording layer.

The polymeric matrix contains the repeating unit expressed by the general formula (1) or (2).

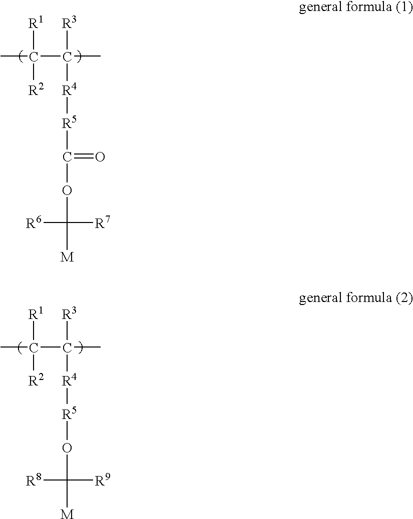

The repeating unit expressed by the general formula (1) can be obtained from the monomer expressed by the general formula (1m). The repeating unit expressed by the general formula (2) can be obtained from the monomer expressed by the general formula (2m).

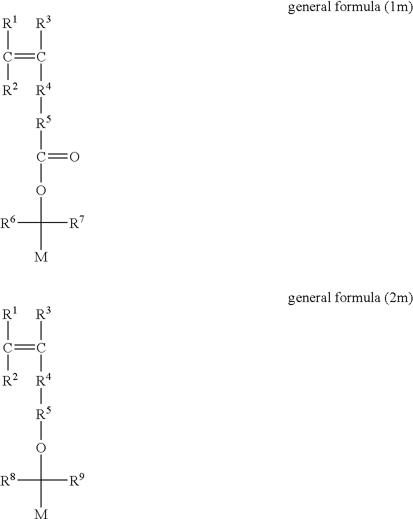

In the general formulae expressed above, R¹, R², and R³ each represent a hydrogen atom or a hydrocarbon group having 10 or less carbon atoms. The hydrocarbon group may be an aliphatic hydrocarbon group, an alicyclic hydrocarbon group, or an aromatic hydrocarbon group. Specific examples of the hydrocarbon group which may be introduced to R¹, R², and R³ include a methyl group, an ethyl group, a propyl group, an isopropyl group, a butyl group, a sec-butyl group, a tert-butyl group, a cyclohexyl group, an adamantyl group, and a phenyl group. When the repeating unit expressed by the general formula (1) is to be synthesized from the monomer expressed by the general formula (1m), the preparation becomes difficult if R¹, R², and R³ are bulky. Therefore, R¹, R², and R³ are preferably hydrogen atoms, methyl groups, or ethyl group. It is particularly preferable that R¹ and R² are hydrogen atoms, except when R² is bonded to R⁴ to form a ring as described below. R³ is particularly preferable as a hydrogen atom or a methyl group.

R⁴ and R⁵ each represent a single bond or a secondary hydrocarbon group having 20 or less carbon atoms. The secondary hydrocarbon group may be an aliphatic hydrocarbon group, an alicyclic hydrocarbon group, or an aromatic hydrocarbon group. Specific examples of the secondary hydrocarbon group which may be introduced to R⁴ and R⁵ include a methylene group, an ethylene group, a propylene group, a butylene group, a pentamethylene group, a hexamethylene group, a heptamethylene group, an octamethylene group, a cyclohexylene group, an adamantylene group, and a phenylene group.

As described above, the repeating unit expressed by the general formula (1) is synthesised from the monomer expressed by the general formula (1m), but if R⁴ is bulky, obtaining the repeating unit expressed by the general formula (1) becomes difficult. Therefore, the hydrocarbon group introduced to R⁴ is preferably primary carbon, and preferably a methylene group, an ethylene group, a propylene group, or a butylene group.

As will be described later, the carbon atom directly bonded to the adjacent oxygen atom in R⁵ is preferably a secondary or primary carbon, and more preferably a primary carbon. From such point of view, it is preferable that a hydrocarbon group selected from the group consisting of a methylene group, an ethylene group, a propylene group, and a butylene group is introduced to R⁵.

The hydrocarbon group introduced to each of R⁴ and R⁵ may contain an oxygen or nitrogen atom. When an oxygen or nitrogen atom is contained in the hydrocarbon, R⁴ and R⁵ easily form long hydrocarbon groups, which results in an increase of the distance between the main chain and M. This favorably facilitates the occurrence of the reaction on M as will be described below. Another advantage is the decrease in refractive index of the polymeric matrix due to the introduction of greater number of hydrocarbons into the polymeric matrix. For example, the oxygen atom may be contained in the form of a carbonyl group or an ether group, and a nitrogen atom may be contained in the form of an amino group or an amide group. The hydrocarbon group which may be introduced to R⁴ may form a ring together with the hydrocarbon group introduced to R².

When R⁴ and/or R⁵ is a single bond, the compound is easily synthesized. On the other hand, when hydrocarbon groups are introduced to R⁴ and R⁵, a greater number of hydrocarbons can be introduced to the polymeric matrix thereby decreasing its refractive index. Therefore, one can select either from a single bond or from a hydrocarbon group to introduce to each of R⁴ and R⁵ depending on the purpose.

R⁶ represents a hydrocarbon group having 10 or less carbon atoms, and may be an aliphatic hydrocarbon group, an alicyclic hydrocarbon group, or an aromatic hydrocarbon group. Specific examples of the hydrocarbon group which may be introduced to R⁶ include a methyl group, an ethyl group, a propyl group, an isopropyl group, a butyl group, a sec-butyl group, a tert-butyl group, a cyclohexyl group, and a phenyl group. As will be described later, since the acid generated by the photo-acid generator cleaves the bond between the carbon atom and oxygen atom located between R⁶ and R⁷, the hydrocarbon group introduced to R⁶ is preferably a spatially small methyl or ethyl group in order to reduce the steric hindrance. As for R⁴ and R⁵, the hydrocarbon group introduced to R⁶ may contain an oxygen atom or a nitrogen atom.

R⁷ represents a hydrogen atom or a hydrocarbon group having 10 or less carbon atoms. The hydrocarbon group may be an aliphatic hydrocarbon group, an alicyclic hydrocarbon group, or an aromatic hydrocarbon group. Specific examples of the hydrocarbon group which may be introduced to R⁷ include a methyl group, an ethyl group, a propyl group, an isopropyl group, a butyl group, a sec-butyl group, a tert-butyl group, a cyclohexyl group, an adamantyl group, and a phenyl group. As will be described later, since the acid generated by the photo-acid generator cleaves the bond between the carbon atom and oxygen atom located between R⁶ and R⁷, the hydrocarbon group introduced to R⁶ is preferably a spatially small methyl or ethyl group in order to reduce the steric hindrance.

R⁸ and R⁹ each represent a hydrocarbon group having 10 or less carbon atoms, and may be an aliphatic hydrocarbon group, an alicyclic hydrocarbon group, or an aromatic hydrocarbon group. R⁸ and R⁹ may be the same or different from each other. Specific examples of the hydrocarbon group which may be introduced to R⁸ or R⁹ include a methyl group, an ethyl group, a propyl group, an isopropyl group, a butyl group, a sec-butyl group, a tert-butyl group, a cyclohexyl group, and a phenyl group. As will be described later, since the acid generated by the photo-acid generator cleaves the bond between the carbon atoms located between R⁸ and R⁹, the hydrocarbon group introduced to R⁸ or R⁹ is preferably a spatially small ethyl or methyl group. As is the case with R⁴ and R⁵, the hydrocarbon group introduced to R⁸ or R⁹ may contain an oxygen atom or a nitrogen atom.

M represents an aromatic group, and preferably has 30 or less carbon atoms. Specifically, the aromatic group introduced to M may be selected from the group consisting of benzene, naphthalene, anthracene, tetracene, pentacene, triphenyl, chrysene, phenanthrene, pyrene, thiophene, and phenalene. To the aromatic group M, a hydrocarbon group having 10 or less carbon atoms, an aromatic group having 10 or less carbon atoms, a halogen atom other than a fluorine atom, or a thiol group may be introduced. It is favorable that these substituents are introduced to the aromatic group M since the refractive index of M increases.

Examples of the hydrocarbon group which may be introduced include a methyl group, an ethyl group, a propyl group, an isopropyl group, a butyl group, a sec-butyl group, and a tert-butyl group. Examples of the aromatic group which may be introduced include a phenyl group and a naphthyl group.

From the viewpoint of commercial availability and absorption at the recording wavelength, the aromatic group M is particularly preferably benzene, naphthalene, anthracene, and phenanthrene.

Specific examples of the repeating unit expressed by the general formula (1) are shown below.

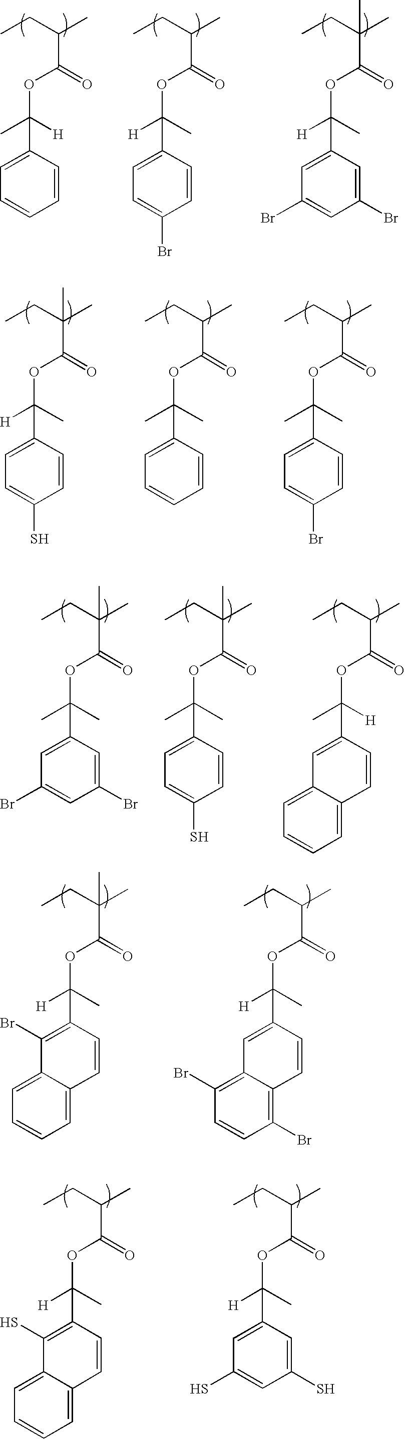

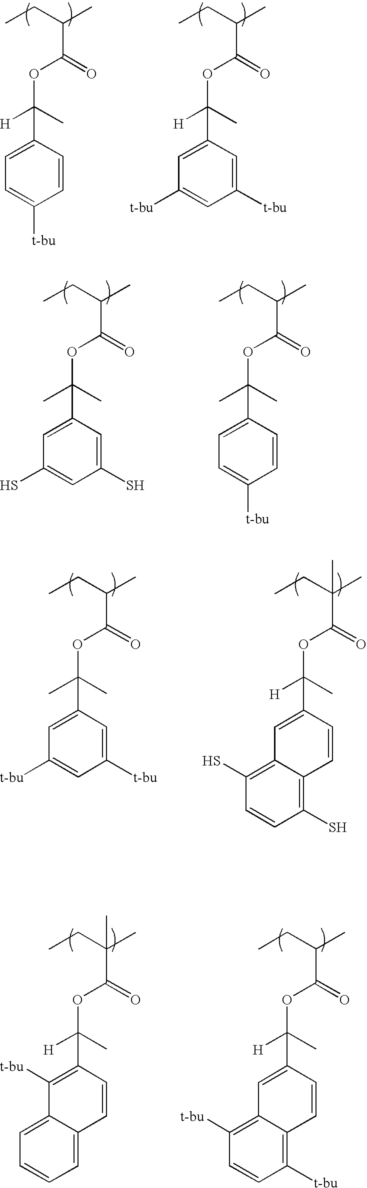

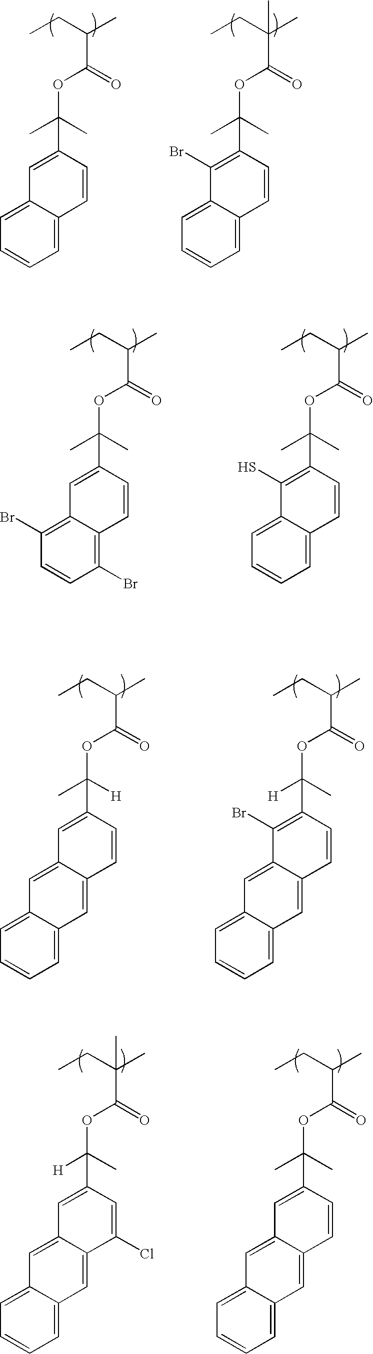

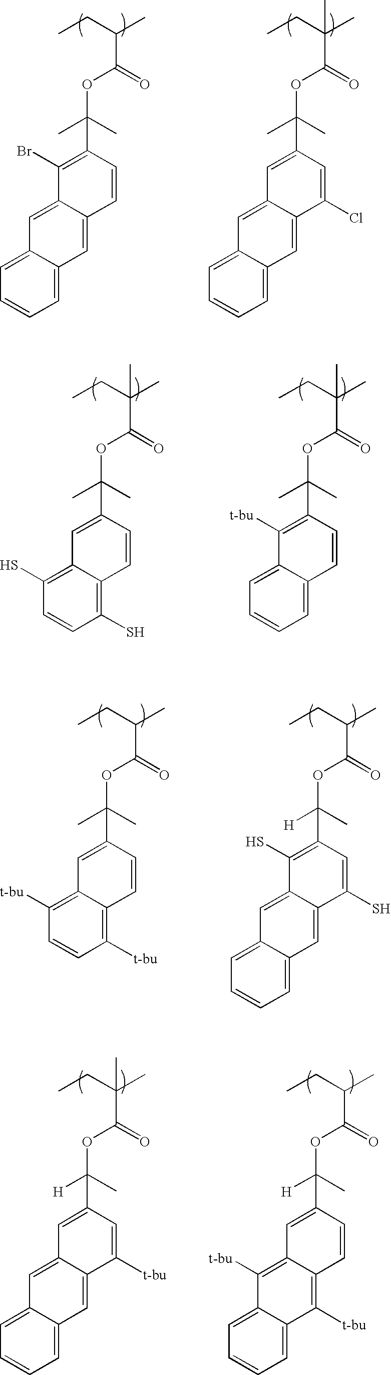

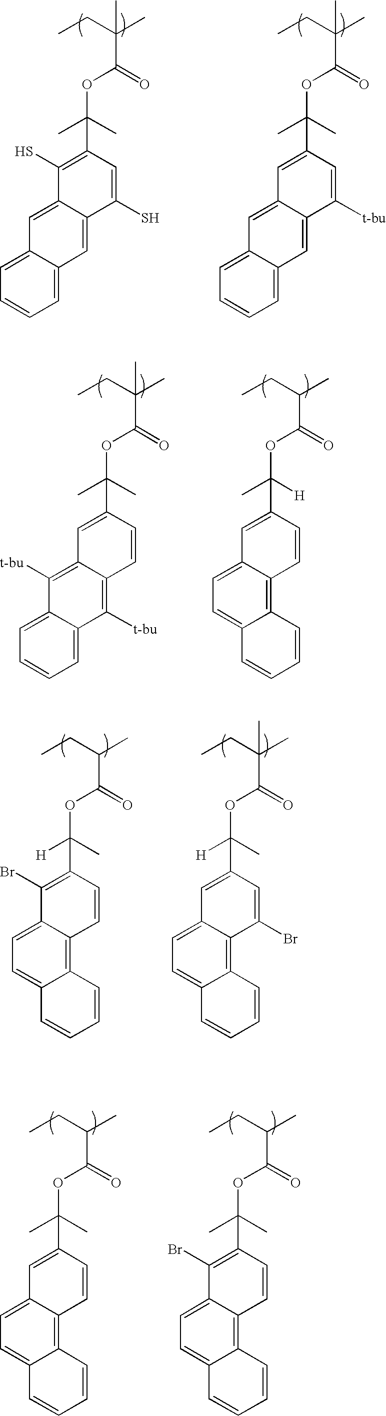

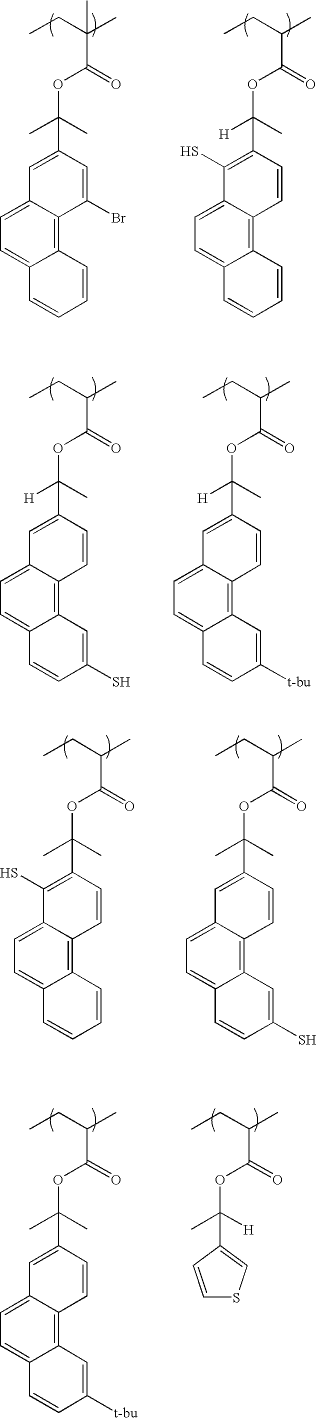

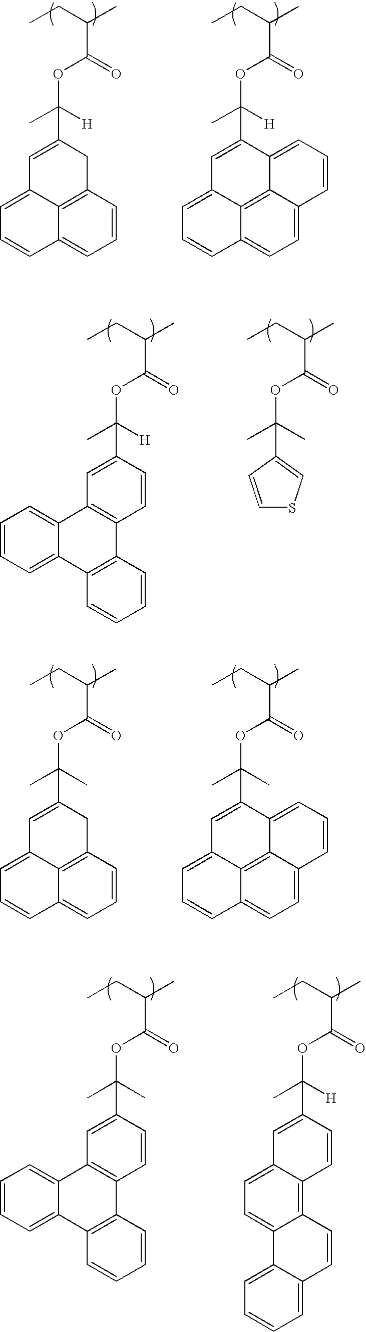

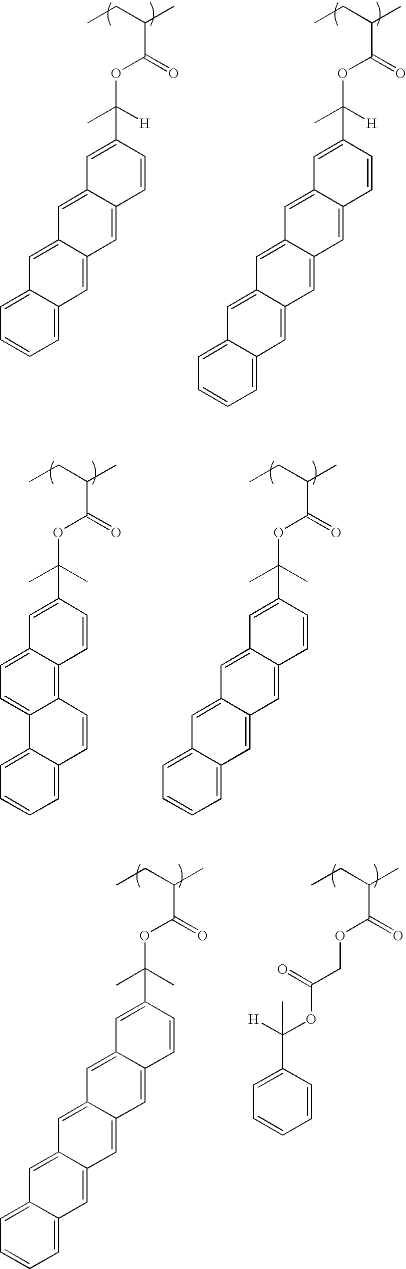

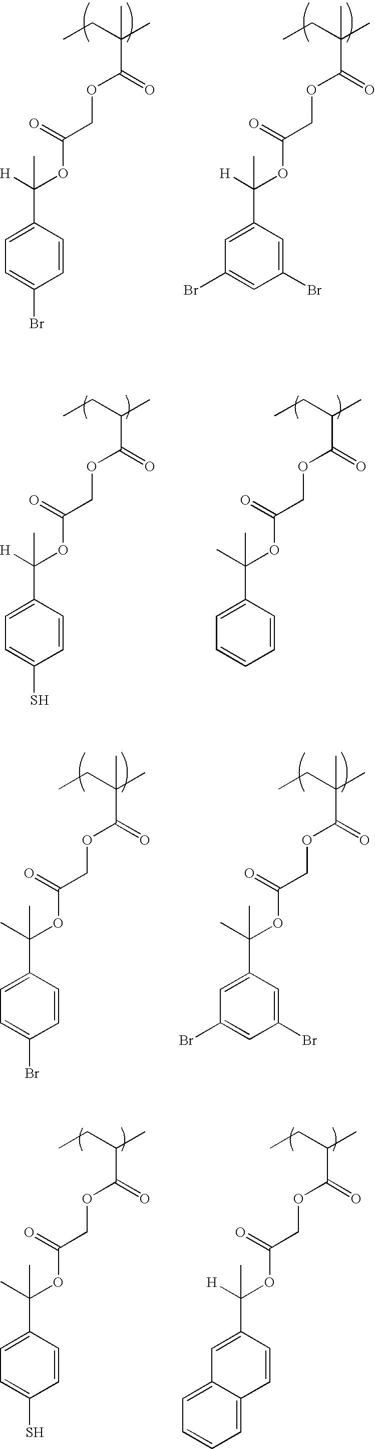

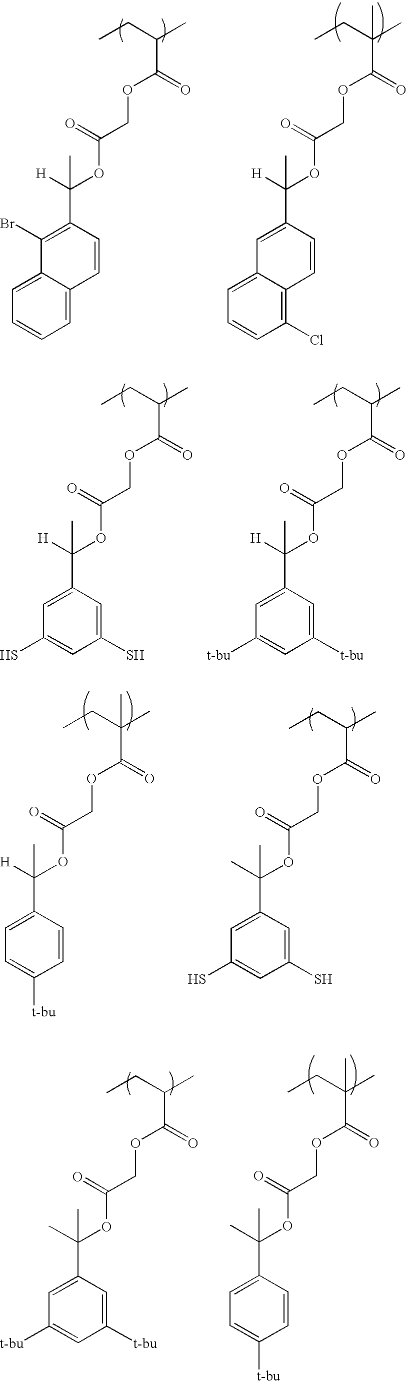

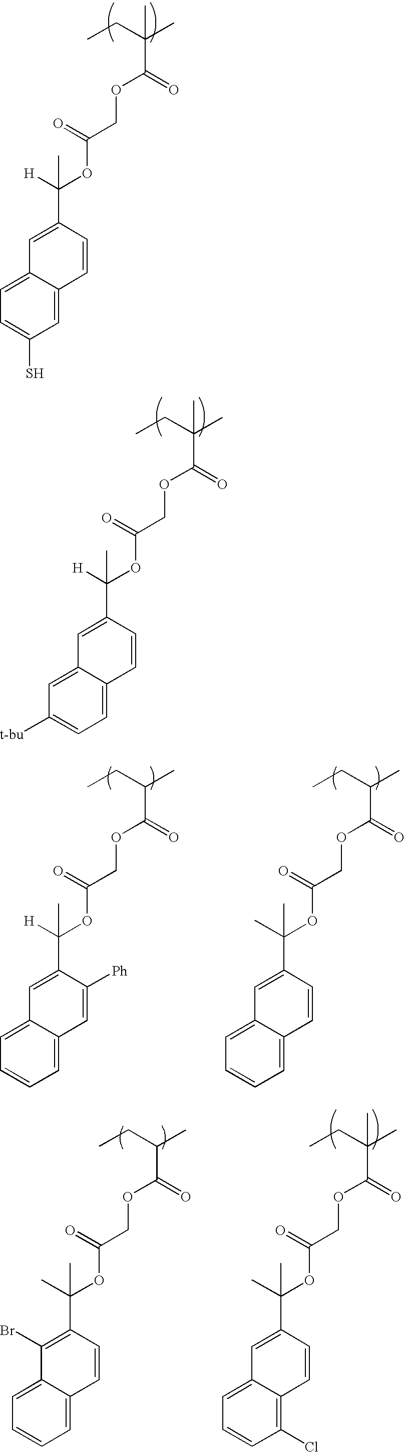

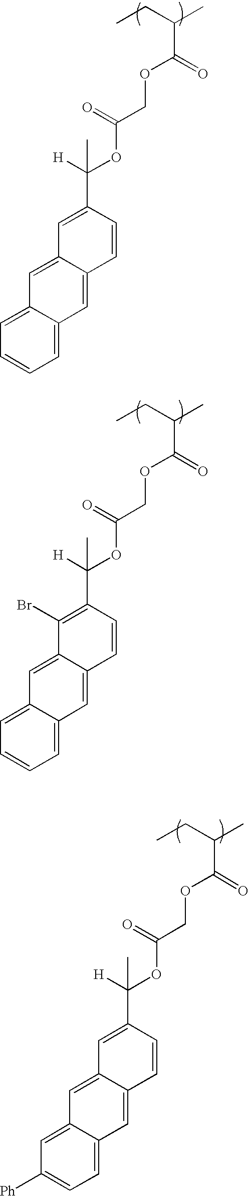

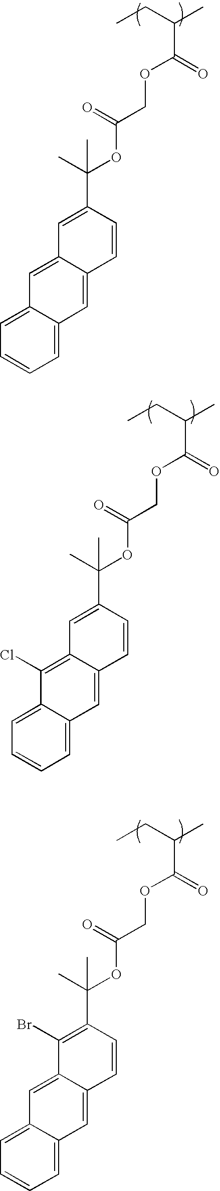

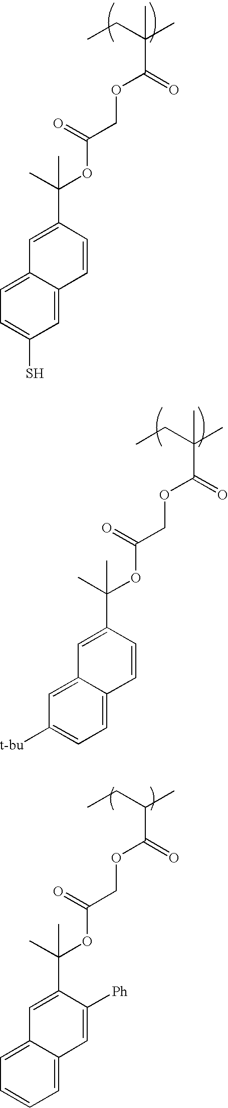

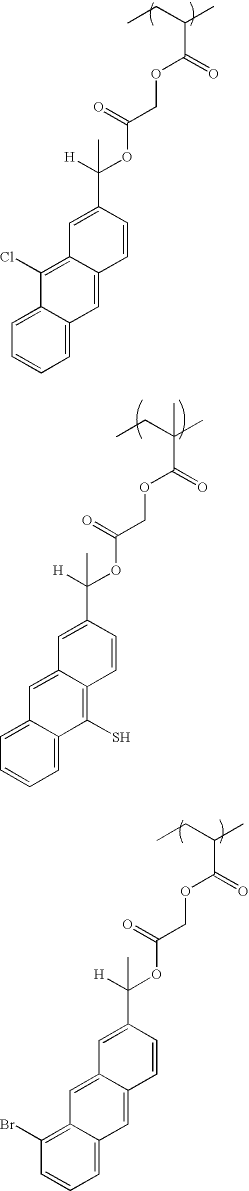

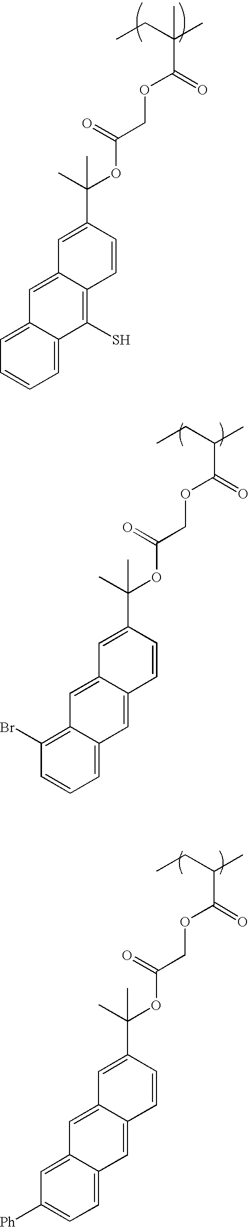

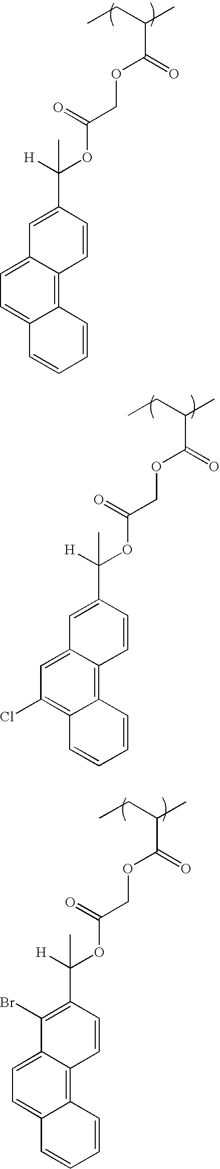

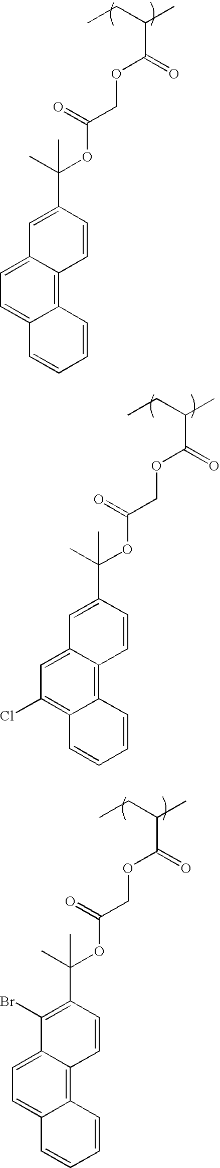

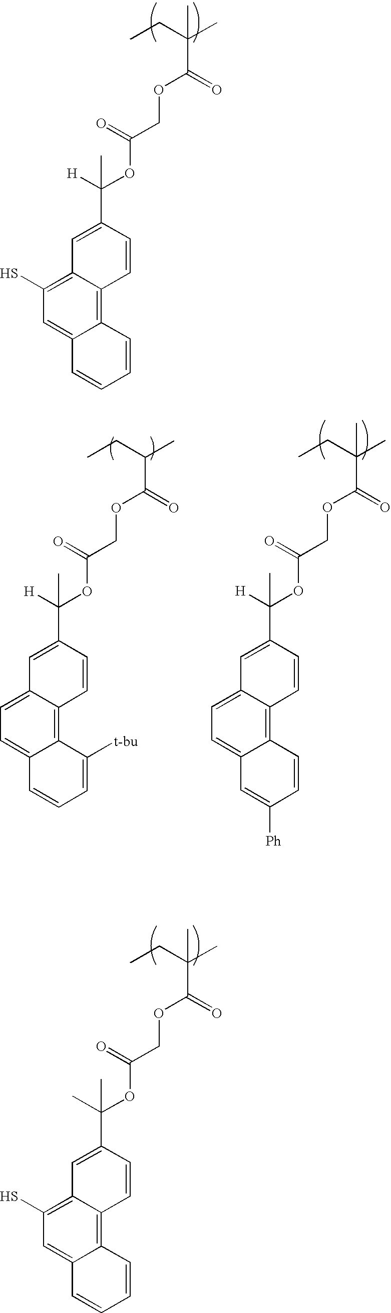

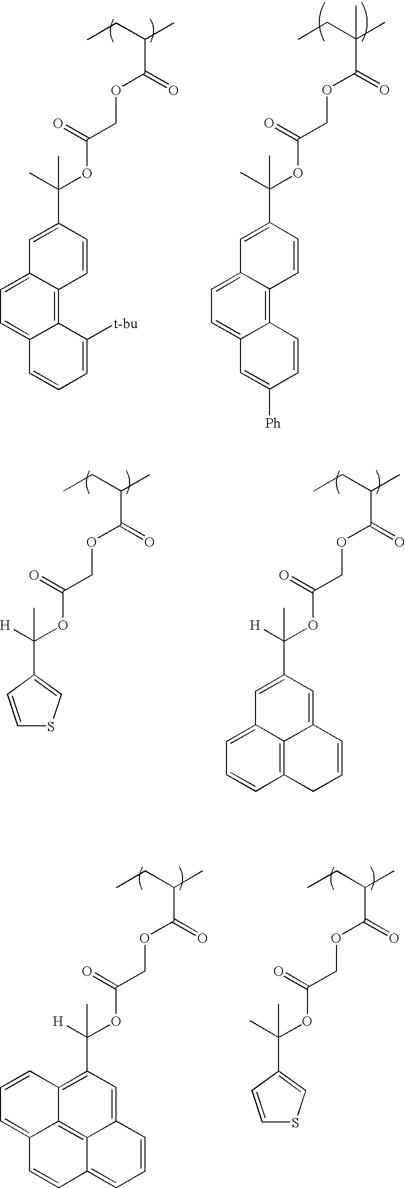

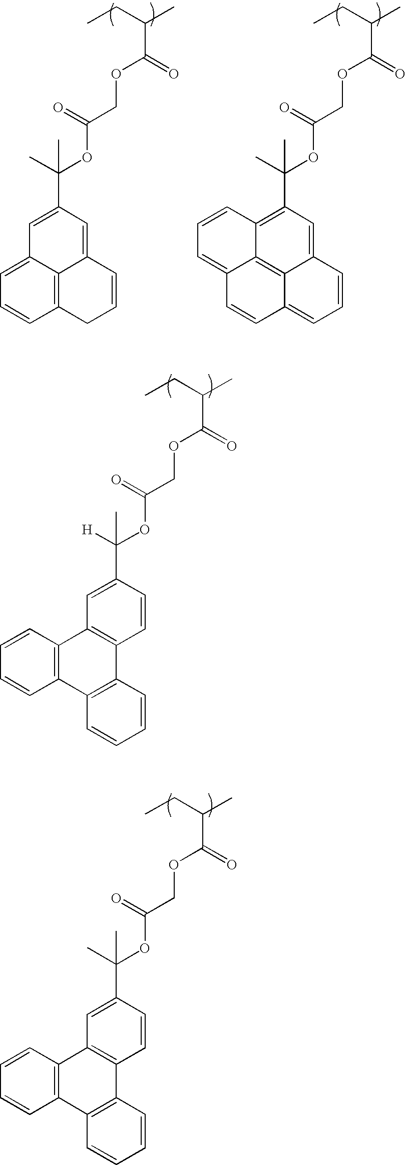

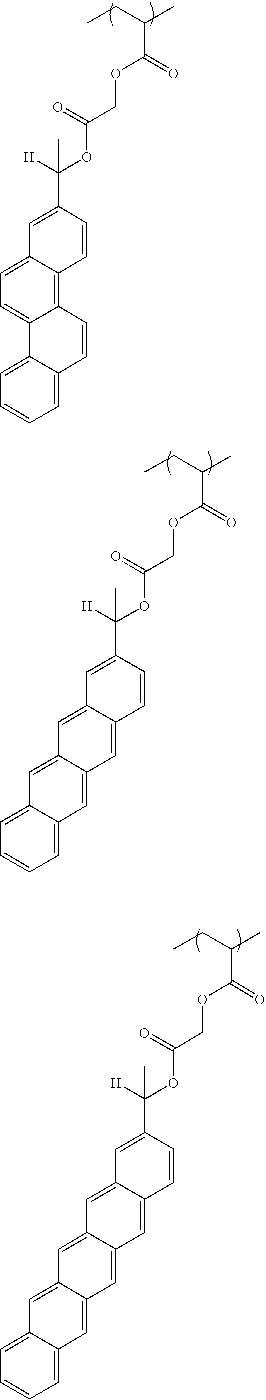

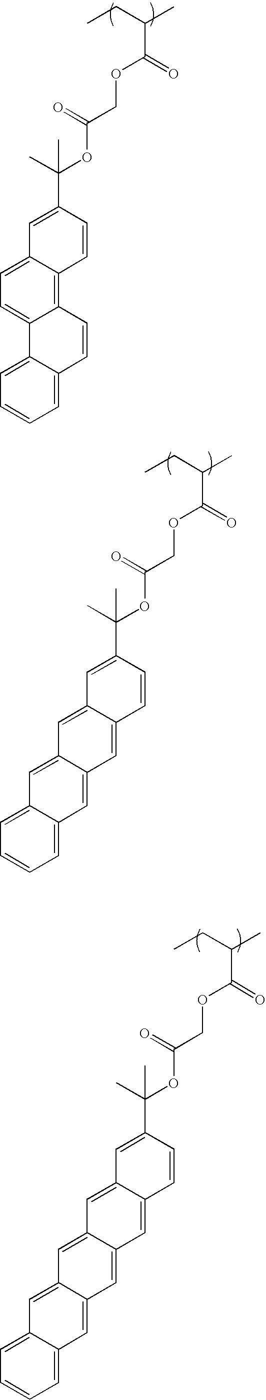

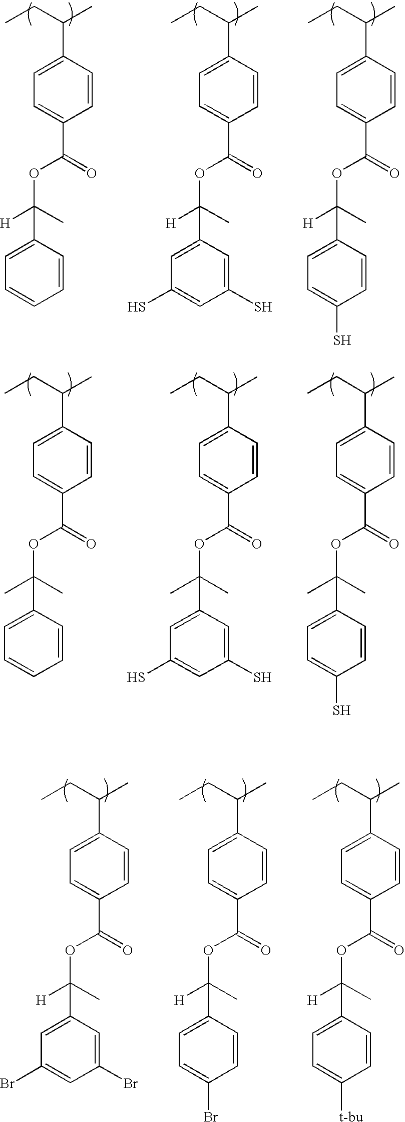

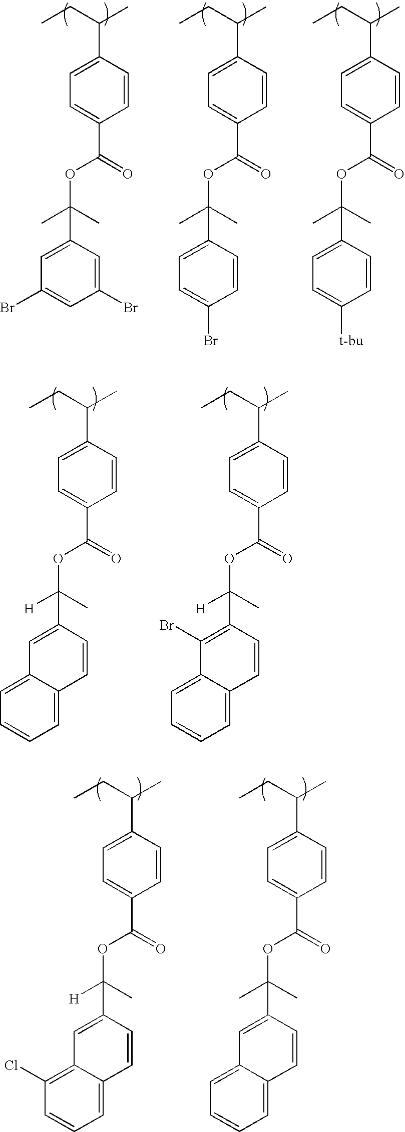

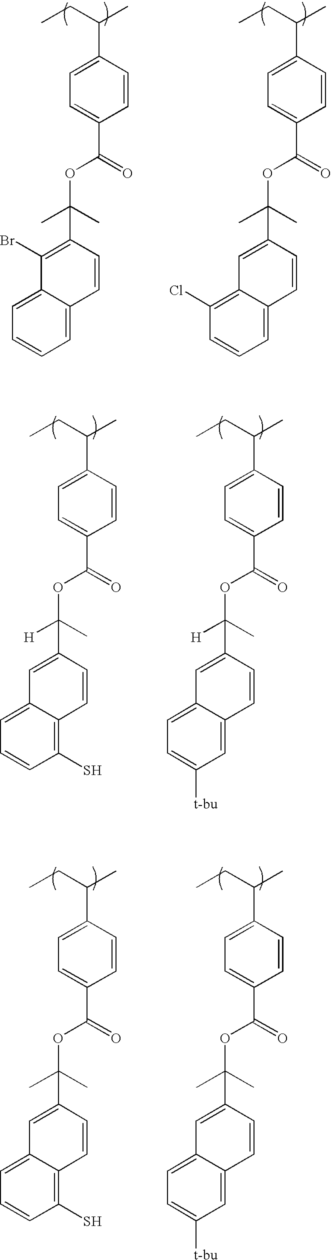

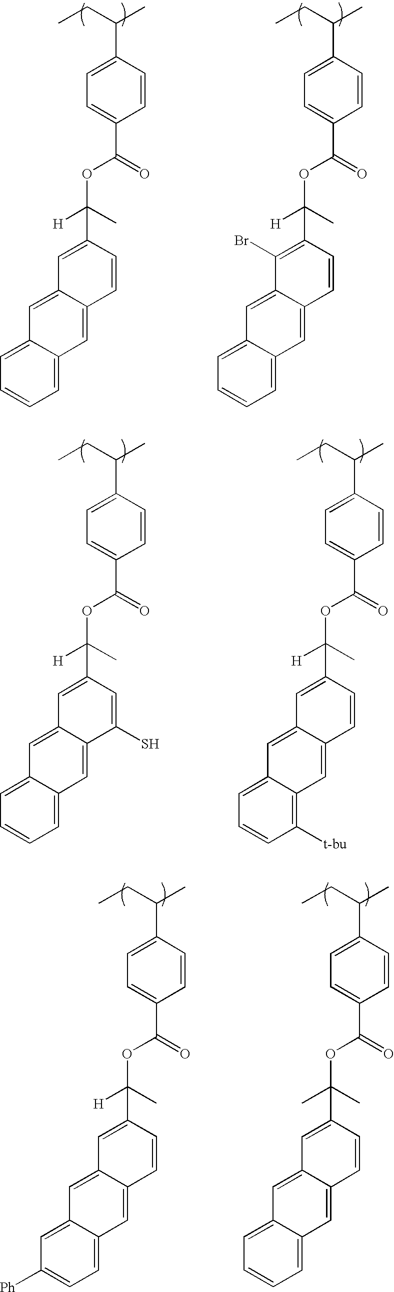

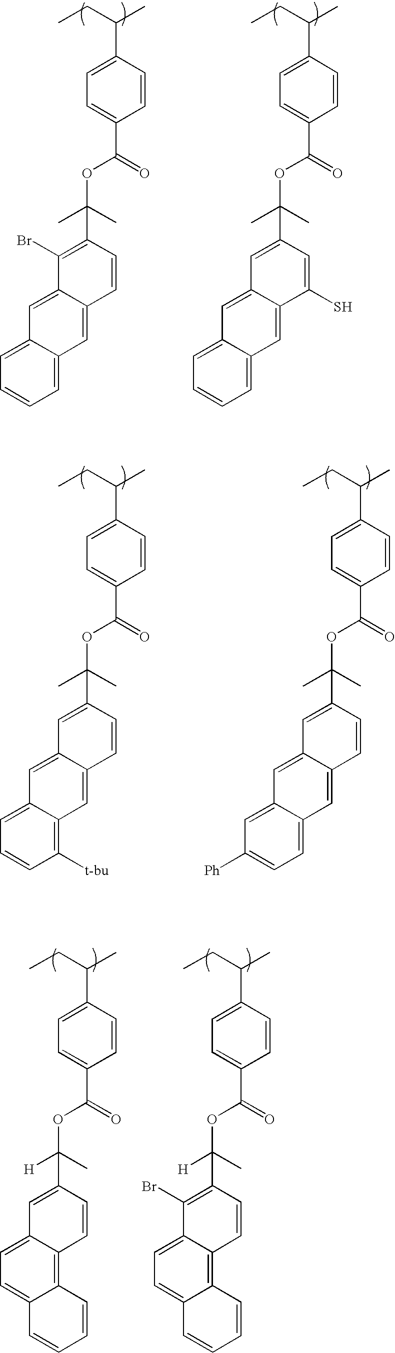

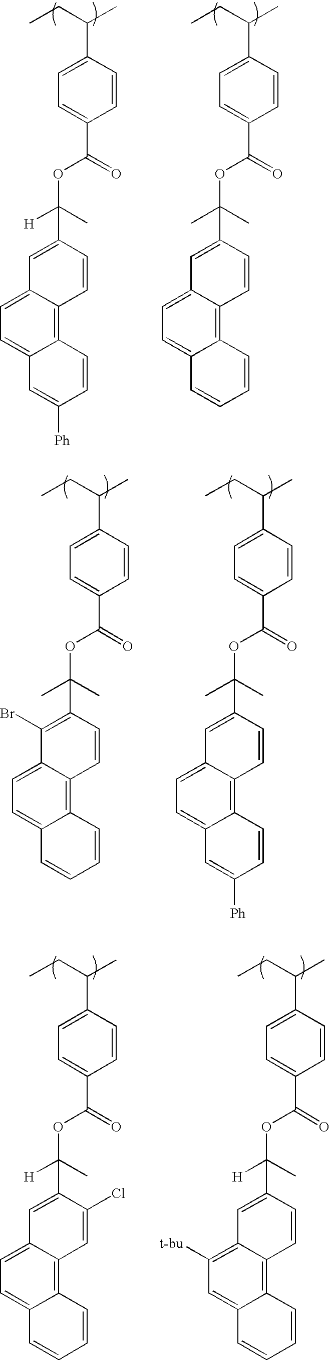

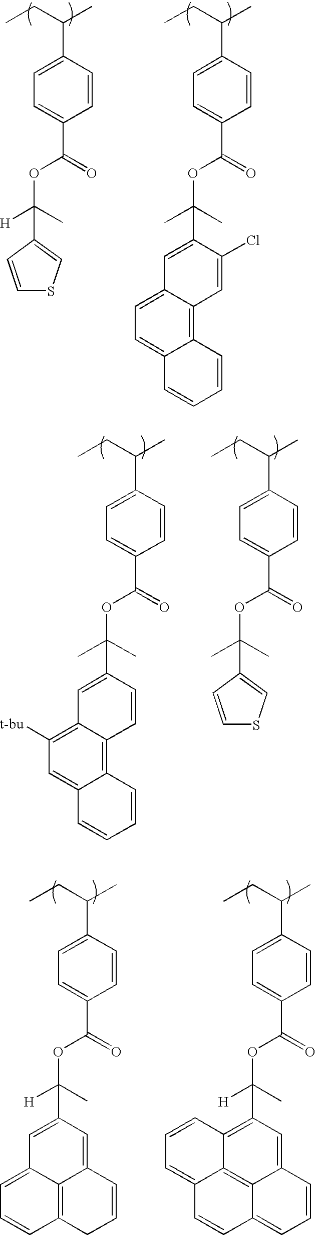

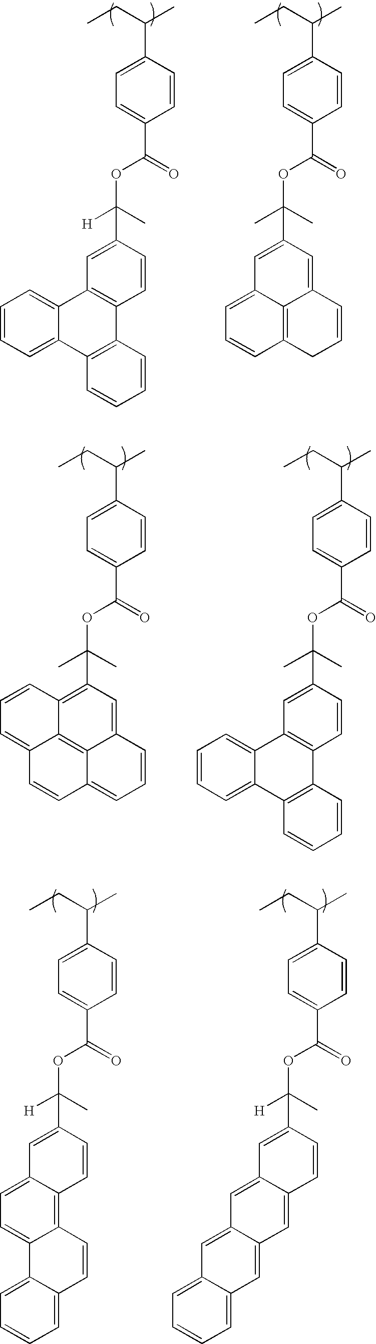

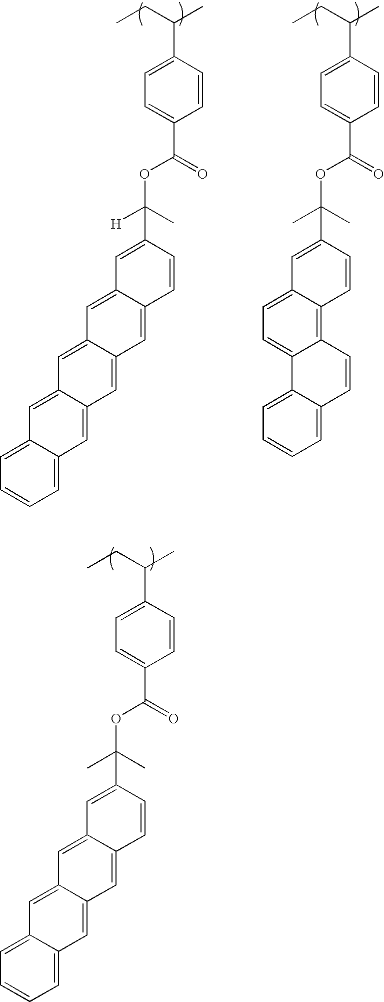

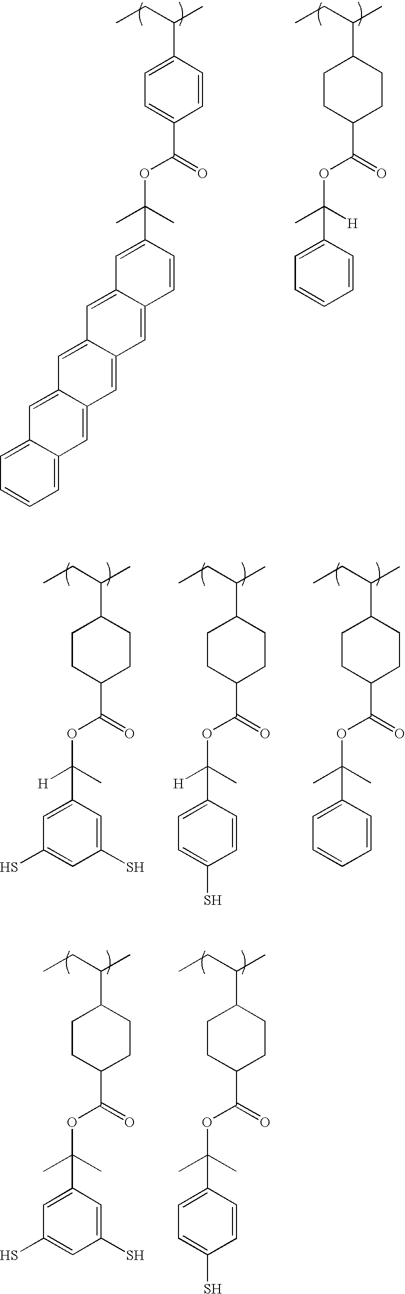

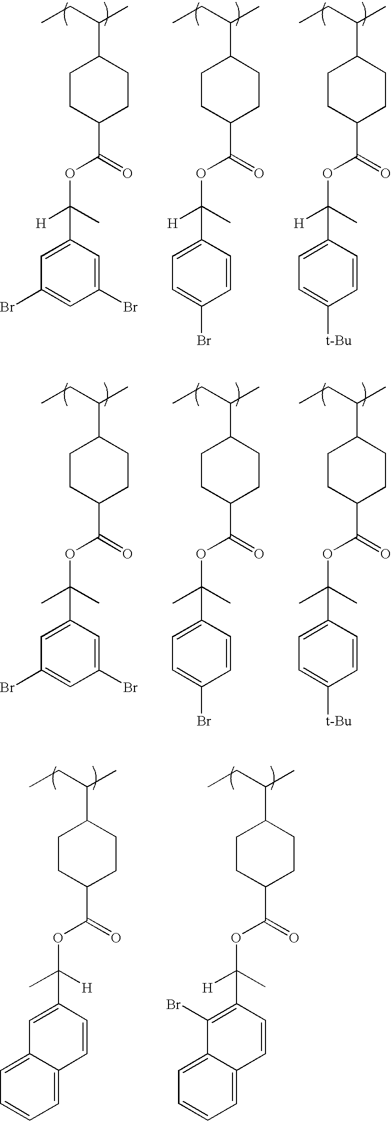

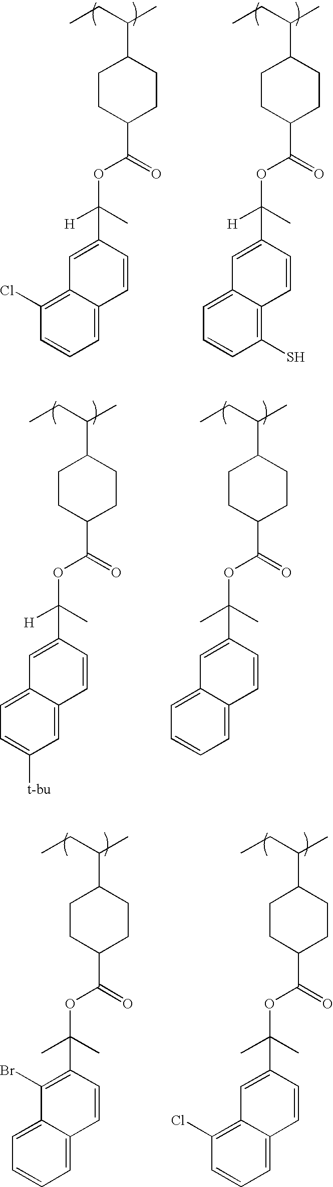

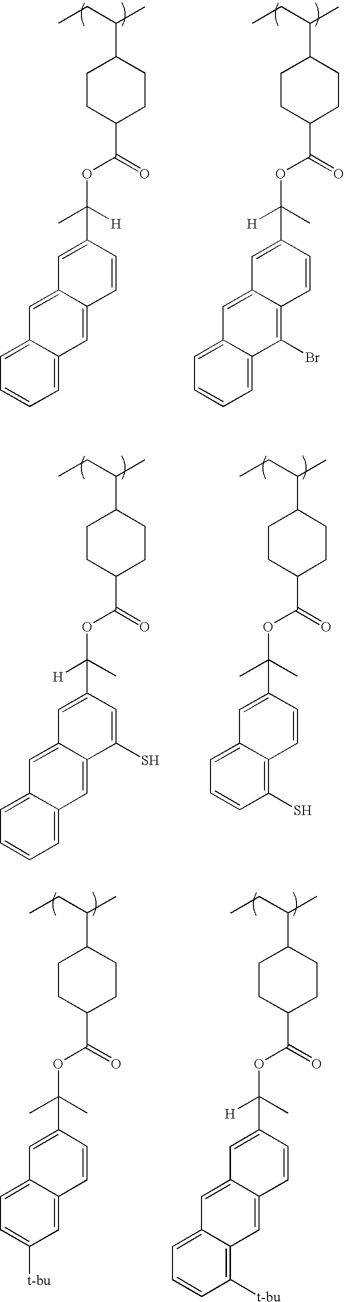

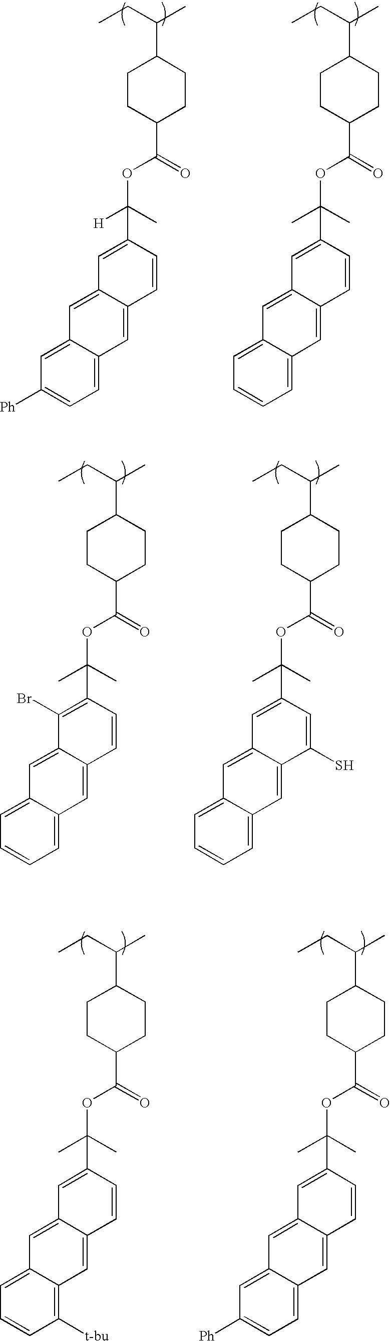

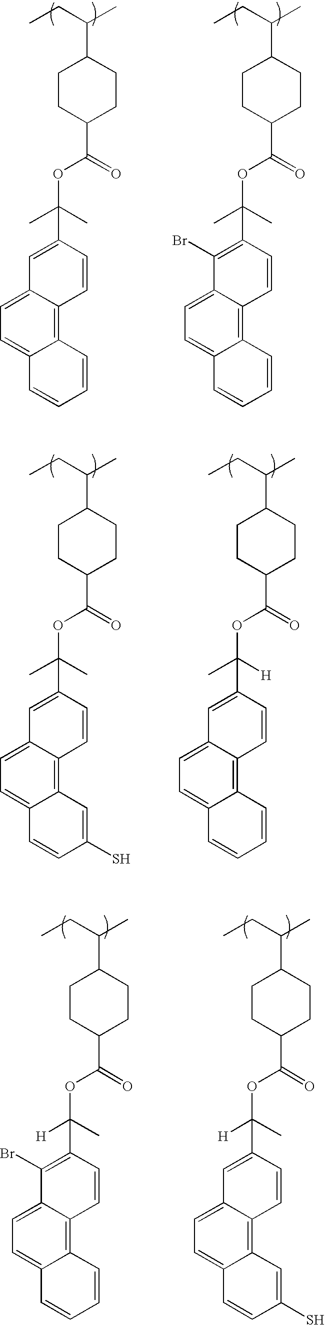

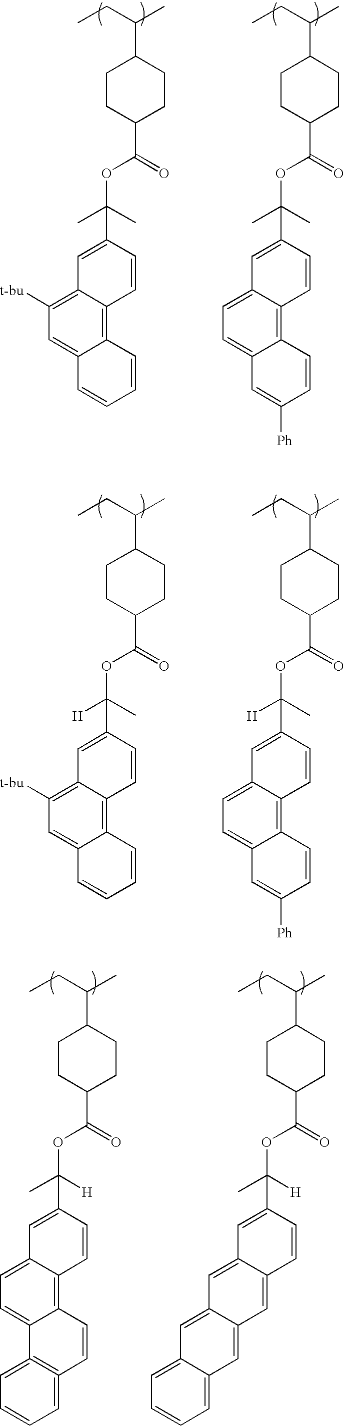

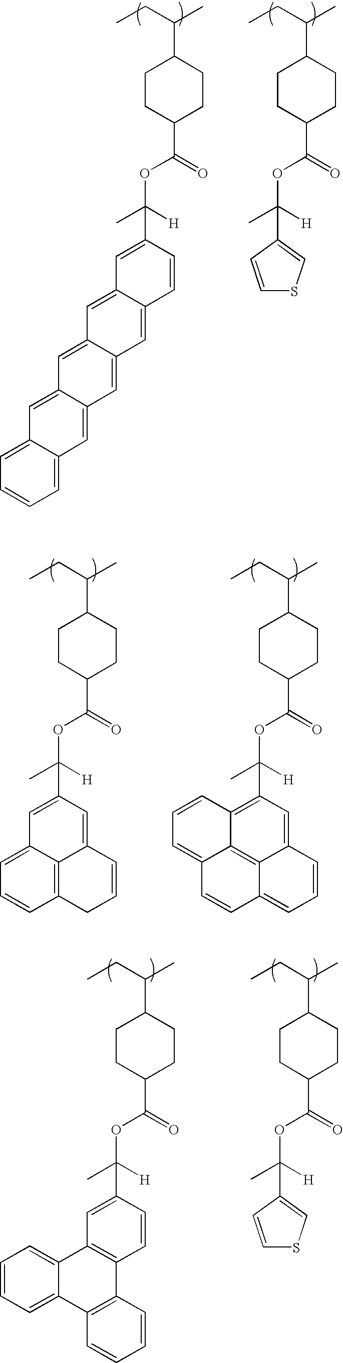

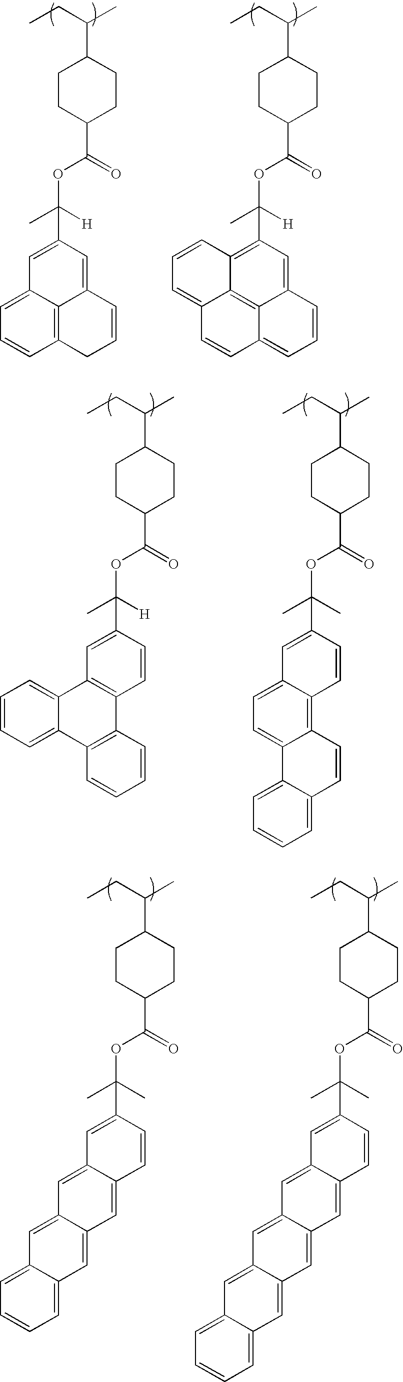

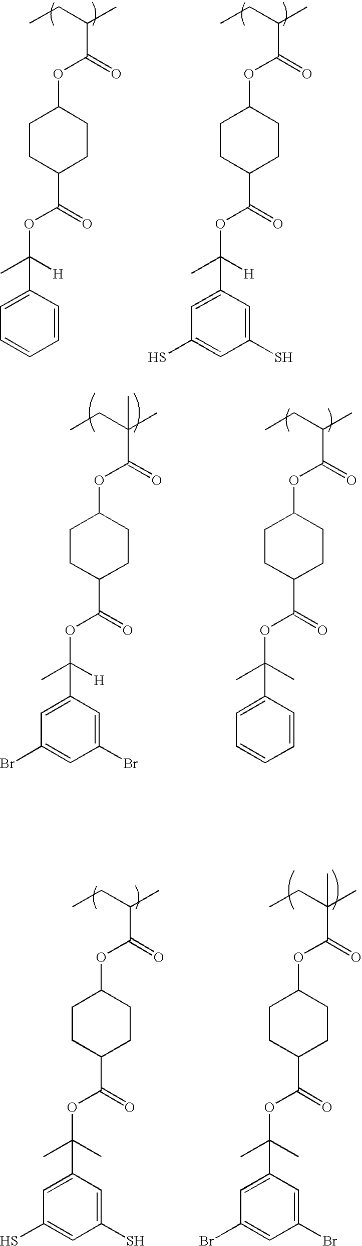

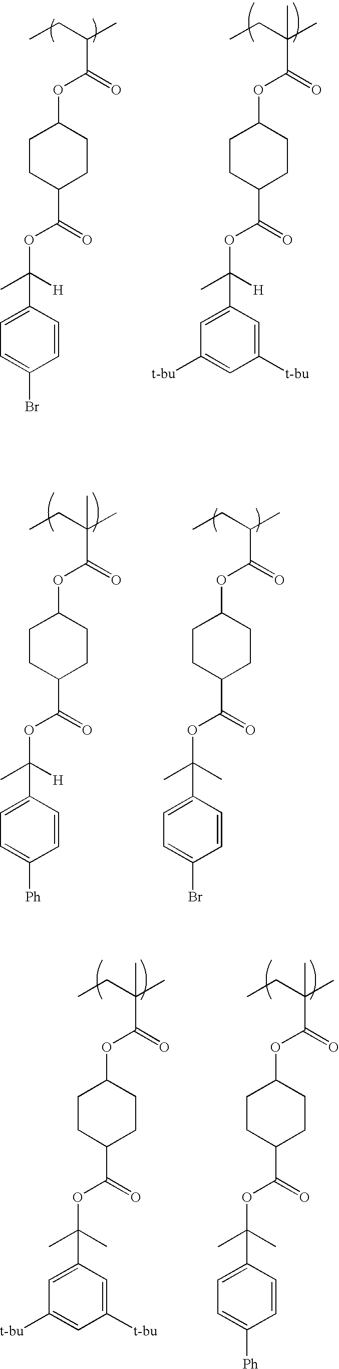

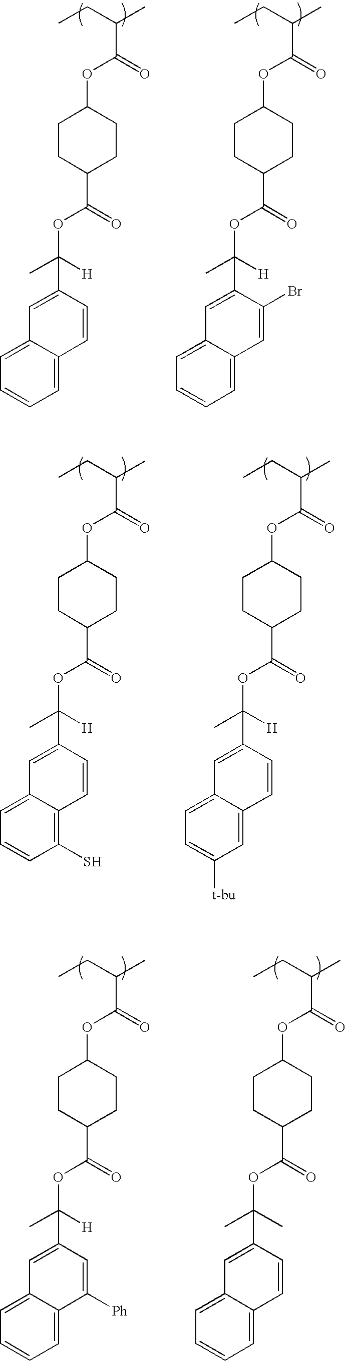

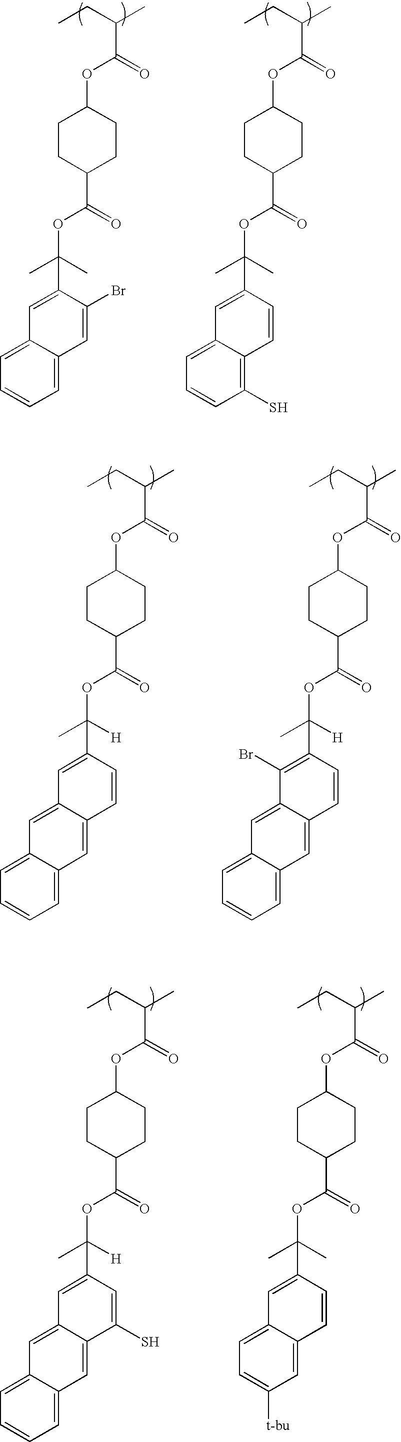

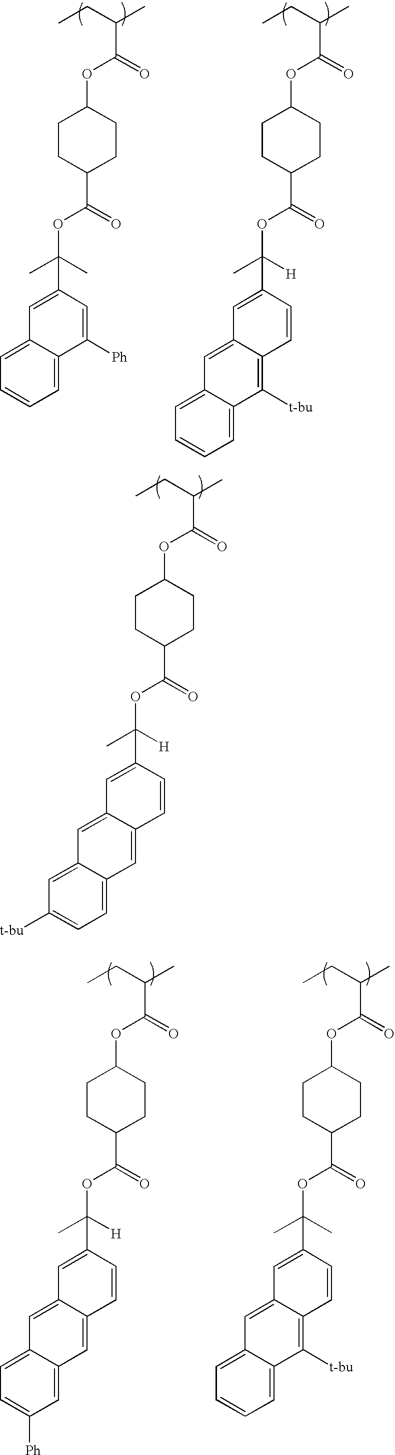

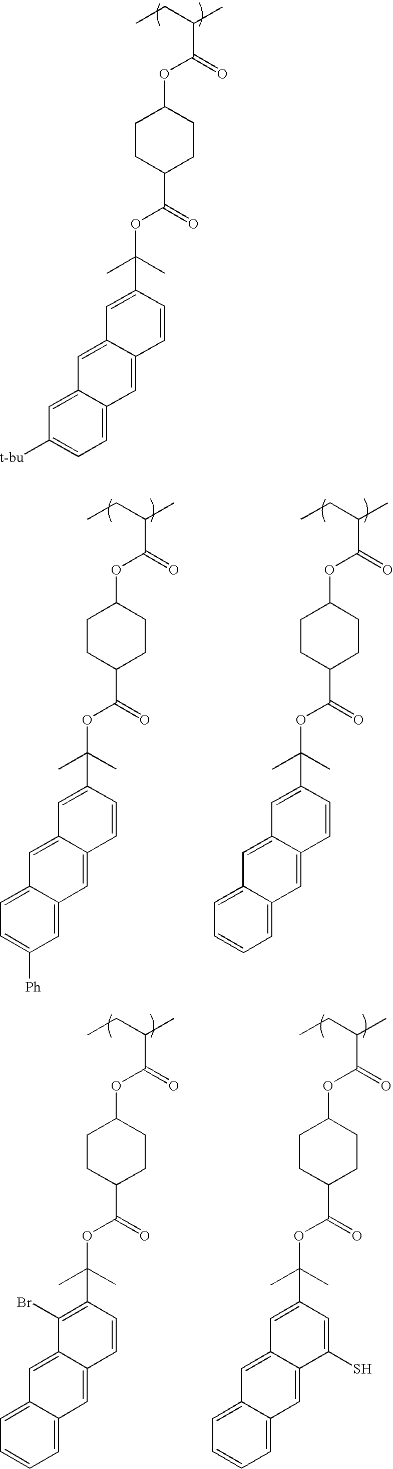

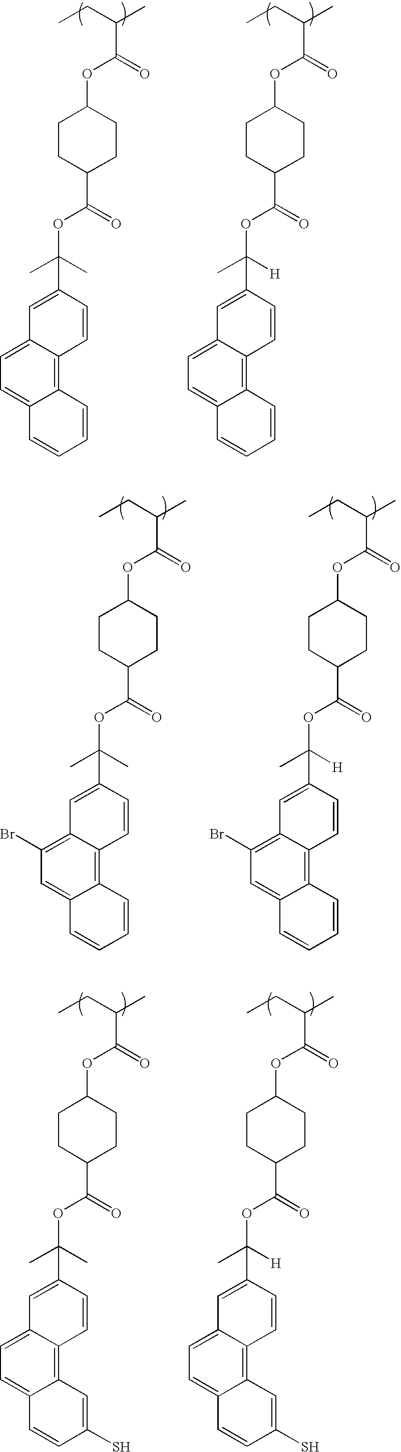

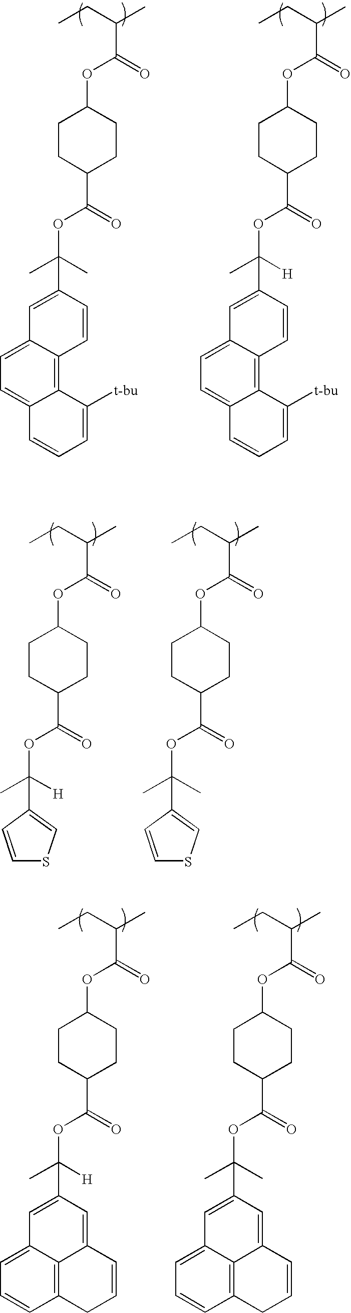

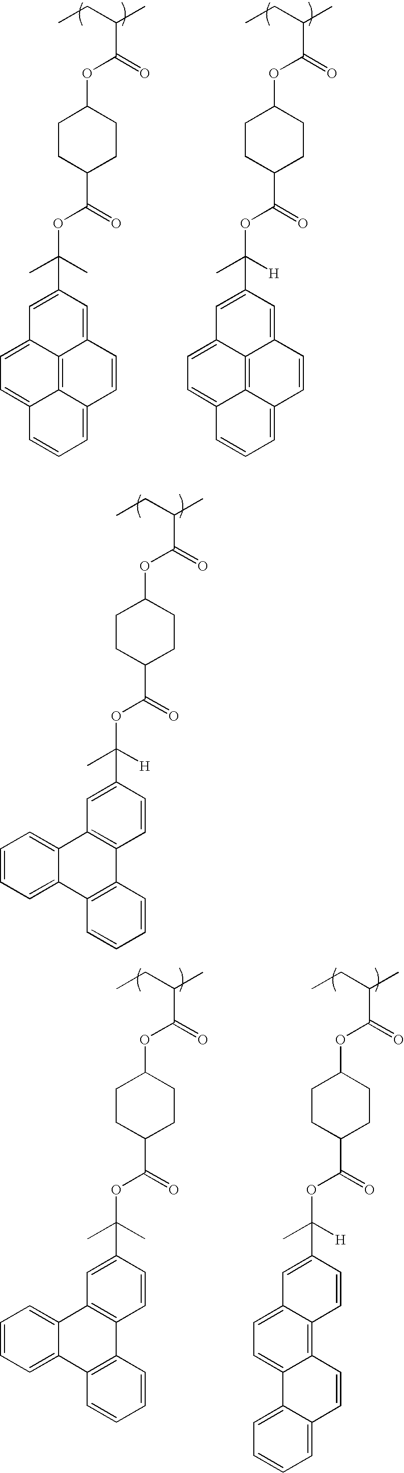

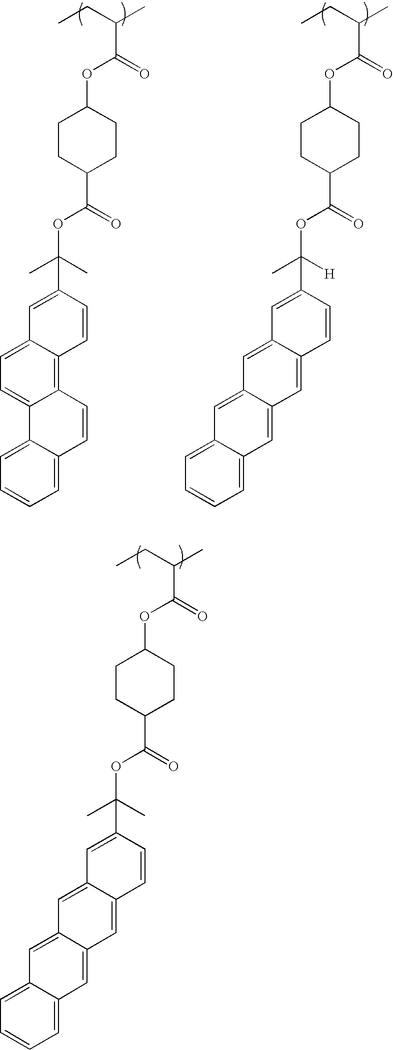

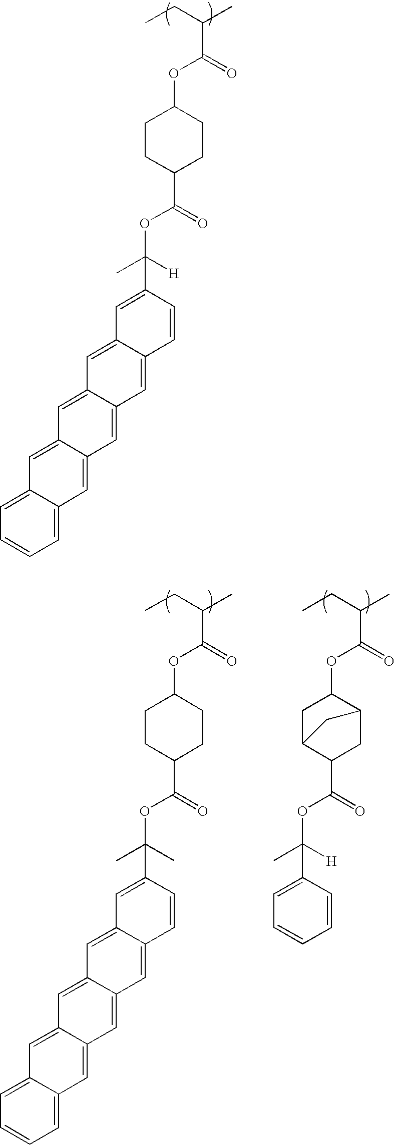

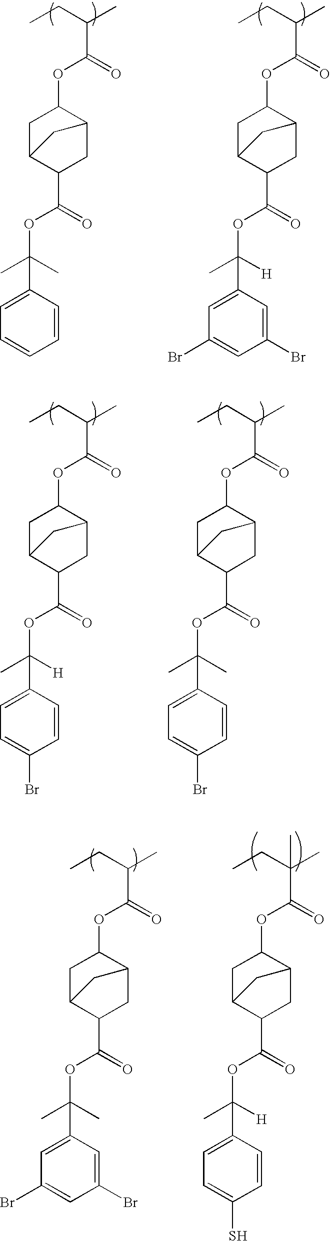

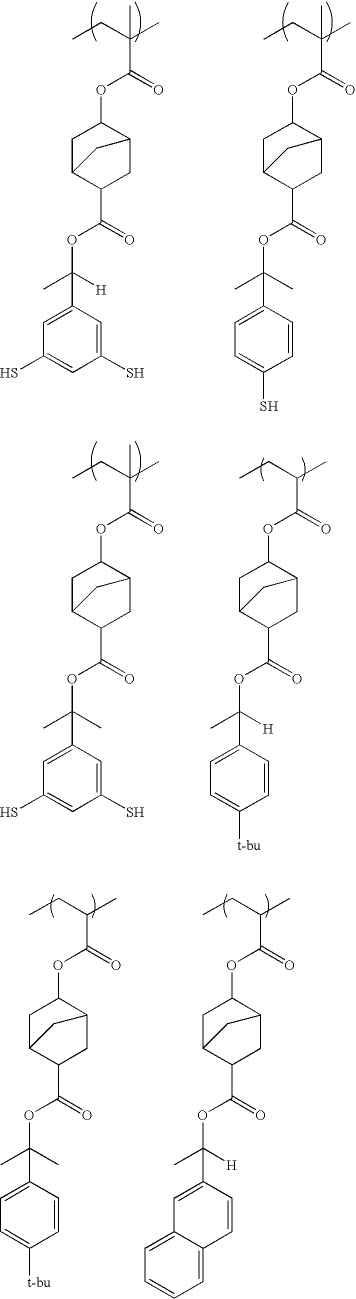

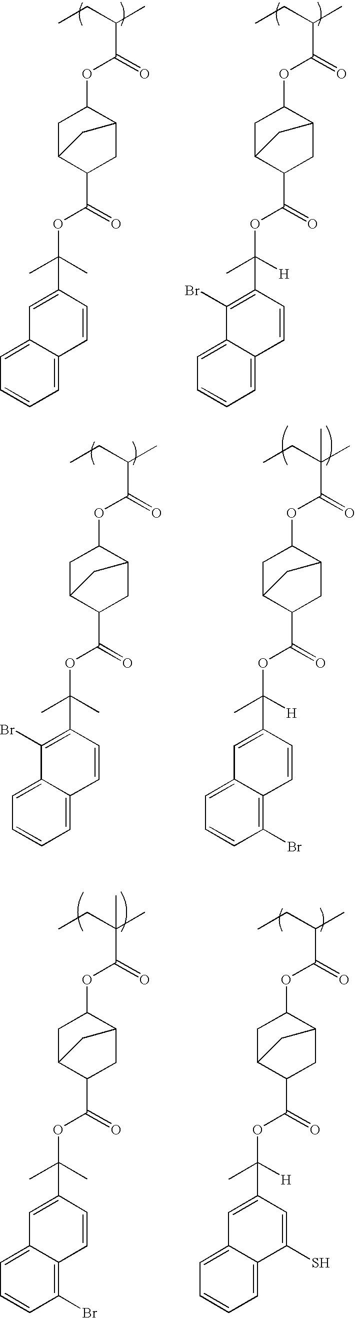

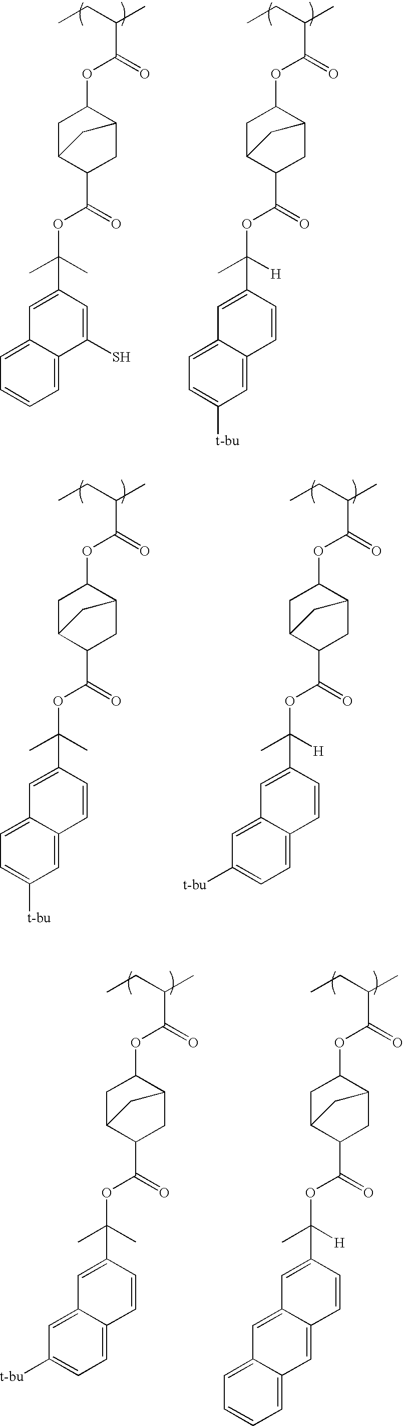

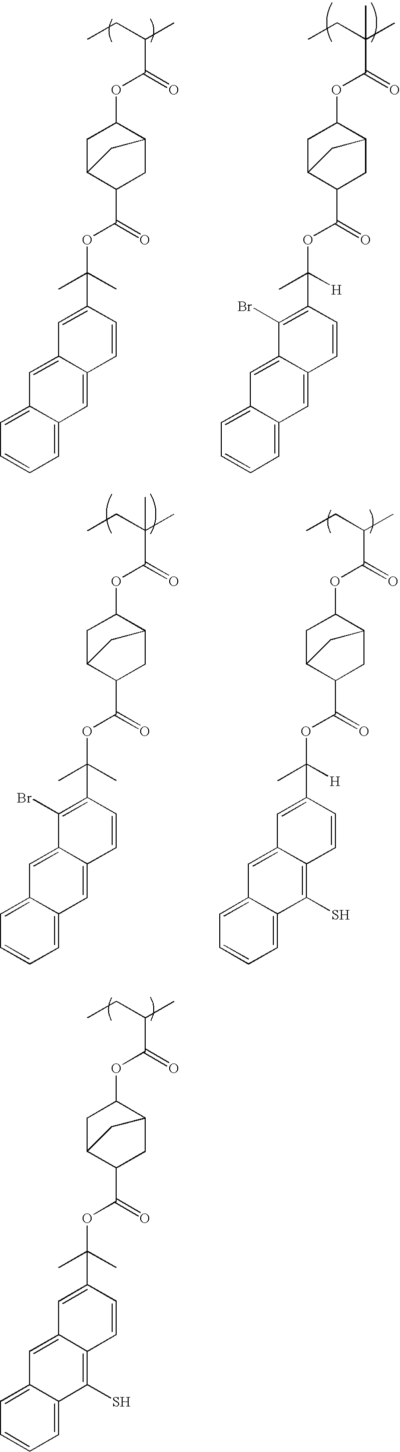

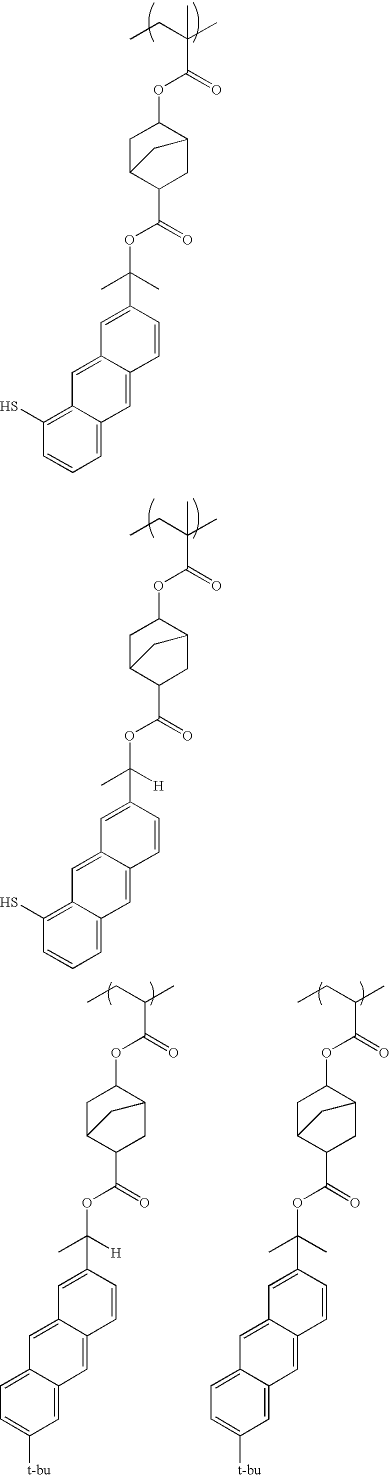

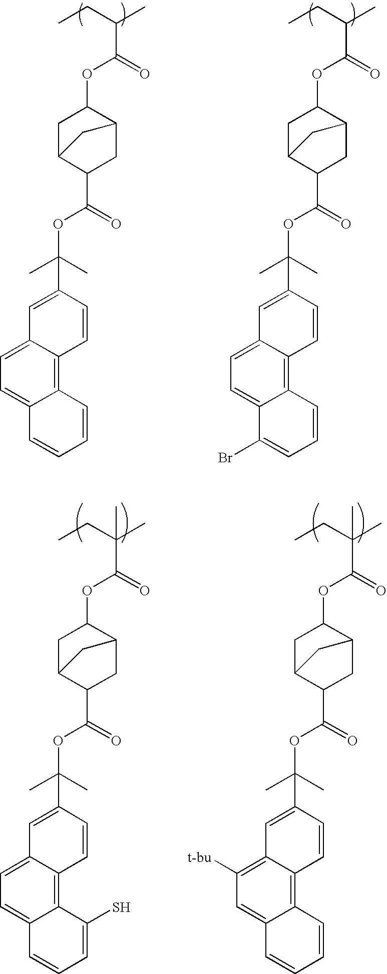

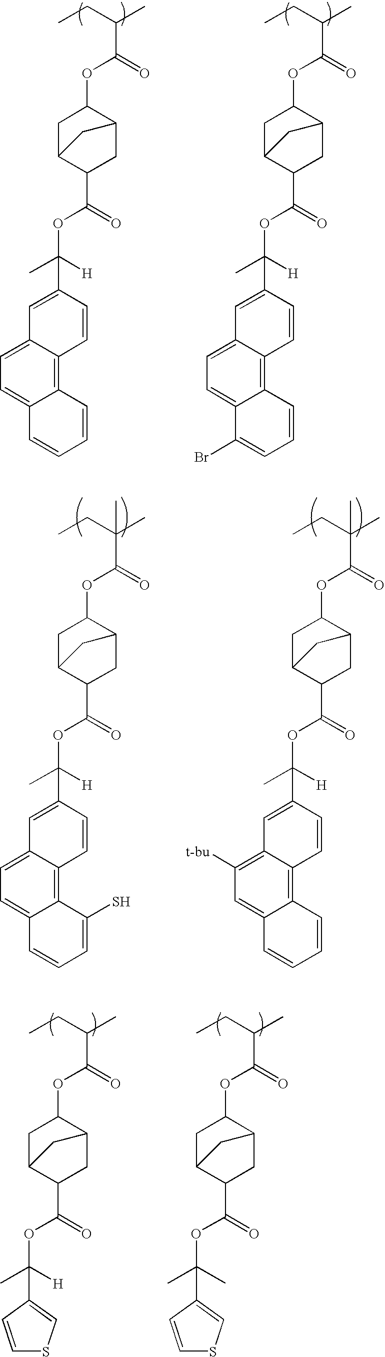

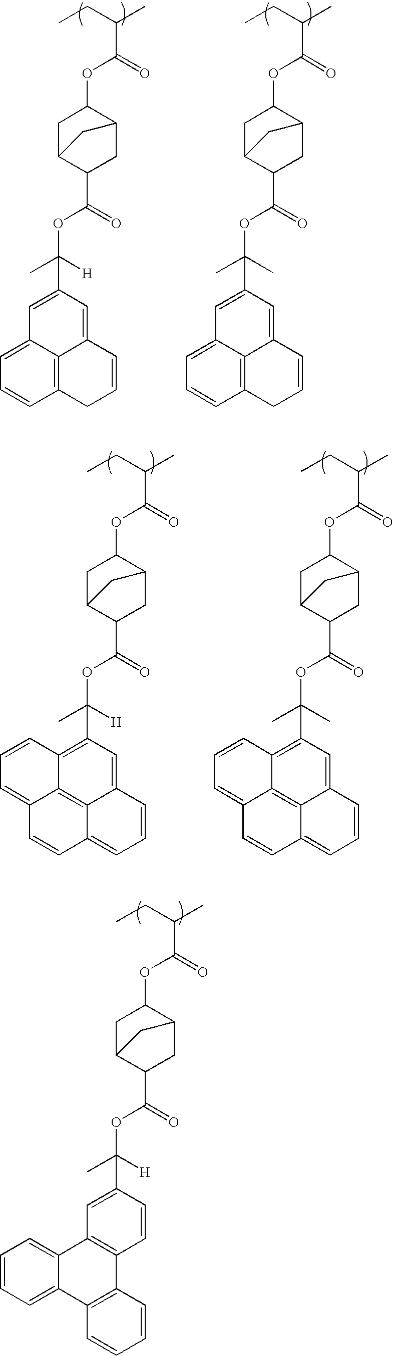

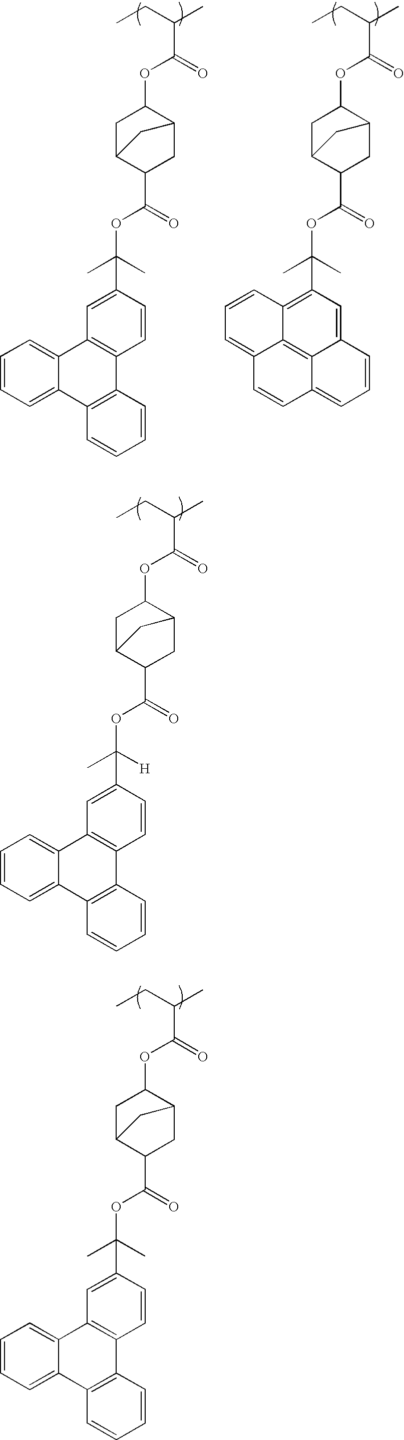

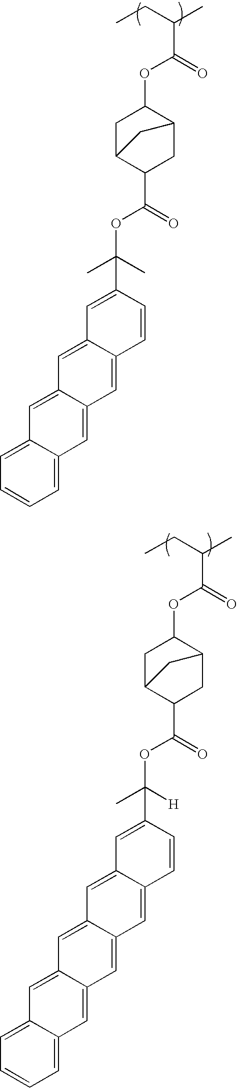

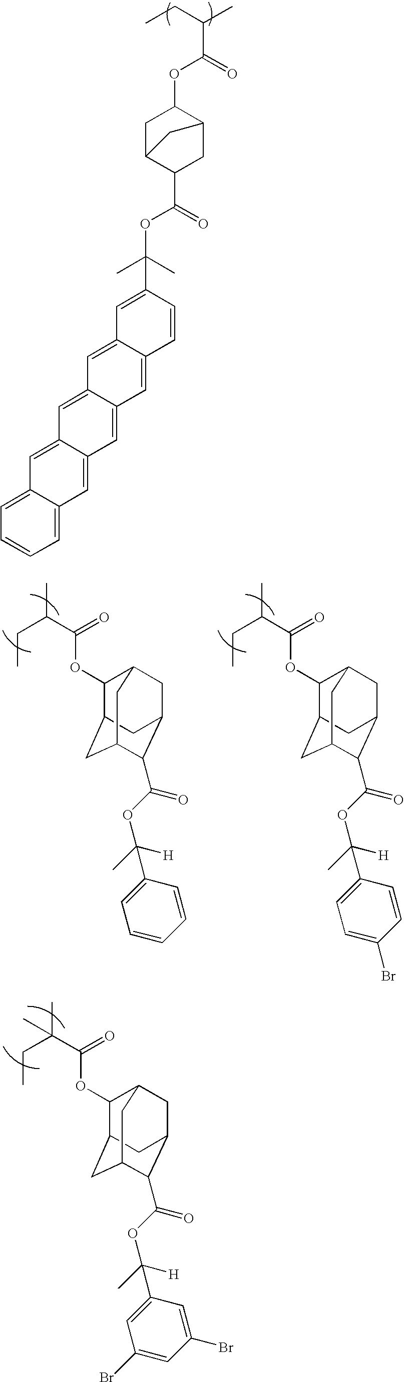

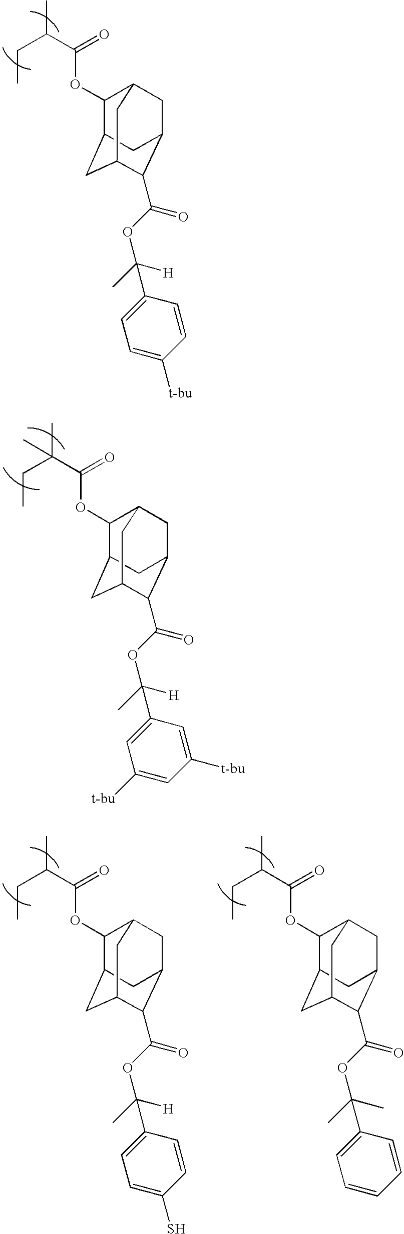

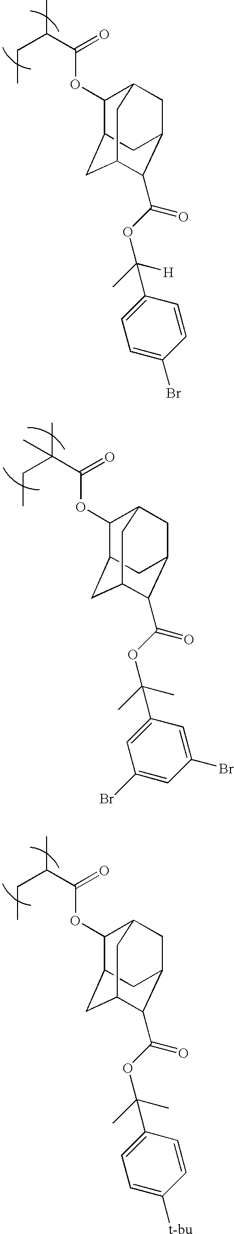

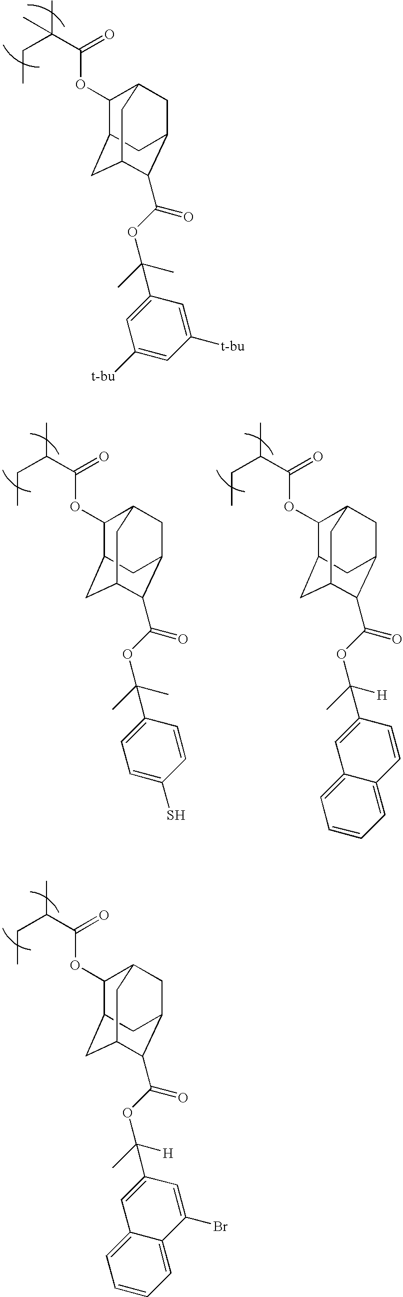

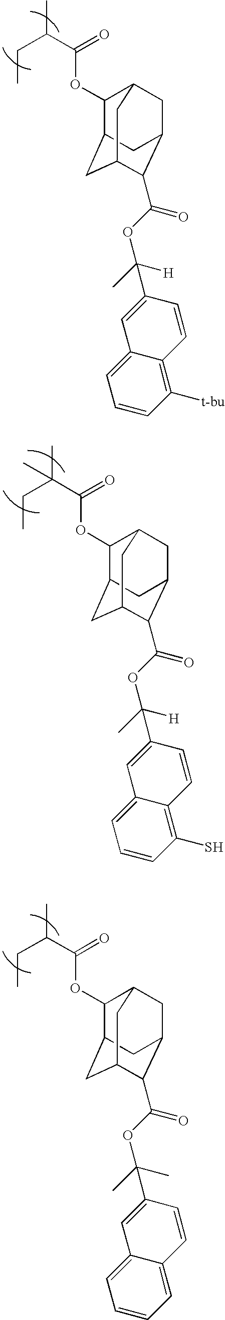

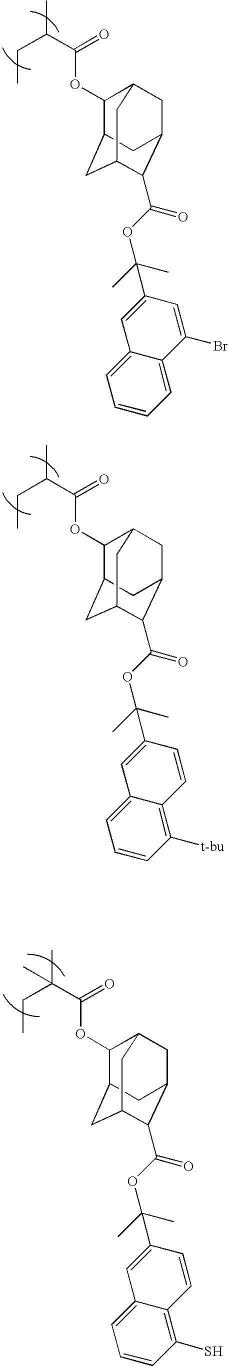

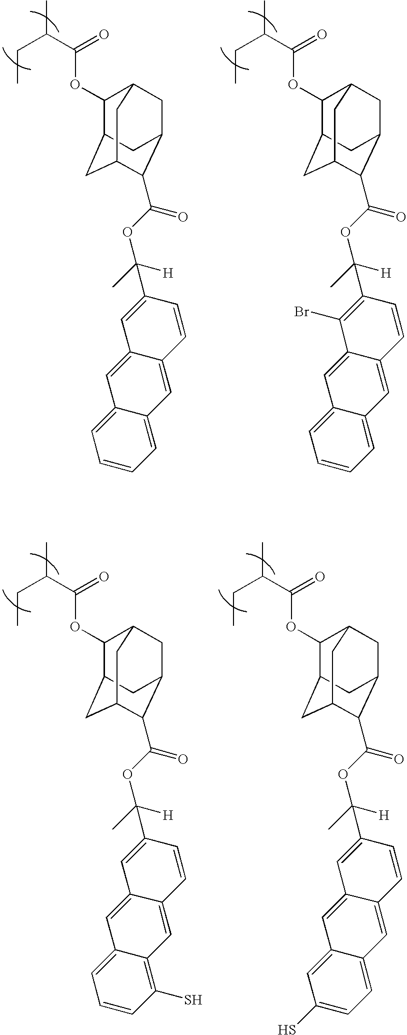

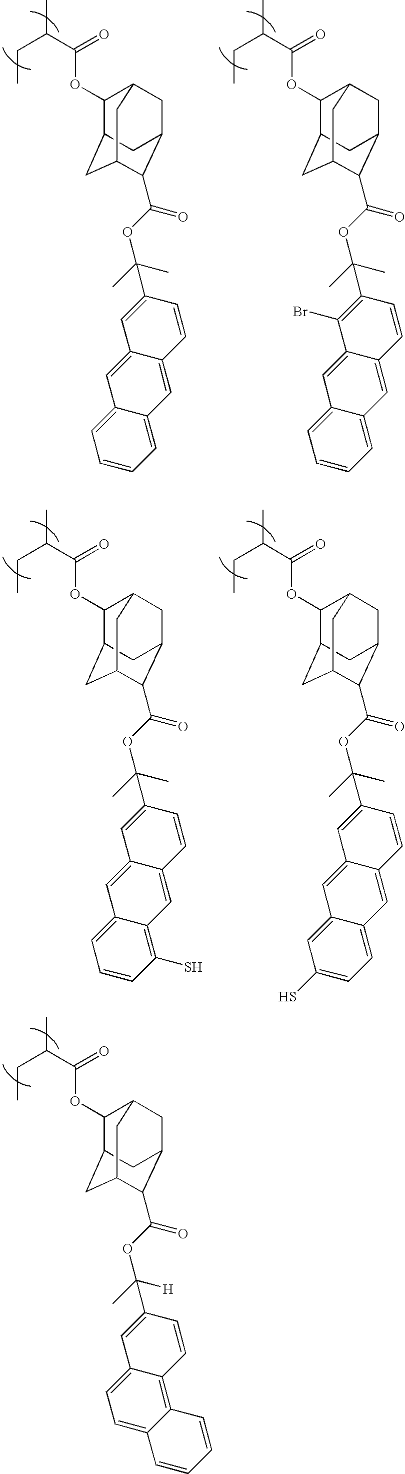

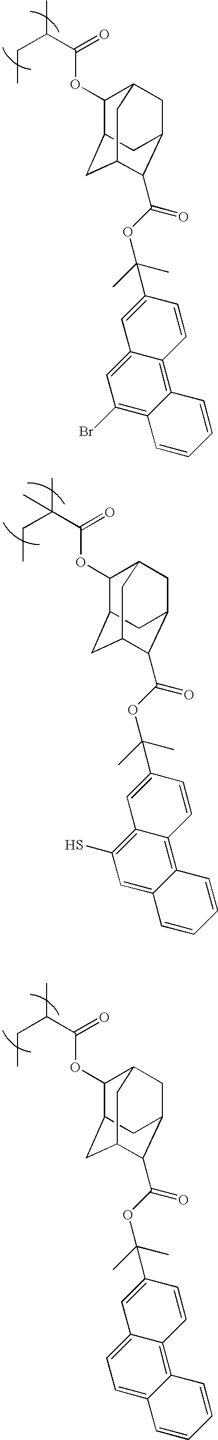

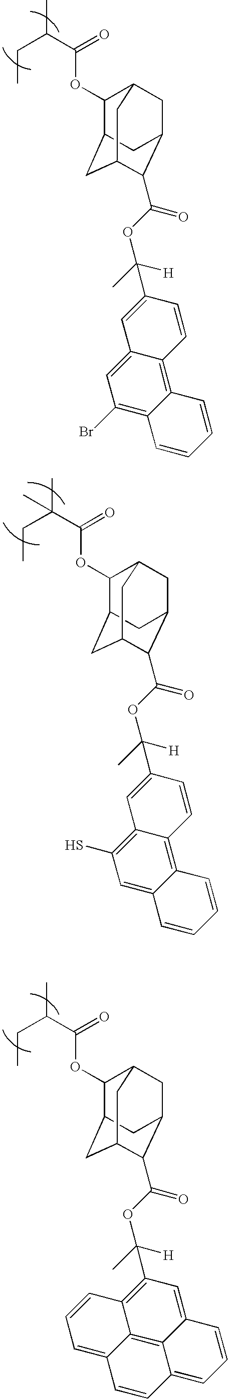

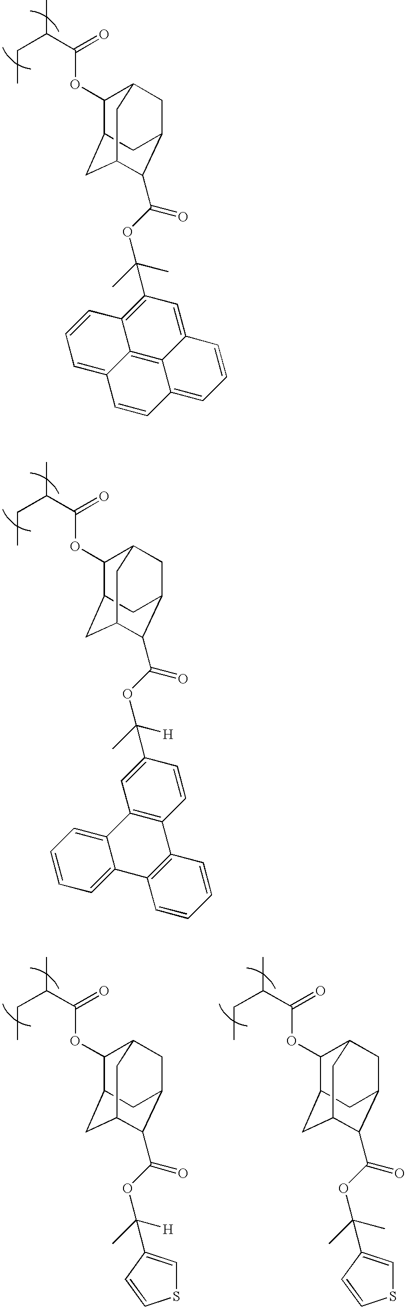

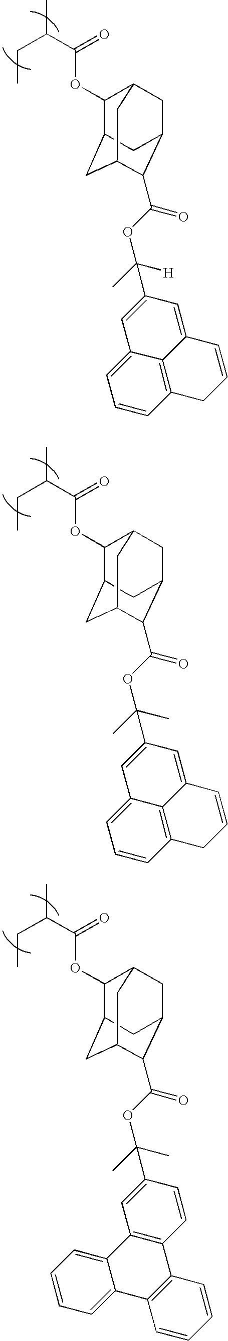

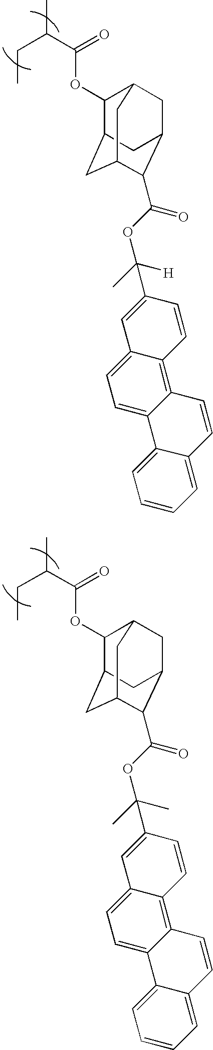

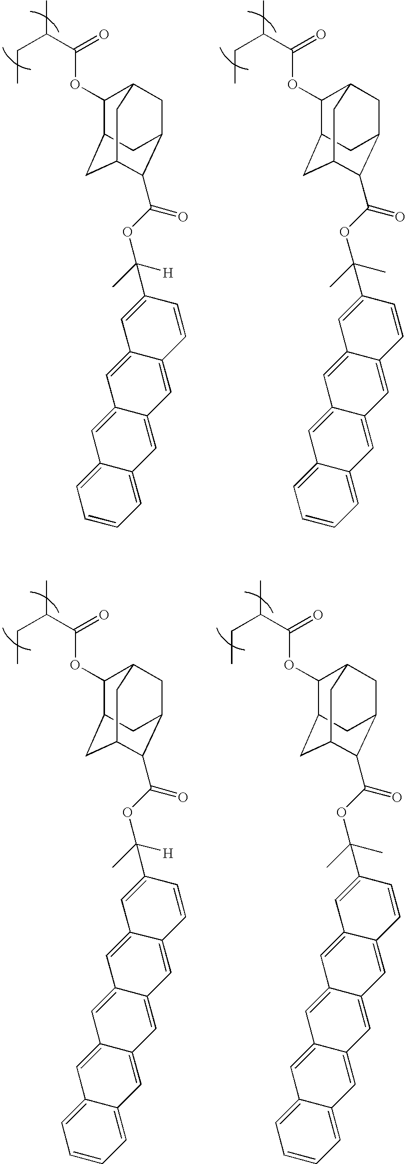

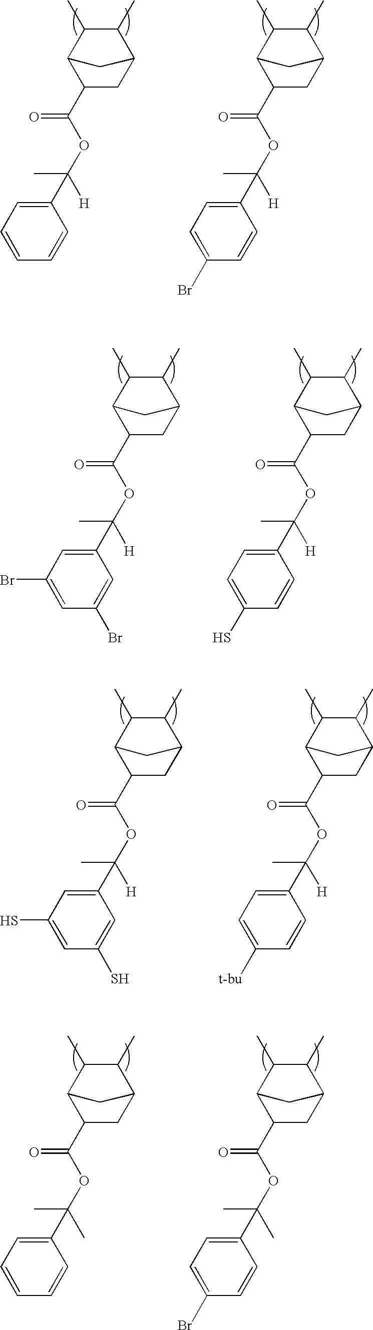

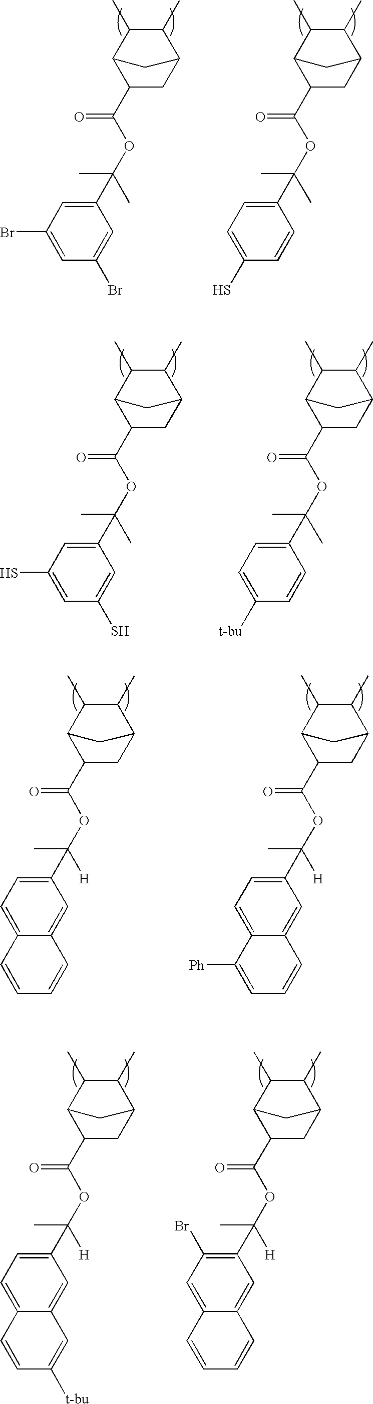

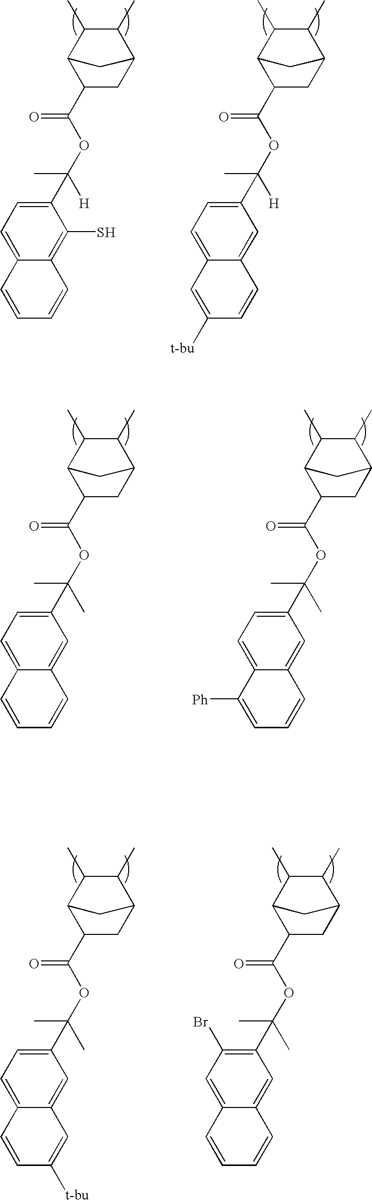

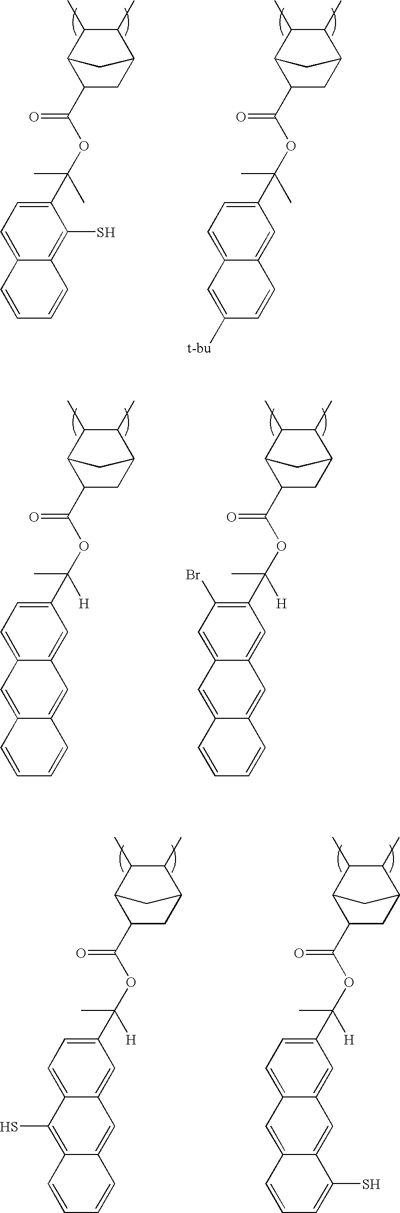

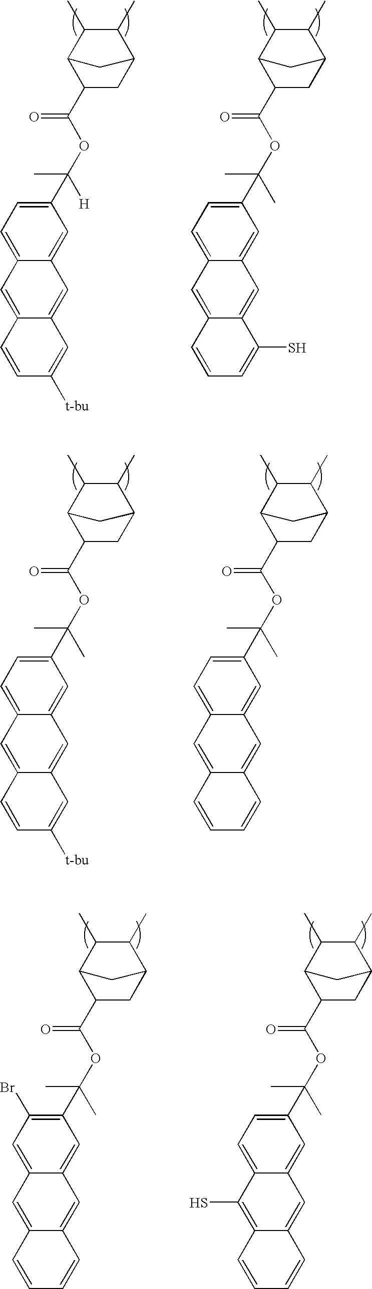

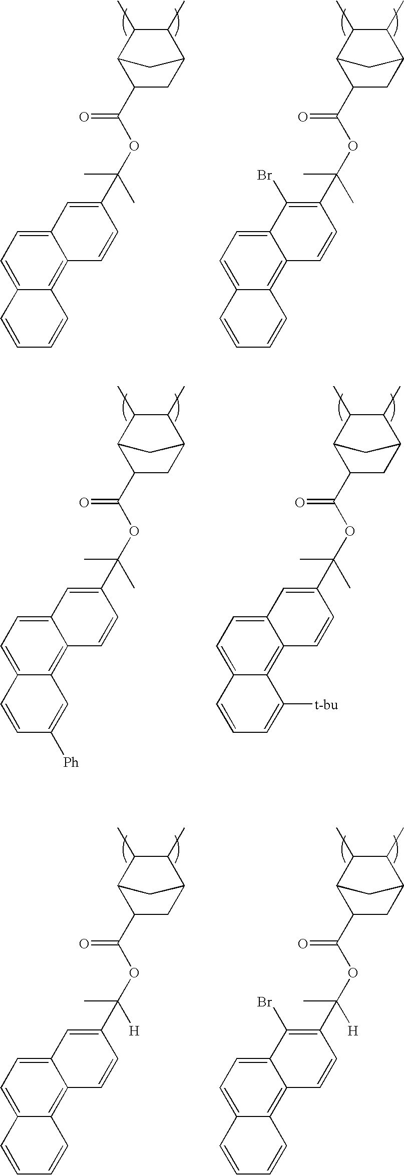

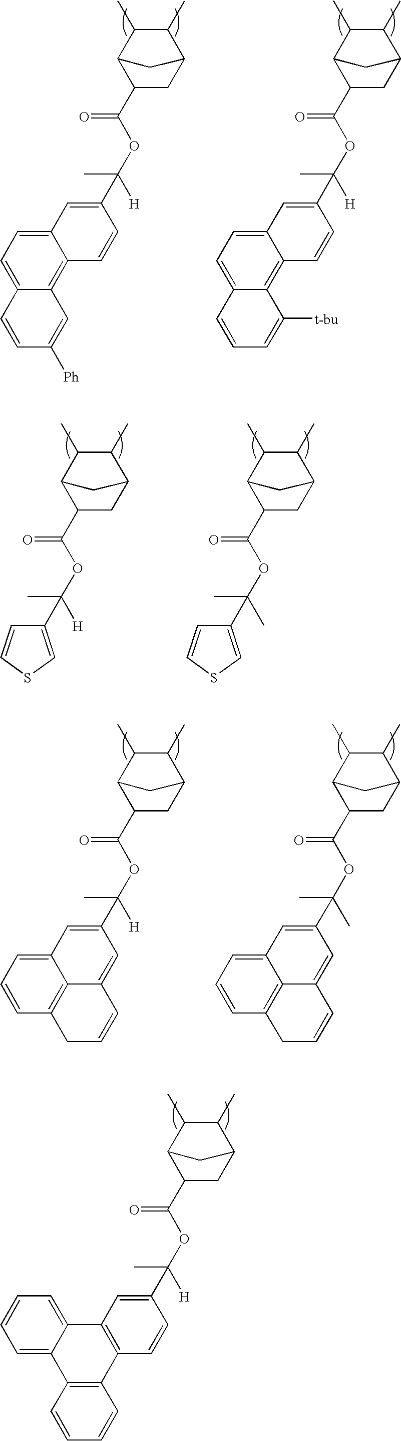

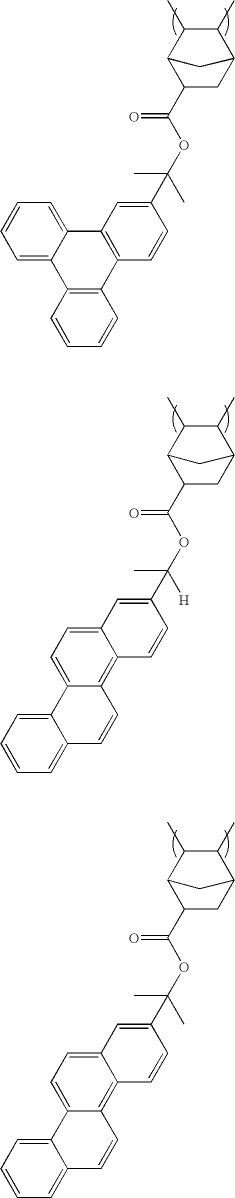

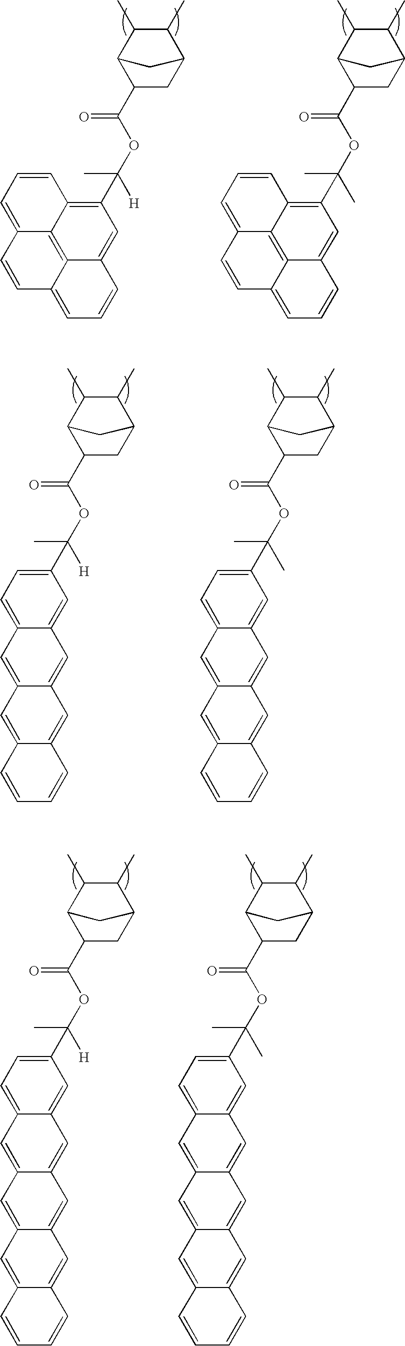

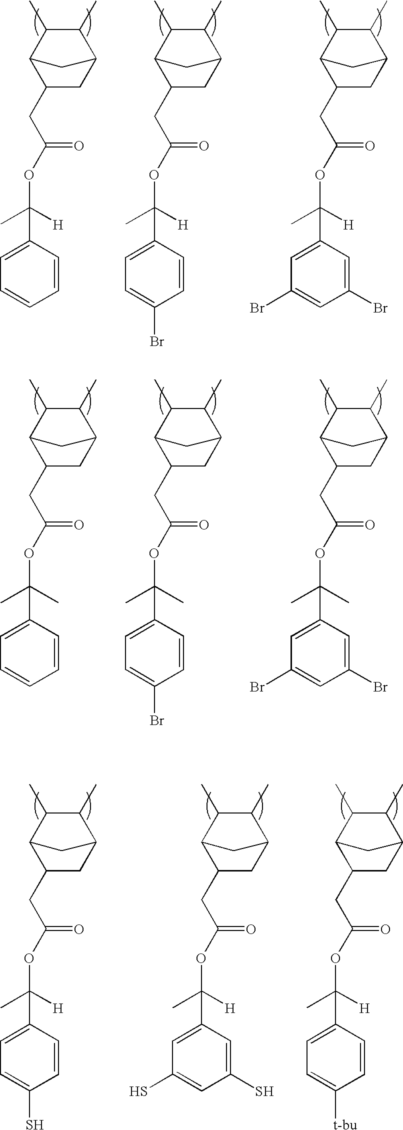

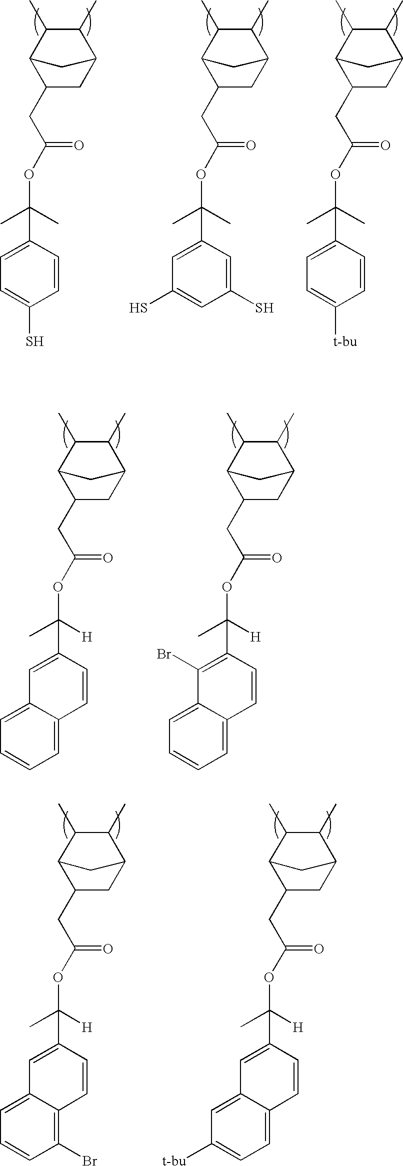

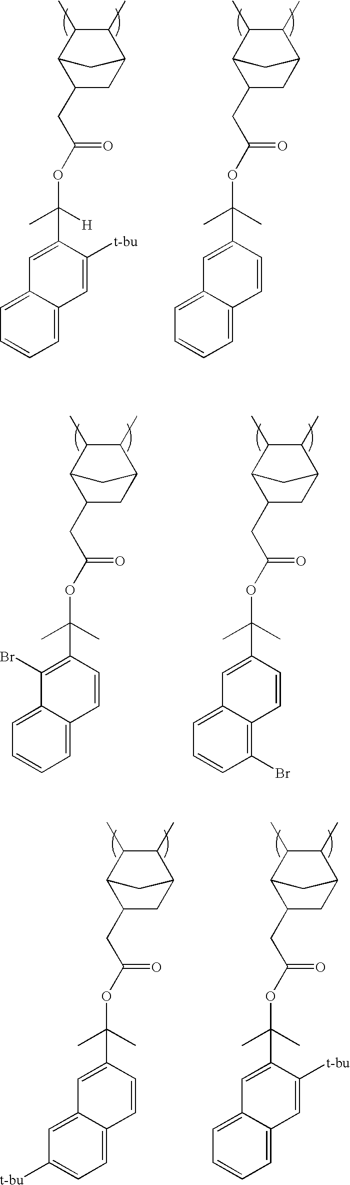

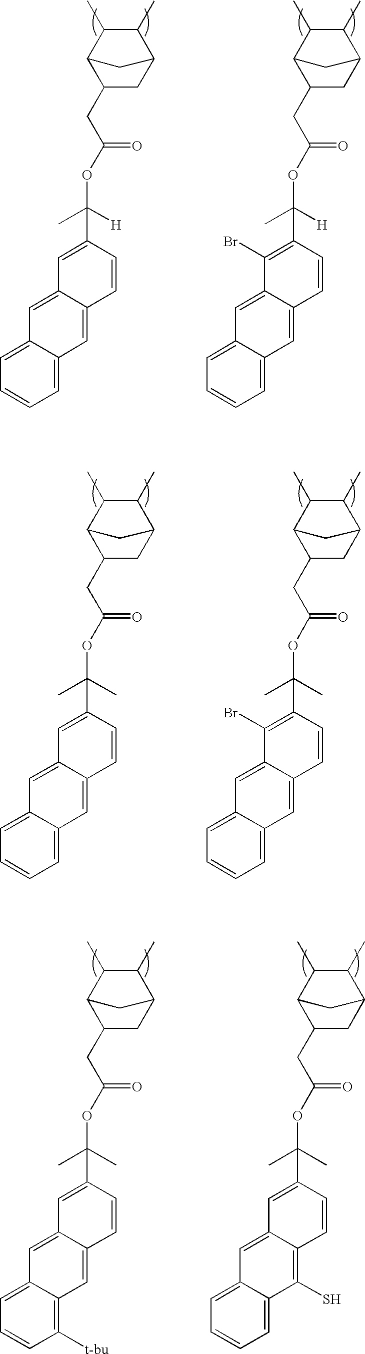

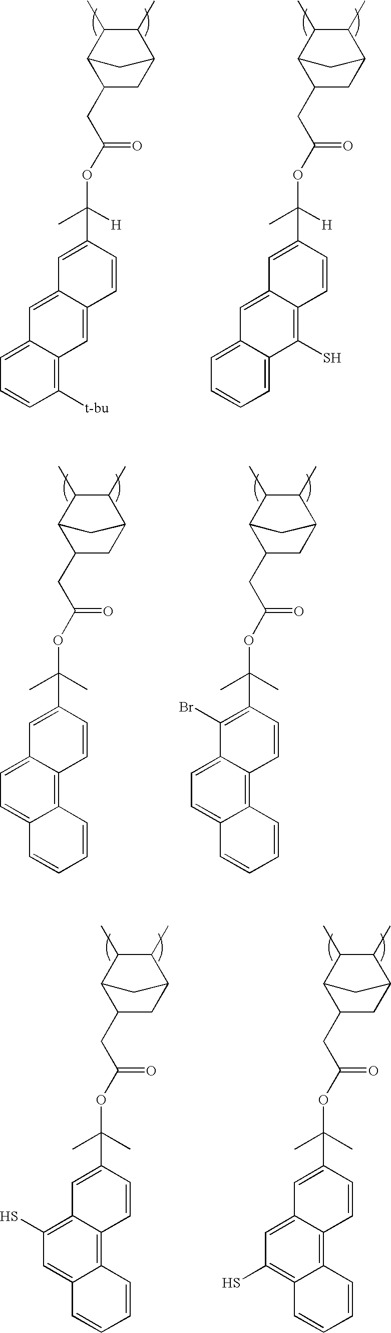

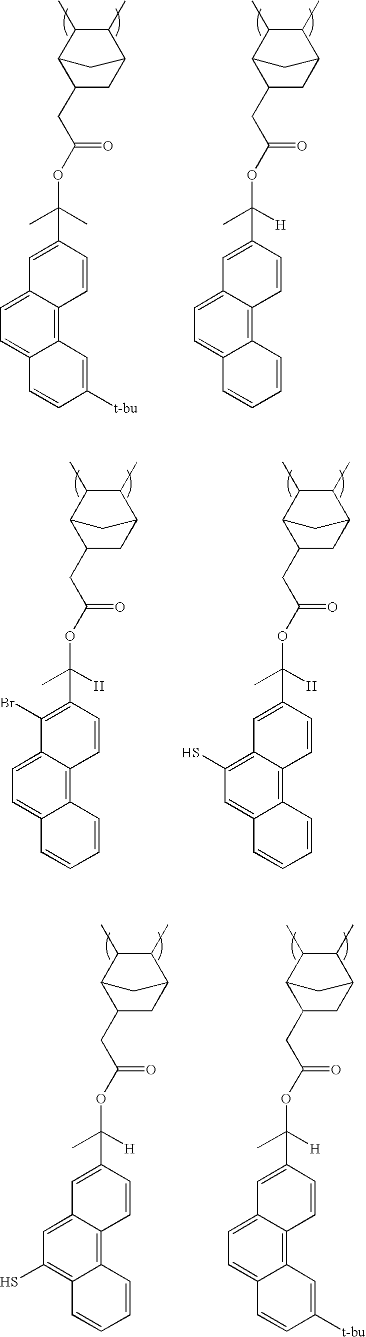

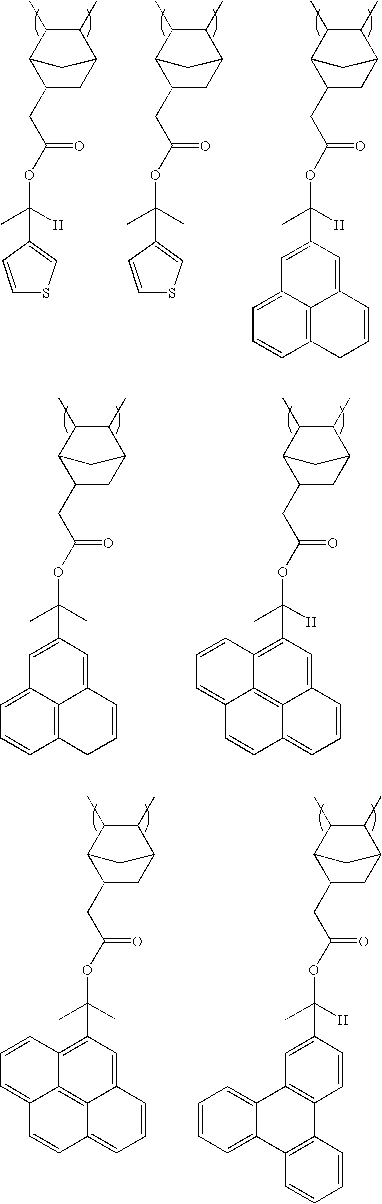

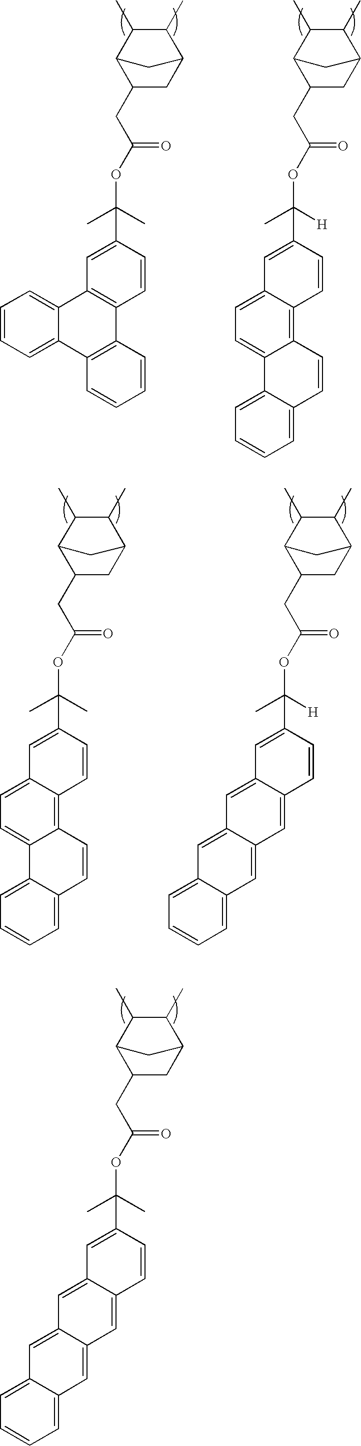

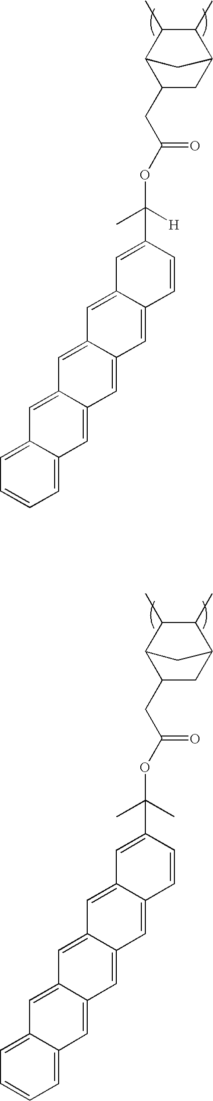

Specific examples of the repeating unit expressed by the general formula (2) are shown below.

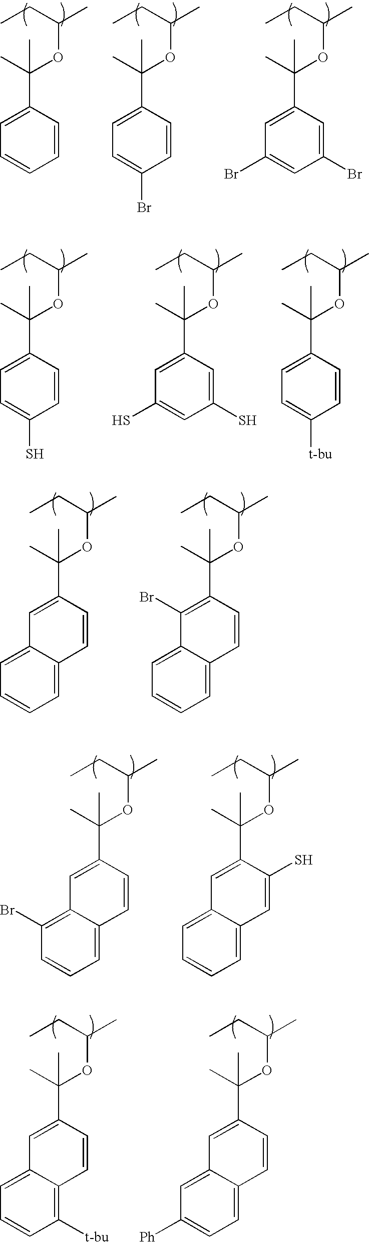

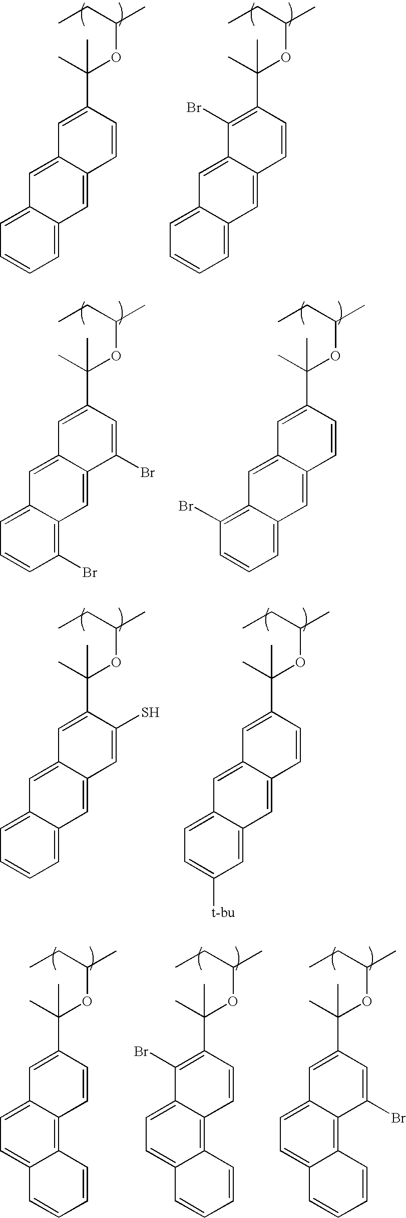

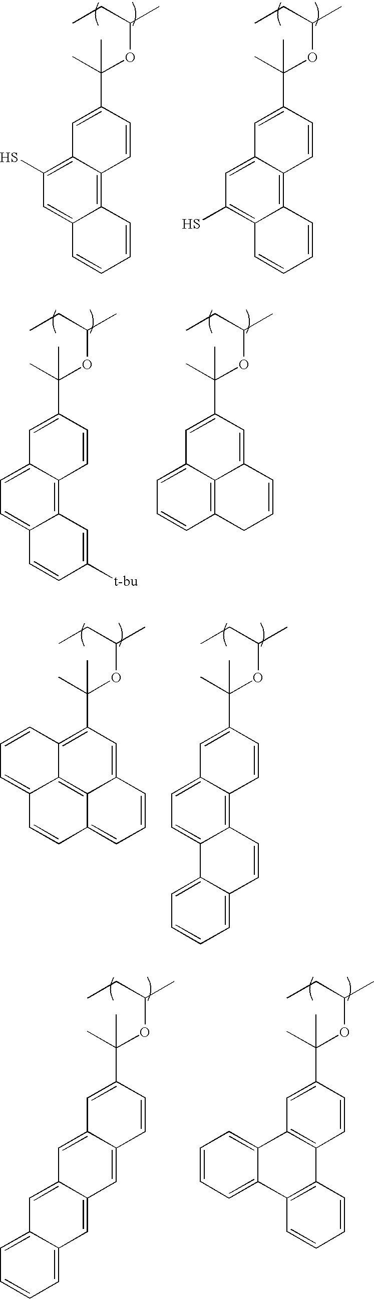

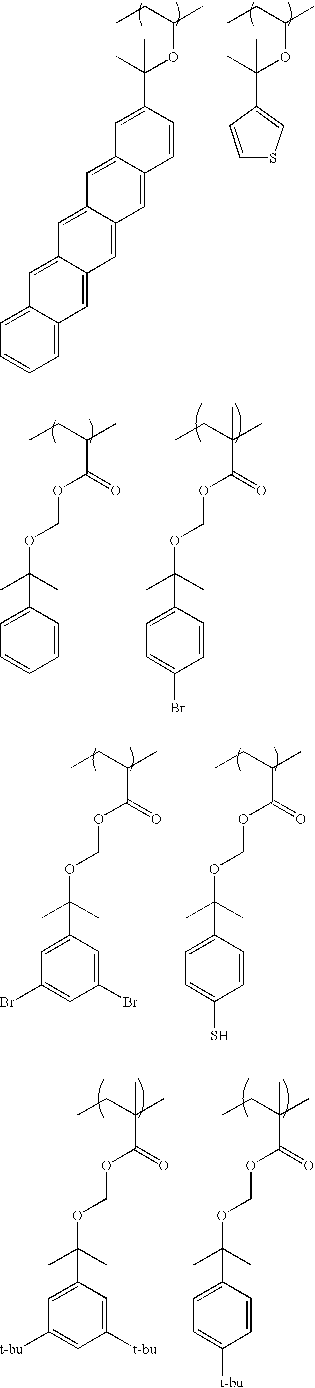

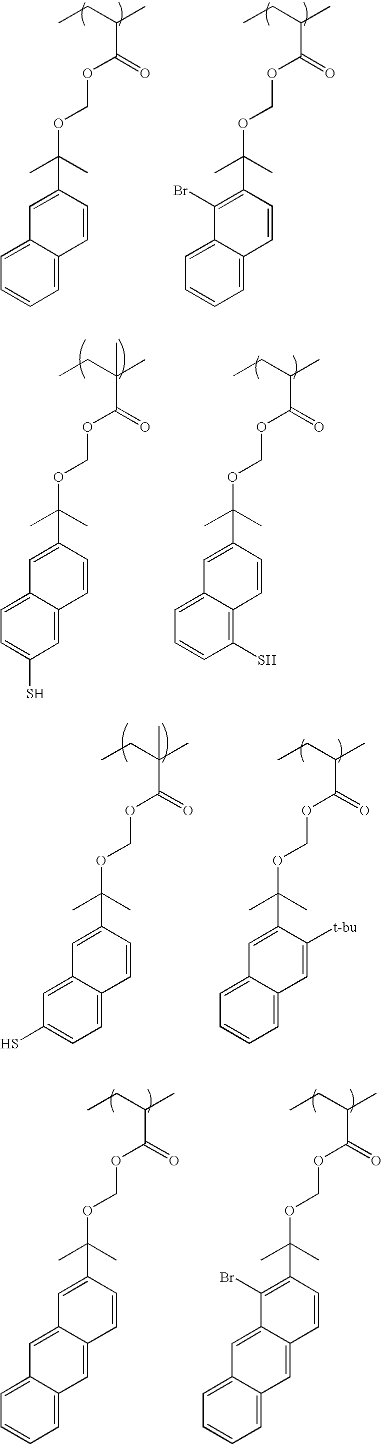

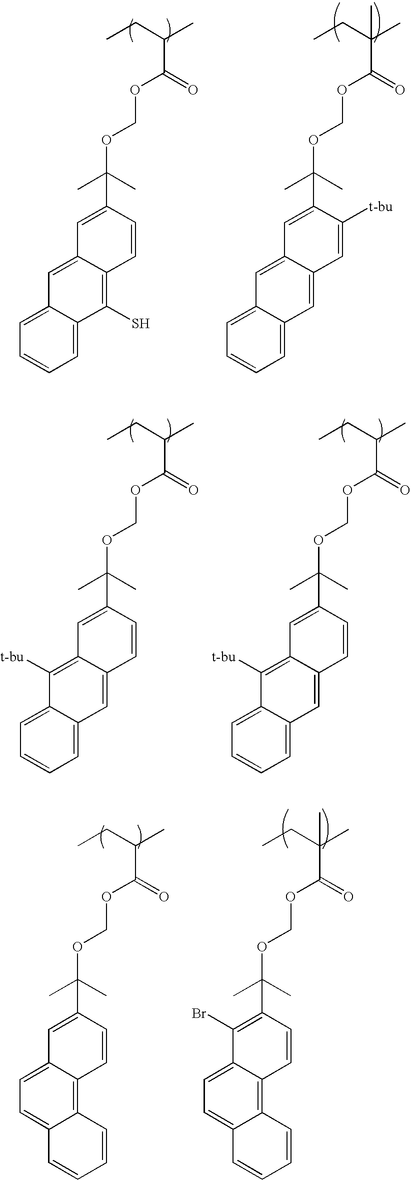

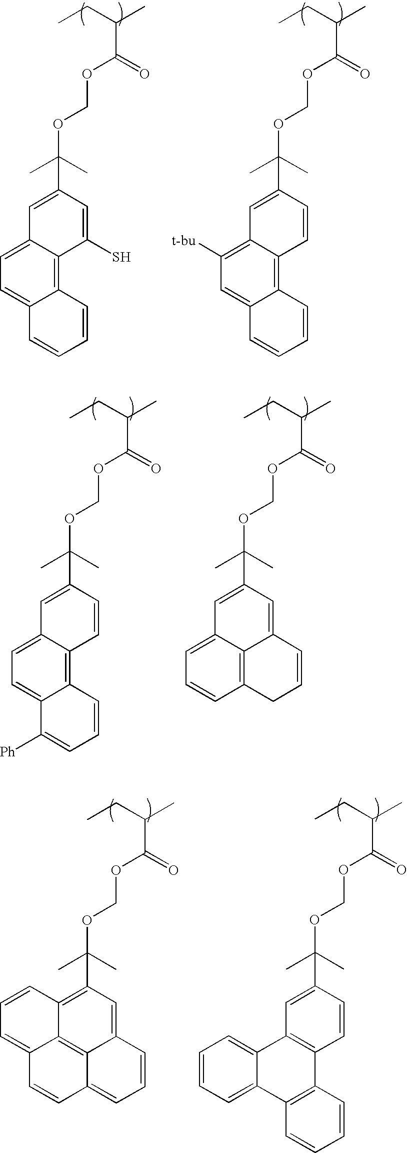

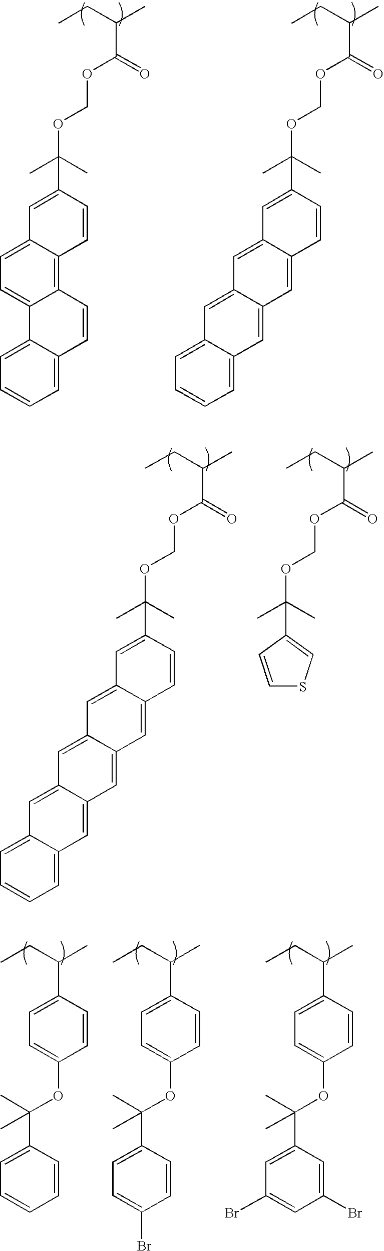

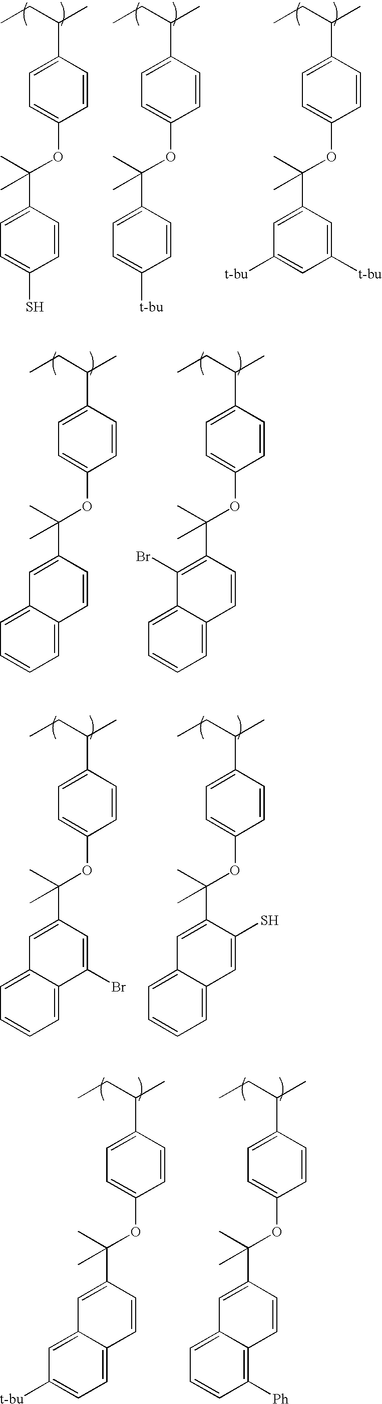

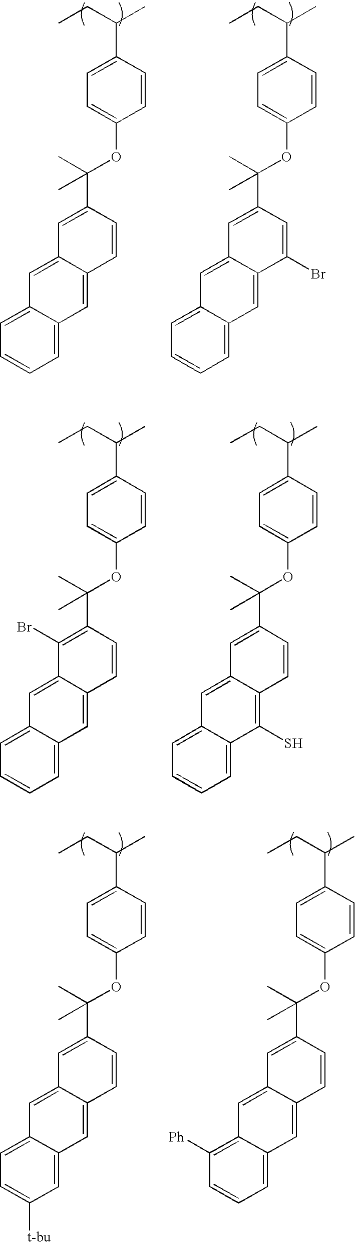

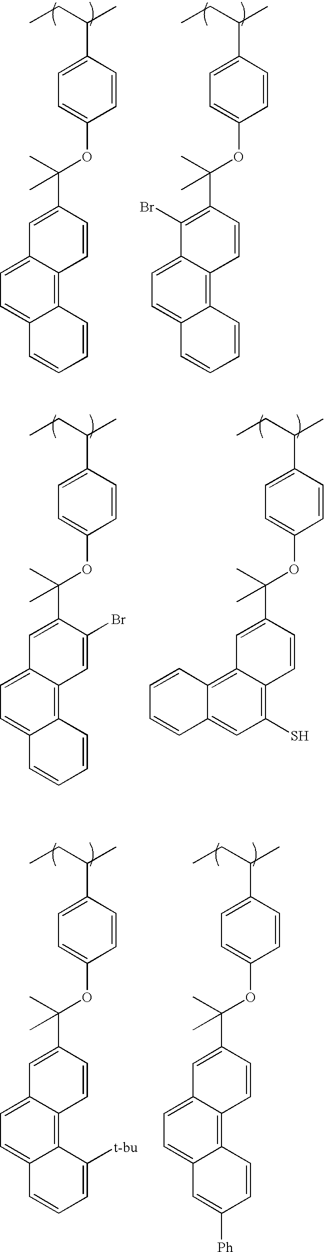

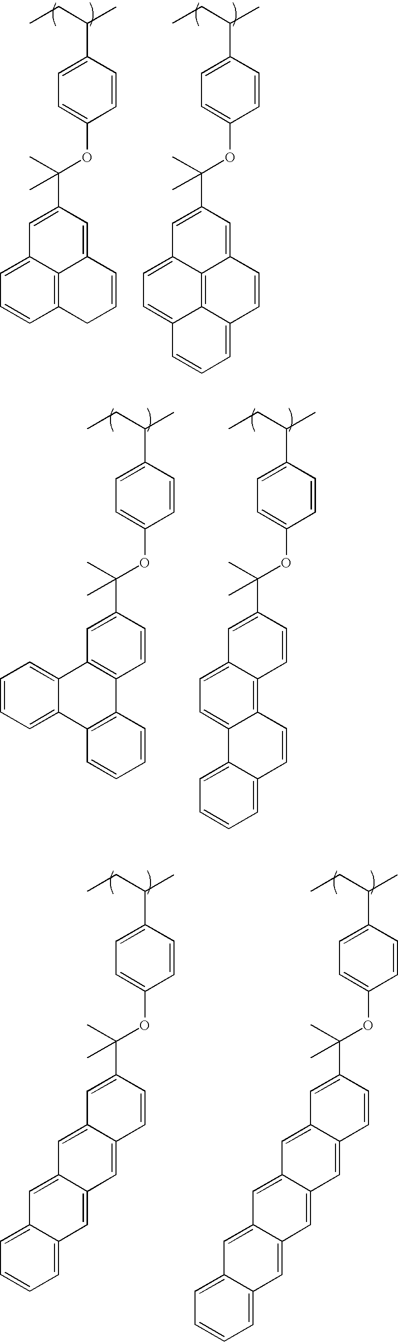

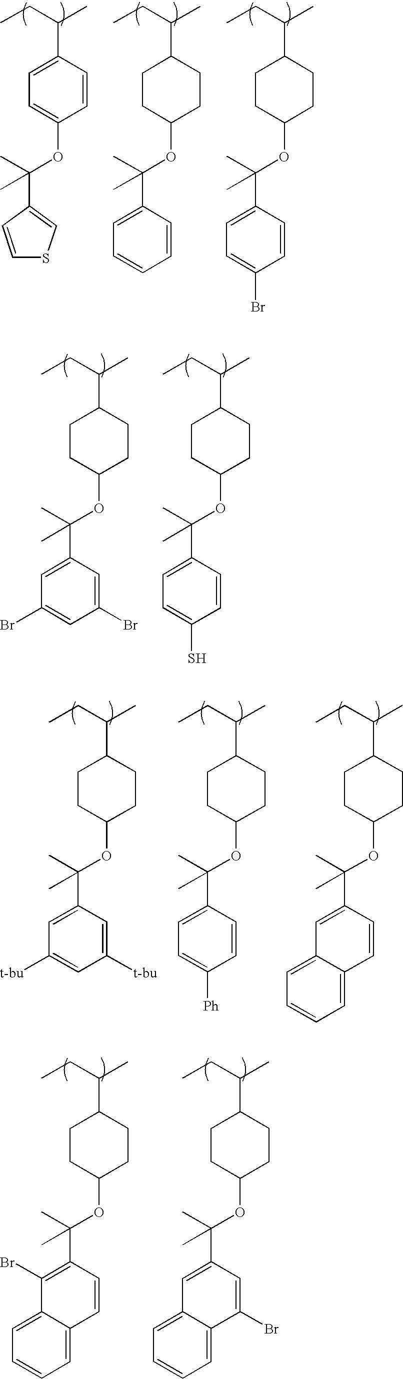

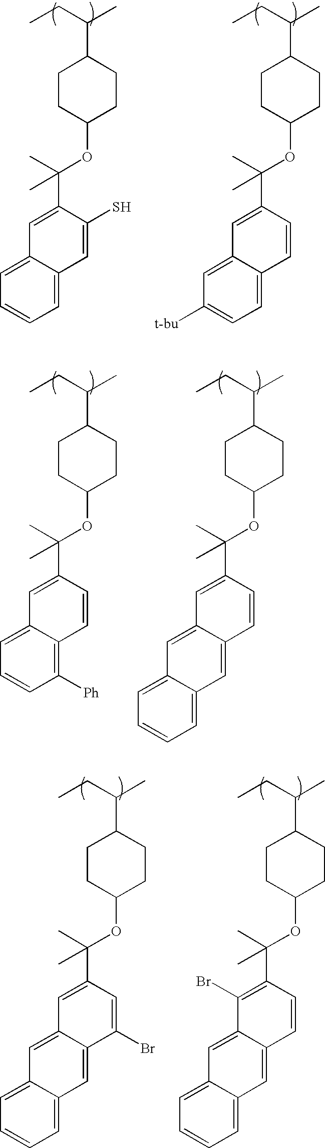

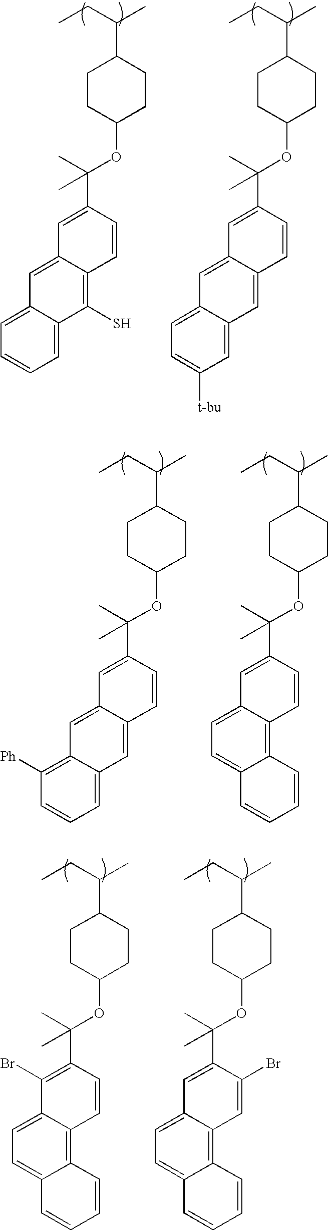

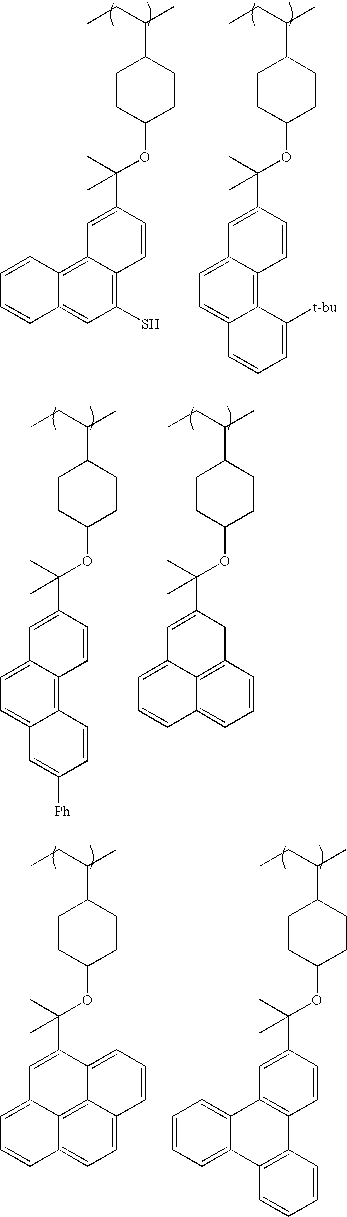

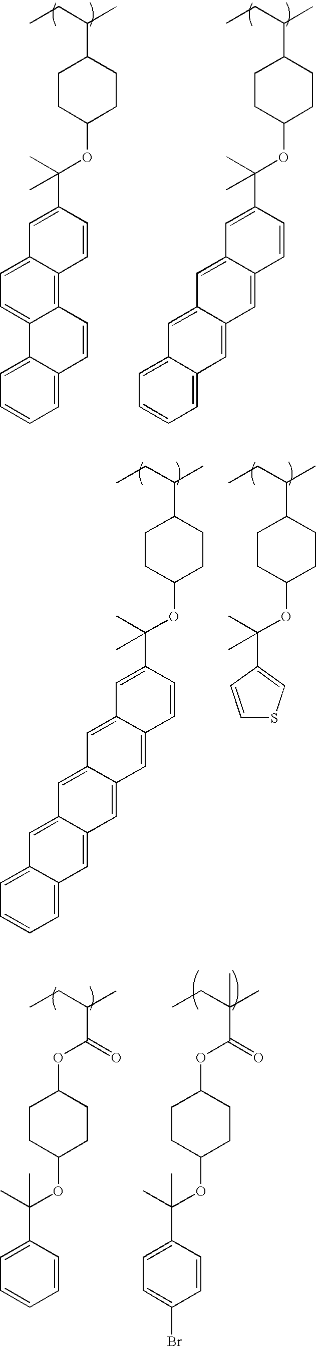

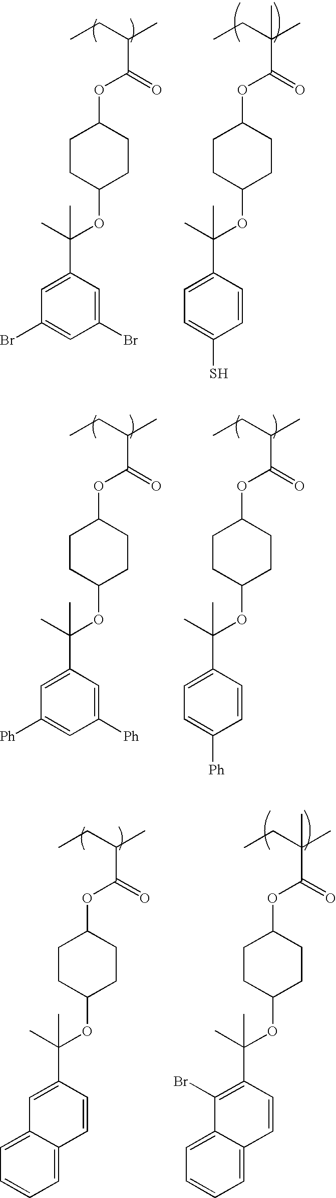

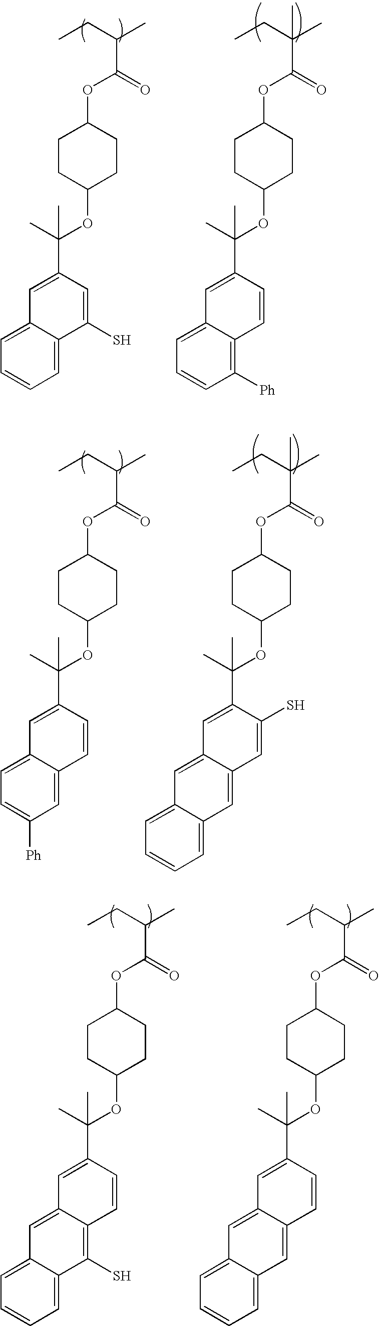

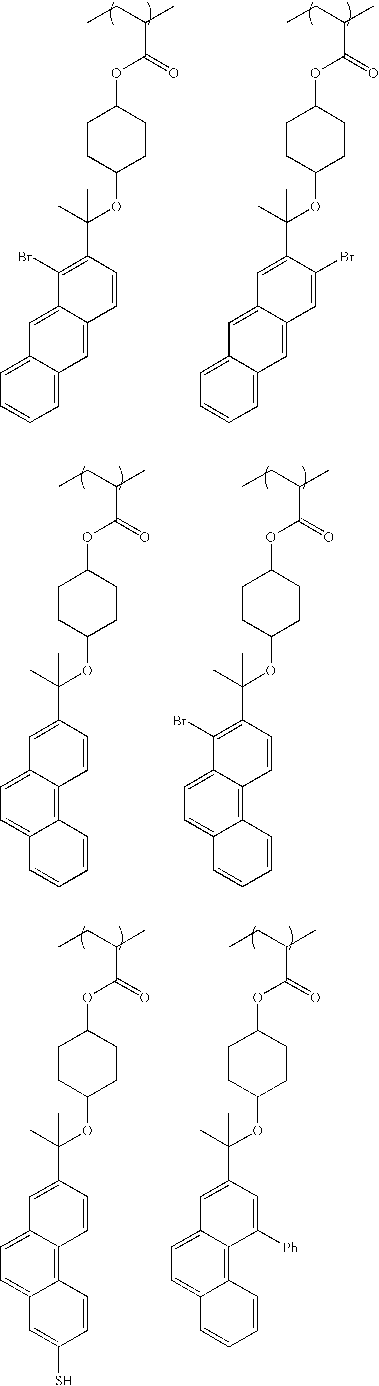

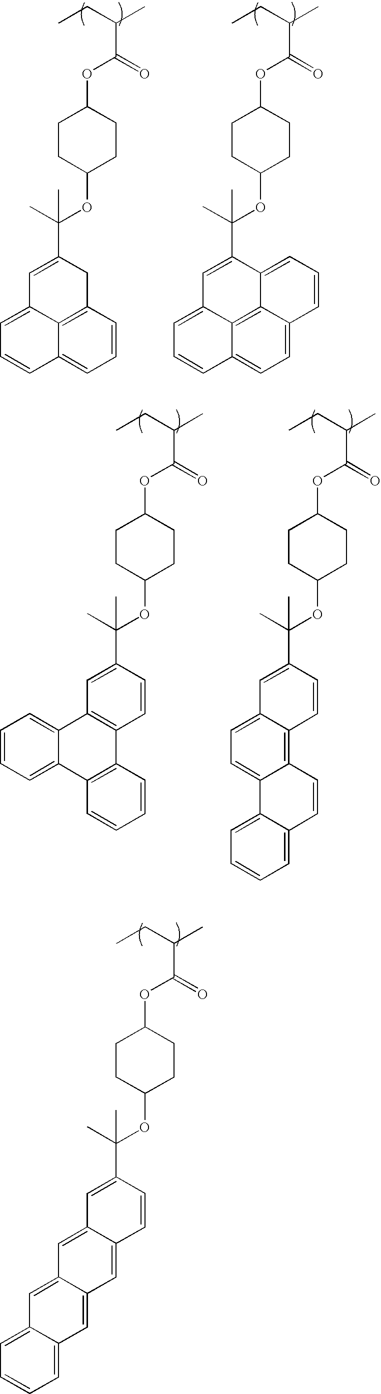

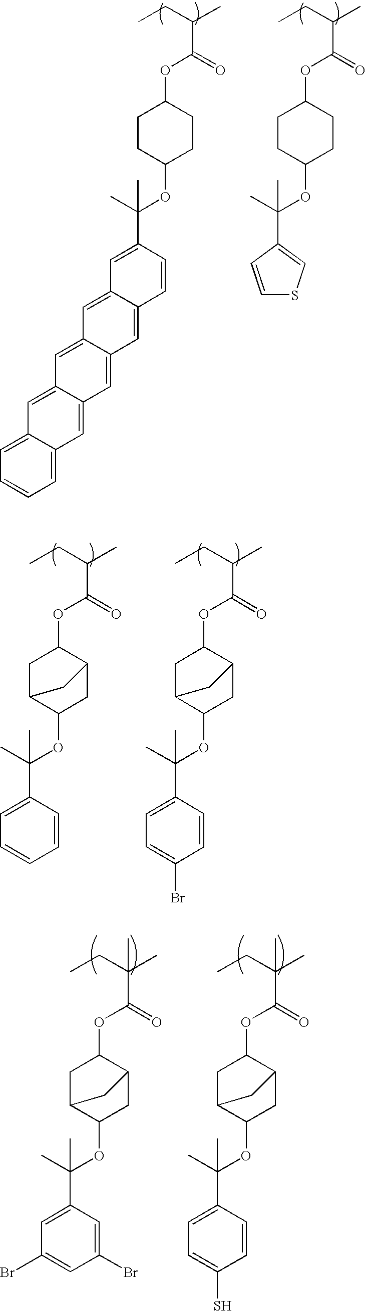

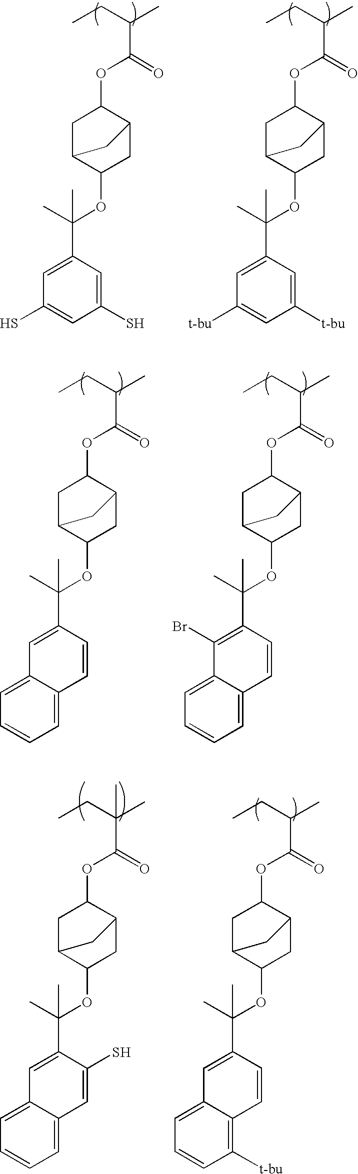

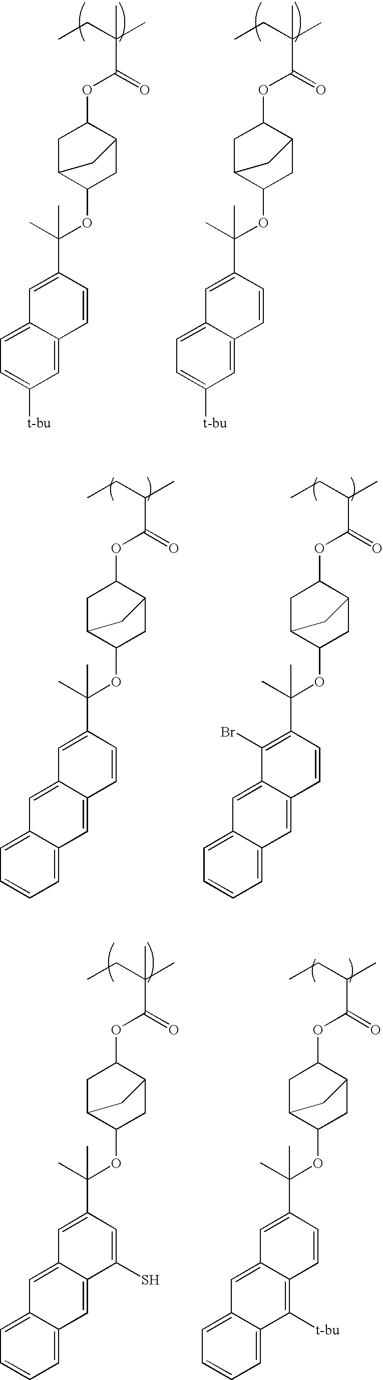

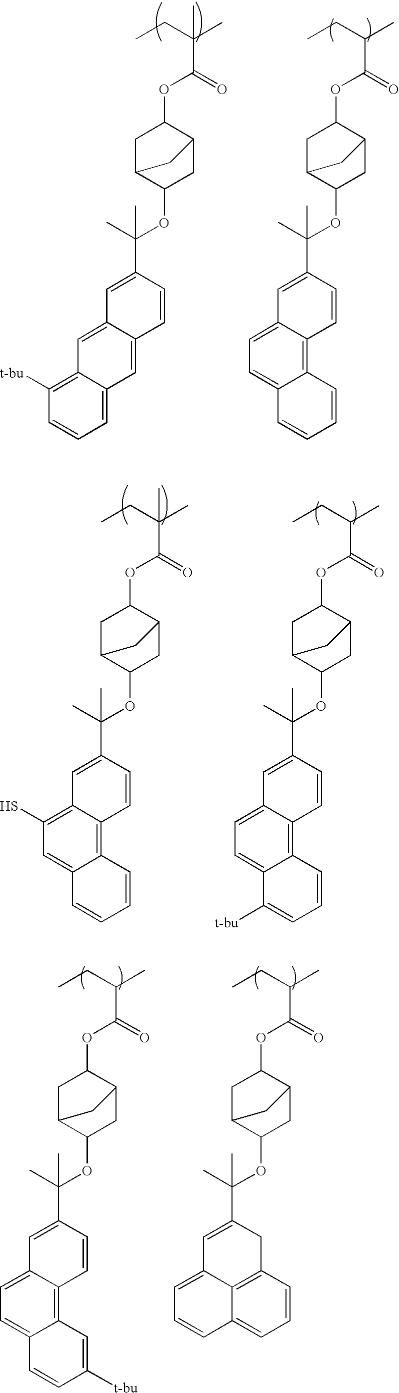

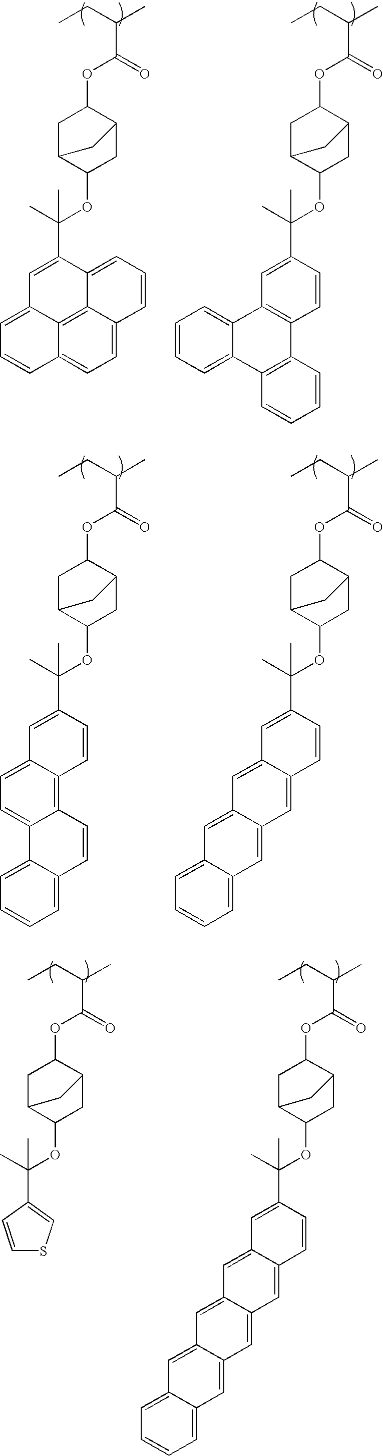

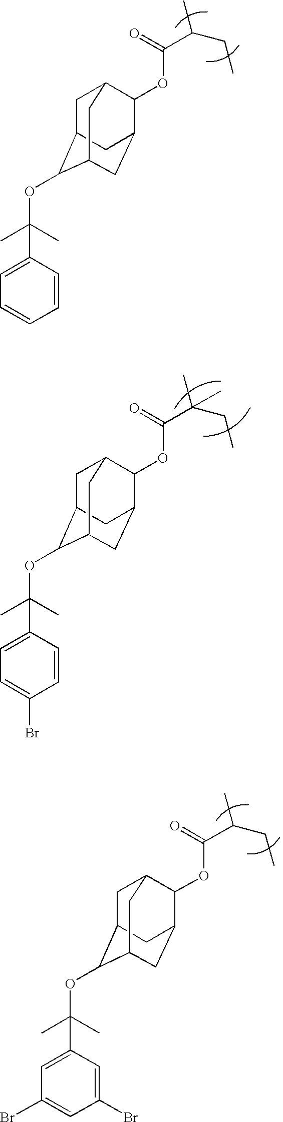

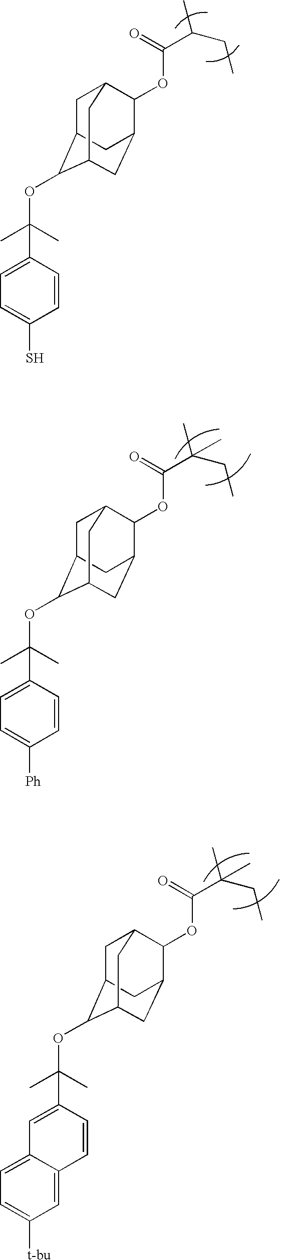

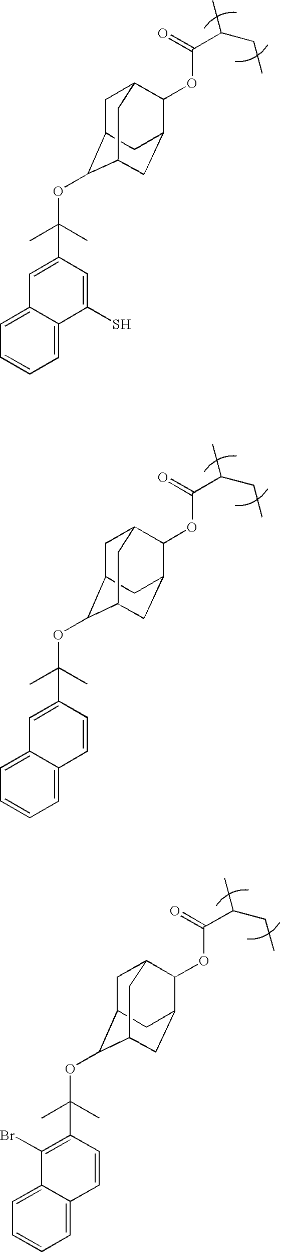

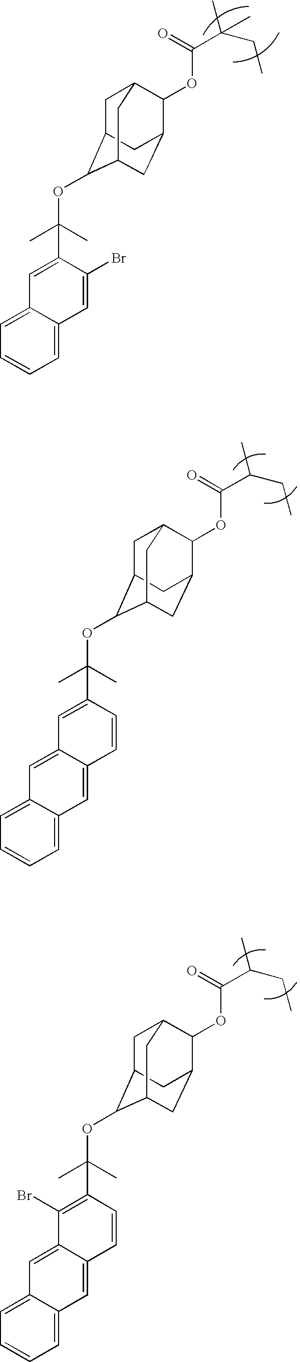

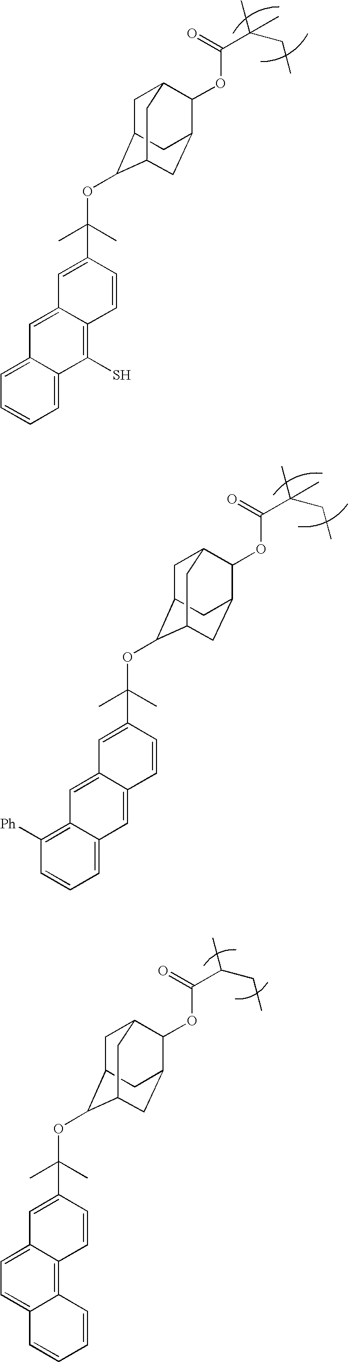

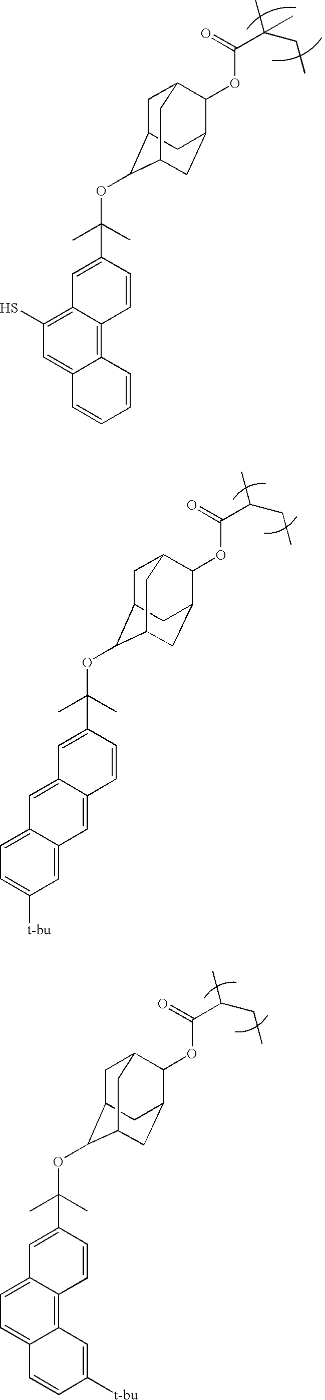

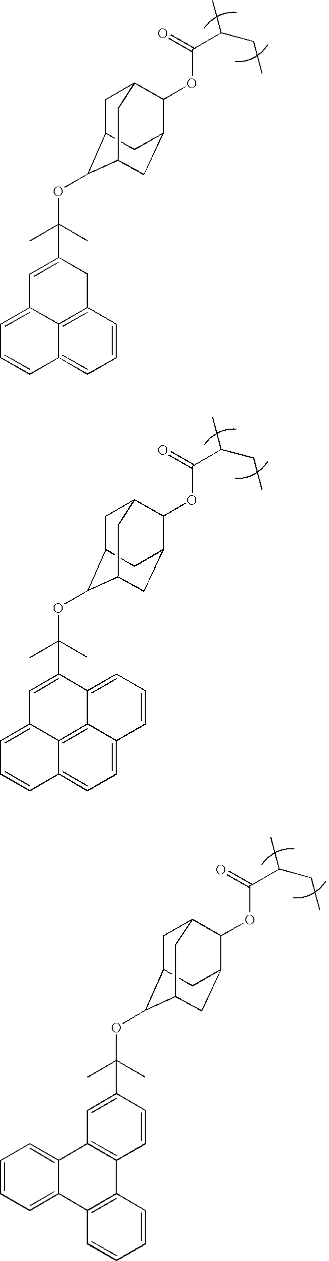

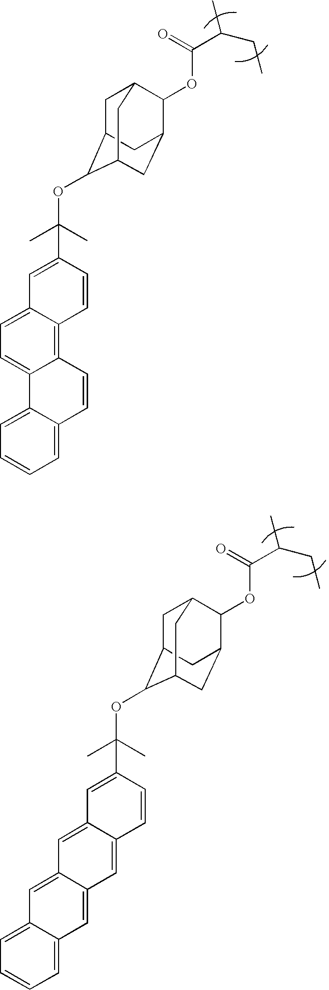

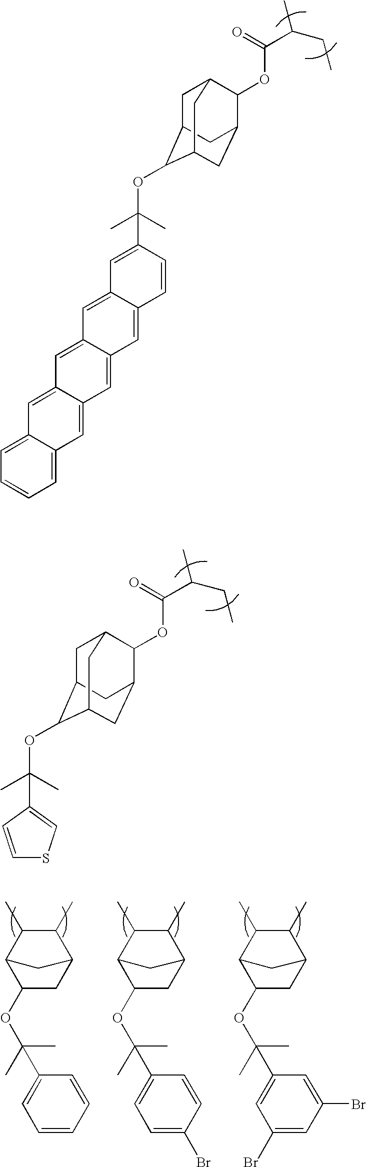

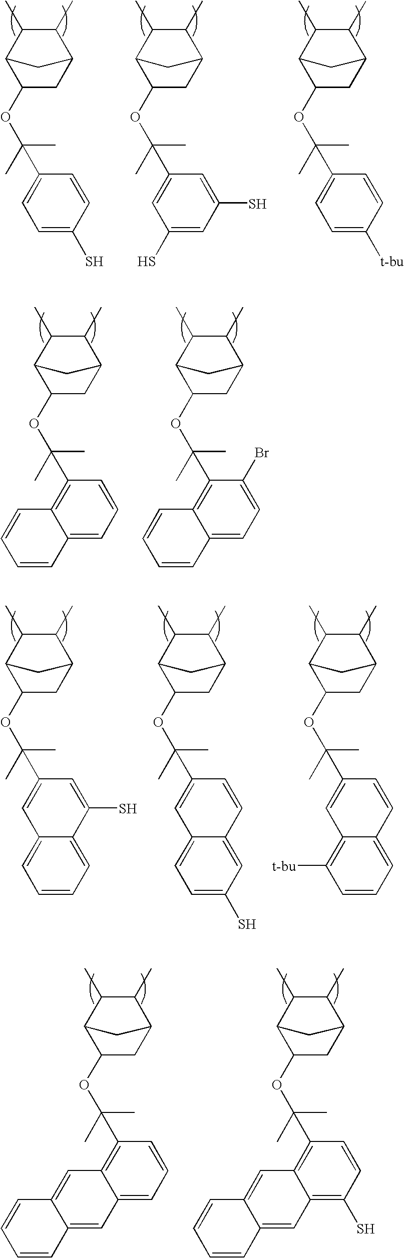

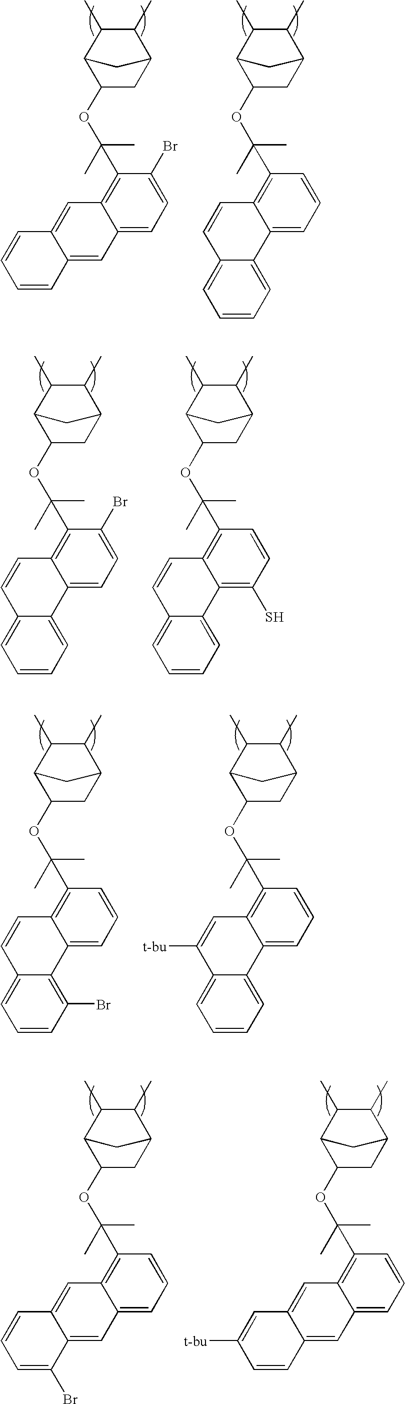

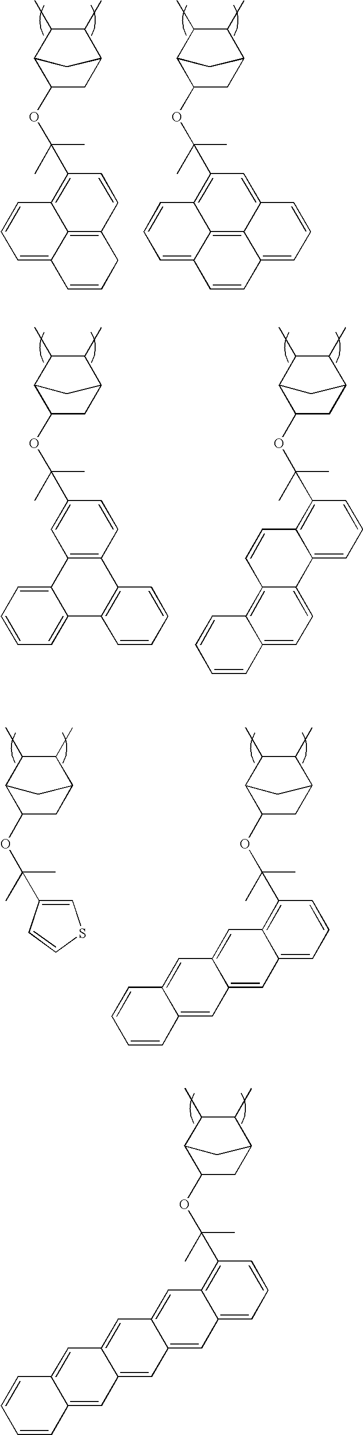

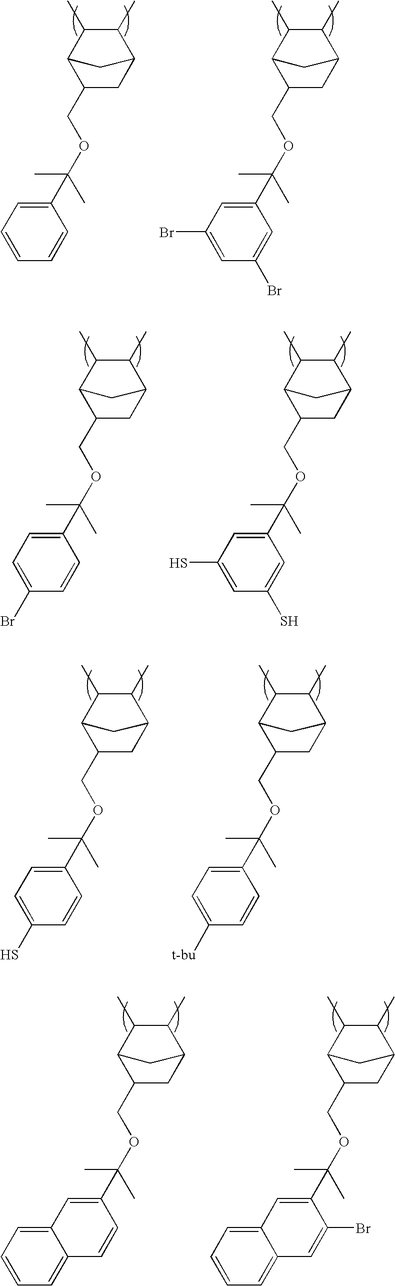

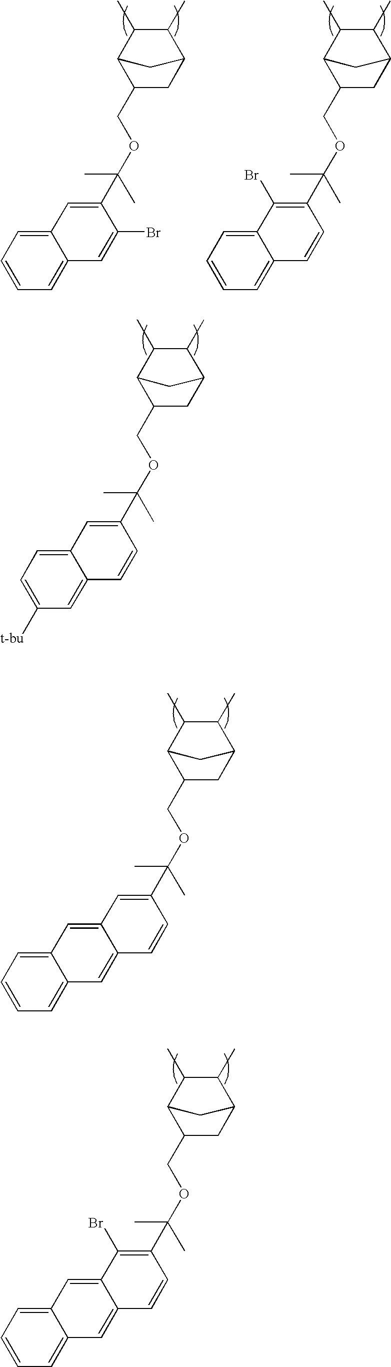

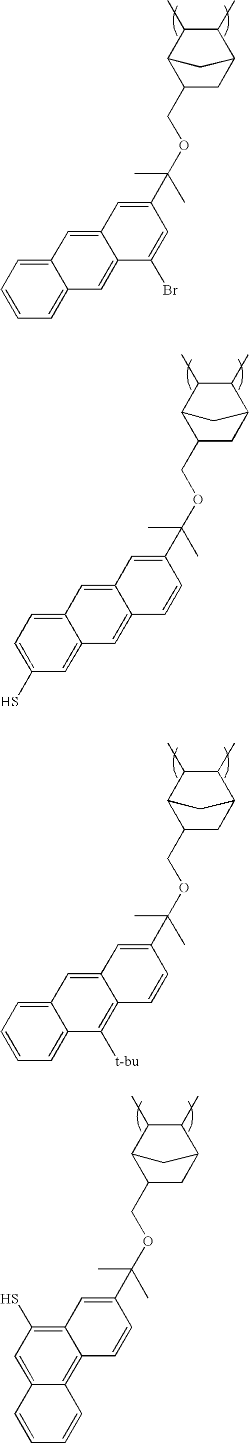

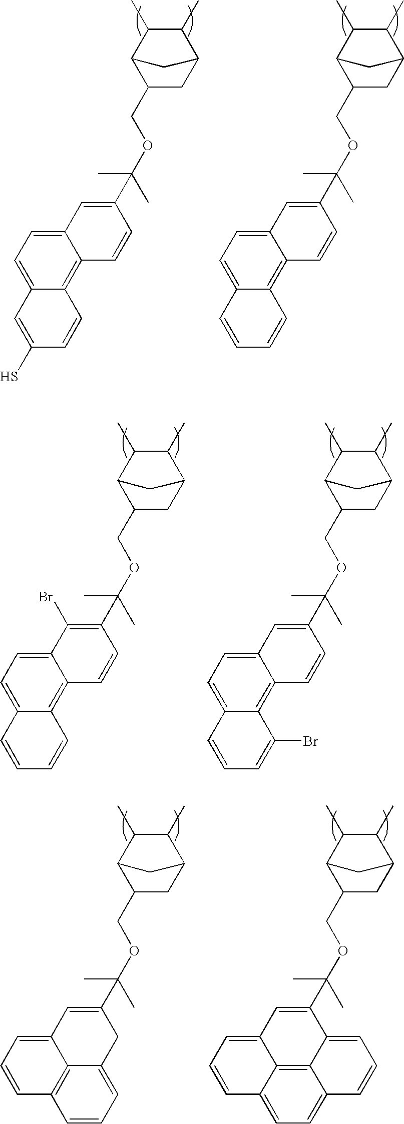

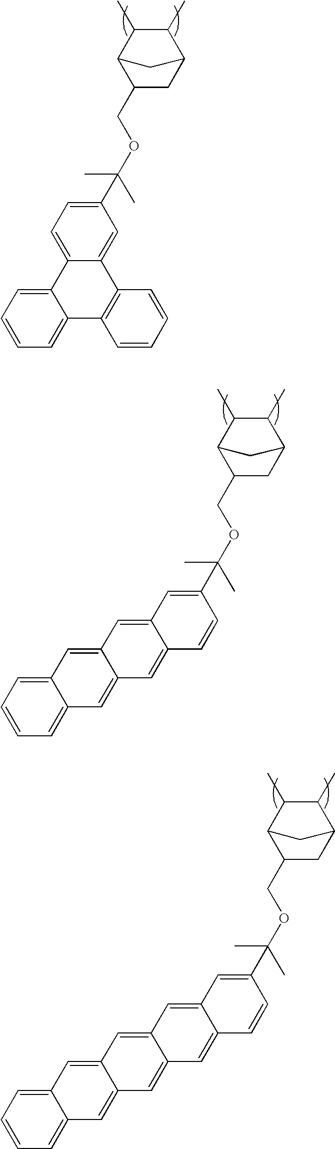

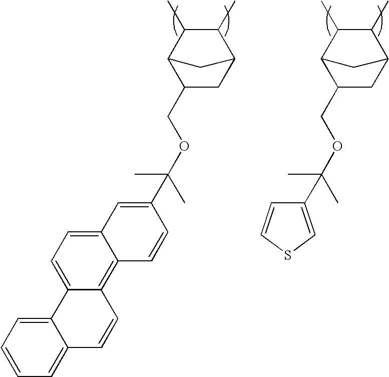

When the repeating unit expressed by the general formula (1) is exposed to an acid, as shown below, the bond between the oxygen atom at the end of the carbonyloxy group (—C(═O)—O—) and the carbon atom located between R⁶ and R⁷ is cleaved. The molecular group located adjacent to the oxygen atom at the end of the carbonyloxy group is dissociated from the main chain. When dissociation occurs, a new ethylenically unsaturated bond (R⁶═C) is formed between R⁶ and the carbon atom located between R⁶ and R⁷. Alternatively, an ethylenically unsaturated bond (C═R⁷) is formed between R⁷ and the carbon atom located between R⁶ and R⁷.

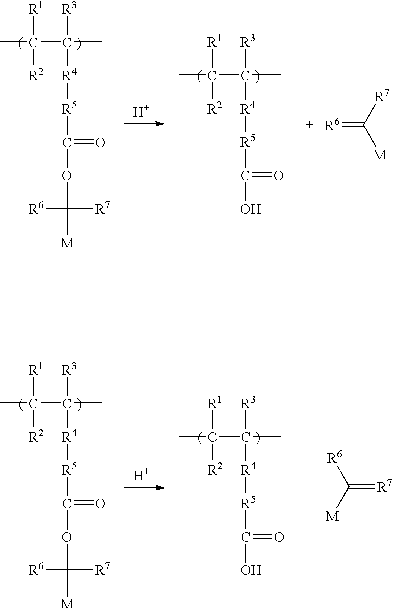

The consequence of this whole reaction is that the molecular group located adjacent to the oxygen atom at the end of the carbonyloxy group is dissociated from the main chain, and a new ethylenically unsaturated bond is formed within the molecular group. As a result of this, a new polymerizable monomer is produced. The molecular group located adjacent to the oxygen atom at the end of the carbonyloxy group dissociated from the main chain is referred to as “vinyl-M”.

If R⁶ or R⁷ contained in the vinyl-M is bulky, it means a bulky substituent is present on the ethylenically unsaturated bond between R⁶ and the carbon atom located between R⁶ and R⁷. The same is true for the case when the ethylenically unsaturated bond is the bond between R⁷ and the carbon atom located between R⁶ and R⁷. As a result of this, the vinyl-M as a polymerizable monomer is poor in reactivity. In order to prevent such problem, the hydrocarbon group introduced to R⁶ preferably has 10 or less carbon atoms. For the same reason, R⁷ defined as a hydrocarbon group having 10 or less carbon atoms.

Usually, in order to dissociate an ester by an acid as described above, the carbon atom located between R⁶ and R⁷ must be a tertiary carbon. However, when an aromatic group is introduced to M, there is a case that secondary carbon can be dissociated. The reason for this is likely that carbocation, which is an intermediate by dissociation of the ester, is stabilized by the introduction of an aromatic group to the ester.

On the other hand, when the repeating unit expressed by the general formula (2) is exposed to an acid, the bond between the oxygen atom shown in the general formula (2) and the adjacent carbon atom is cleaved, and then the molecular group located adjacent to the oxygen atom is dissociated from the main chain. At this time, a new ethylenically unsaturated bond (R⁸═C) is formed between R⁸ and the carbon atom located between R⁸ and R⁹. Alternatively, an ethylenically unsaturated bond (C═R⁹) is formed between R⁹ and the carbon atom located between R⁸ and R⁹.

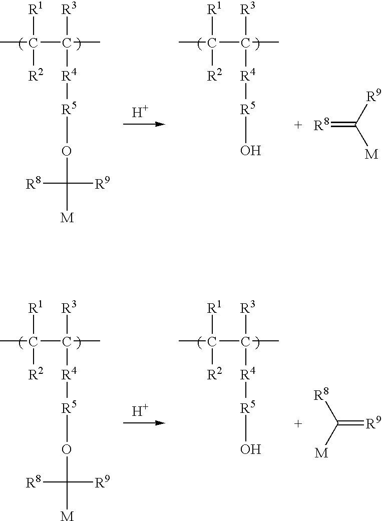

The consequence of this whole reaction is that, the molecular group located adjacent to the oxygen atom in the general formula (2) is dissociated from the main chain, and a new ethylenically unsaturated bond is formed within the molecular group. As a result of this, a new polymerizable monomer is produced. As is the case with the general formula (1), a new vinyl-M is produced from the general formula (2) by an acid.

At this time, it is necessary that the bond between the tertiary carbon located between the R⁸ and R⁹, and the oxygen atom is cleaved in preference to the bond between R⁵ and the oxygen atom. Usually, the bond between the tertiary carbon and an oxygen atom is preferentially cleaved. Accordingly, for R⁵, the carbon atom directly bonded to the oxygen atom is preferably secondary or primary carbon. It is best that the carbon atom is a primary carbon.

If R⁸ or R⁹ contained in the vinyl-M is bulky, it means a bulky substituent is present on the ethylenically unsaturated bond between R⁸ and the carbon atom located between R⁸ and R⁹. The same is true for the case when the ethylenically unsaturated bond is the bond between R⁹ and the carbon atom located between R⁸ and R⁹. As a result of this, the vinyl-M as a polymerizable monomer is poor in reactivity. In order to prevent such problem, the hydrocarbon group introduced to R⁸ or R⁹ preferably has 10 or less carbon atoms.

The polymeric matrix is preferably three-dimensionally crosslinked. A three-dimensionally crosslinked polymeric matrix can be formed by combining the repeating unit expressed by the general formula (1) or (2) with, for example, a repeating unit expressed by the general formula (3).

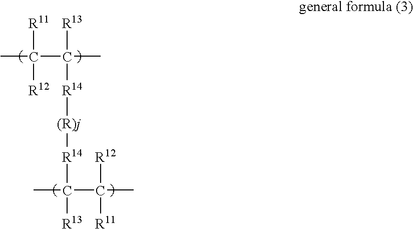

The repeating unit expressed by the general formula (3) can be obtained from the monomer expressed by the general formula (3m).

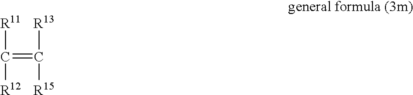

In the general formula (3m), R¹¹, R¹², and R¹³ each represent a hydrogen atom or a hydrocarbon group having 10 or less carbon atoms. The hydrocarbon group may be an aliphatic hydrocarbon group, an alicyclic hydrocarbon group, or an aromatic hydrocarbon group, and R¹¹, R¹², and R¹³ may be the same or different from each other. Specific examples of the hydrocarbon group which may be introduced as R¹¹, R¹², and R¹³ include a methyl group, an ethyl group, a propyl group, an isopropyl group, a butyl group, a sec-butyl group, a tert-butyl group, a cyclohexyl group, an adamantyl group, and a phenyl group. R¹¹, R¹², and R¹³ are preferably hydrogen atoms, methyl groups, or ethyl groups. The reason for this is that R¹¹, R¹² and R¹³ are preferably spatially small to reduce the steric hindrance at the time of polymerization of the monomer expressed by the general formula (3m) to form the repeating unit expressed by the general formula (3). It is particularly preferable that R¹¹ and R¹² are hydrogen atoms, and R¹³ is a hydrogen atom or a methyl group.

R¹⁵ represents a molecular group having a polymerizable functional group, and may be selected according to the crosslinking group R. The end of R¹⁵ may have a molecular group having an ethylenic double bond, an ethynyl group, an azido group, a formyl group, a cyclic ester such as oxirane, oxetane, or spiroorthoester, an amino group, a carboxyl group, a carbonyl group, a hydroxyl group, or a mercapto group. When the molecular group has an ethylenically unsaturated bond, an ethynyl group, or a cyclic ester such as oxirane, oxetane, or spiroorthoester, multiple R¹⁵s may interact with each other to form a three-dimensionally crosslinked polymeric matrix. In such case, crosslinking agent is not necessary.

R¹⁴ is a modified functional group transitioned after the interaction between R¹⁵ in the general formula (3m) and a crosslinking group R, or a modified functional group transitioned after the interaction between multiple R¹⁵s.

R represents a crosslinking agent containing a crosslinking group, and examples of the crosslinking group include an ethylenic double bond group, an ethynyl group, an azido group, a formyl group, oxirane, oxetane, a spiroorthoester, an amino group, a carboxyl group, a hydroxyl group, a mercapto group, and a halogen atom. j represents 0 or 1.

The three-dimensionally crosslinked polymeric matrix containing the repeating unit expressed by the general formula (1) and the repeating unit expressed by the general formula (3) can be expressed by the general formula (MT1). The three-dimensionally crosslinked polymeric matrix containing the repeating unit expressed by the general formula (2) and the repeating unit expressed by the general formula (3) can be expressed by the general formula (MT2).

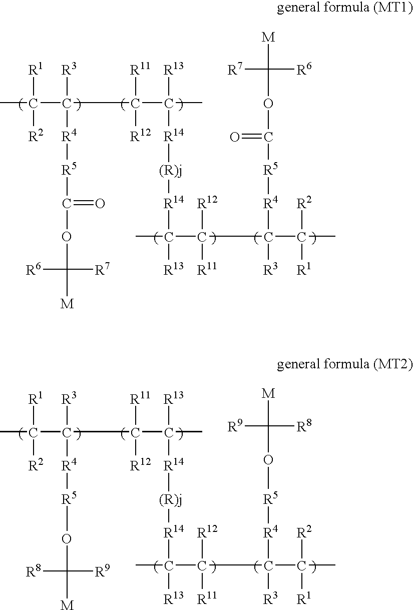

In order to achieve the three-dimensionally crosslinked polymeric matrix expressed by the general formula (MT1), the copolymer expressed by the general formula (CP1) is synthesized preliminarily according to the reaction formula (1). As the starting materials, the monomer expressed by the general formula (1m) and the monomer expressed by the general formula (3m) are used. In this case, radical copolymerization is preferred, because the reaction is not affected by the polarity of the monomer expressed in the general formulae (1m) and (3m). It is also advantageous that the reaction proceeds even in the presence of water. The copolymer expressed by the general formula (CP1) may be referred to as a polymeric matrix precursor.

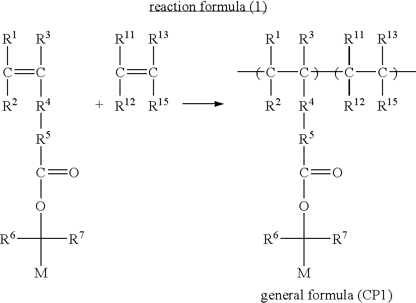

In order to achieve the three-dimensionally crosslinked polymeric matrix expressed by the general formula (MT2), the copolymer expressed by the general formula (CP2) is synthesized preliminarily according to the reaction formula (2). As the starting materials, the monomer expressed by the general formula (2m) and the monomer expressed by the general formula (3m) are used. In this case, radical copolymerization is preferred from the same reason as described above. The copolymer expressed by the general formula (CP2) may be referred to as a polymeric matrix precursor.

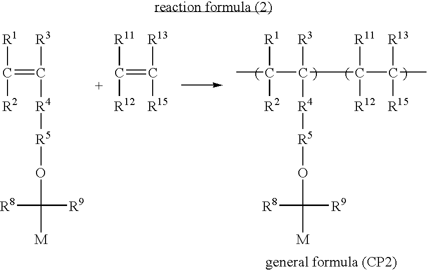

In either cases, a desired three-dimensionally crosslinked polymeric matrix is obtained through the reaction between the crosslinking agent containing the crosslinking group R and the polymeric matrix precursor expressed by the general formula (CP1) or (CP2). When a bonding group is contained at the end of R¹⁵ in the general formula (3m), the crosslinking agent containing the crosslinking group R may not be added. Examples of the bonding group include an ethylenic double bond group, an ethynyl group, oxirane, oxetane, and a spiroorthoester.

The three-dimensionally crosslinked polymeric matrix may be achieved by, for example, the following polymerization reaction: epoxy-amine polymerization, epoxy-acid anhydride polymerization, epoxy-mercaptan polymerization, unsaturated ester-amine polymerization by Michael addition, urethane formation from isocyanate and hydroxyl, urea formation from isocyanate and hydroxyl, and bonding between ethynyl and azido. The polymerization reaction is preferably epoxy-amine polymerization or epoxy-acid anhydride polymerization in particular since these reactions proceed moderately.

When a polymerizable functional group is contained at the end of R¹⁵ in the general formula (3m), a three-dimensionally crosslinked polymeric matrix can be obtained without being intervened by the crosslinking group R. The polymerizable functional groups at the ends of R¹⁵s polymerize with each other to form a three-dimensionally crosslinked polymeric matrix by, for example, epoxy cationic polymerization, vinyl ether cationic polymerization, or epoxy homopolymerization in the presence of an aluminum catalyst.

The crosslinking agent containing the crosslinking group R may be any compound having a functional group linkable to the end group of R¹⁵ in the general formula (3m). For example, when the end group of R¹⁵ is an epoxy group, any compound known as an epoxy curing agent may be used as the crosslinking agent.

Specific examples of the compound include ethylenediamine, diethylenetriamine, triethylenetetramine, tetraethylenepentamine, pentaethylenehexamine, hexamethylenediamine, menthenediamine, isophoronediamine, bis(4-amino-3-methyldicyclohexyl)methane, bis(aminomethyl)cyclohexane, N-aminoethylpiperazine, m-xylylenediamine, 1,3-diaminopropane, 1,4-diaminobutane, trimethylhexamethylenediamine, iminobispropylamine, bis(hexamethylene)triamine, 1,3,6-trisaminomethylhexane, dimethylaminopropylamine, aminoethylethanolamine, tri(methylamino)hexane, m-phenylenediamine, p-phenylenediamine, diaminodiphenylmethane, diaminodiphenylsulfone, 3,3′-diethyl-4,4′-diamino diphenyl methane, maleic anhydride, succinic anhydride, tetrahydrophthalic anhydride, methyltetrahydrophthalic anhydride, anhydrous methyl nadic anhydride, hexahydrophthalic anhydride, methylhexahydrophthalic acid, methylcyclohexenetetracarboxylic anhydride, phthalic anhydride, trimellitic anhydride, benzophenonetetracarboxylic anhydride, dodecenylsuccinic anhydride, ethylene glycol bis(anhydroustrimellitate), phenol novolac resin, cresol novolac resin, polyvinylphenol, terpenephenol resin, and polyamide resin.

A curing catalyst may be added, if necessary, when forming a three-dimensionally crosslinked polymeric matrix. The curing catalyst may be a basic catalyst. Examples of the basic catalyst include tertiary amines, organic phosphine compounds, imidazole compounds, and derivatives thereof. Specific examples of the curing agent include triethanolamine, piperidine, N,N′-dimethylpiperazine, 1,4-diazadicyclo(2,2,2)octane(triethylenediamine), pyridine, picoline, dimethylcyclohexylamine, dimethylhexylamine, benzyldimethylamine, 2-(dimethylaminomethyl)phenol, 2,4,6-tris(dimethylamino methyl)phenol, DBU(1,8-diazabicyclo[5,4,0]undeca-7-ene), or phenol salts thereof, trimethylphosphine, triethylphosphine, tributylphosphine, triphenylphosphine, tri(p-methylphenyl)phosphine, 2-methylimidazole, 2,4-dimethylimidazole, 2-ethyl-4-methylimidazole, 2-phenylimidazole, 2-phenyl-4-methylimidazole, and 2-heptaimidazole.

A latent catalyst also may be used. Examples of the latent catalyst include boron trifluoride amine complexes, dicyandiamide, organic acid hydrazide, diaminomaleonitrile and derivatives thereof, melamine and derivatives thereof, and amine imides. Furthermore, a compound having active hydrogen, for example, a phenol or salicylic acid may be added to promote curing of the three-dimensionally crosslinked polymeric matrix.

The three-dimensionally crosslinked polymeric matrix may contain, in addition to the repeating unit expressed by the general formula (MT1) or (MT2), another common polymer in the main chain thereof.

In order to manufacture a holographic recording medium according to one embodiment, the above-described radically polymerizable monomer, photo-acid generator, radical polymerization initiator, polymeric matrix precursor, and crosslinking agent are mixed together to obtain a recording layer forming solution. The recording layer forming solution may contain, if necessary, a sensitizer and a plasticizing agent. The recording layer is formed by forming a resin layer, which is originated from the recording layer forming solution, on a given substrate. By crosslinkage of the recording layer forming solution, the recording layer is formed.

For example, a recording layer forming solution is applied to a transparent substrate, thereby forming a recording layer. The transparent substrate may be, for example, a glass substrate or a plastic substrate. Before the application of the recording layer forming solution, the surface of the substrate may be subjected to an adhesion promoting treatment selected from a corona discharge treatment, plasma treatment, ozone treatment, and alkali treatment. The application of the solution may employ casting or spin coating. Alternatively, two glass substrates are arranged with a resin spacer sandwiched between them, and the recording layer forming solution is poured into the gap, thereby forming a recording layer.

When an aliphatic primary amine is used as the curing agent, three-dimensional crosslinking of the polymeric matrix proceeds even at room temperature. According to the reactivity of the curing agent, the system may be heated to a temperature of 30° C. to 150° C. The thickness of the recording layer to be formed is preferably from 20 mm to 2 mm, and more preferably from 50 mm to 1 mm. If the thickness of the recording layer is less than 20 mm, it is difficult to obtain a sufficient storage volume. On the other hand, if the thickness of the recording layer is greater than 2 mm, sensitivity and diffraction efficiency may deteriorate.

As described above, the polymeric matrix precursor composed of the copolymer expressed by the general formula (CP1) is synthesized by the reaction expressed by the reaction formula (1) from the monomers expressed by the general formulae (1m) and (3m). The crosslinking agent containing the crosslinking group R, radically polymerizable monomer M1, photo-radical polymerization initiator I, and photo-acid generator PAG are mixed to make a recording layer forming solution, and the solution undergoes a three-dimensional crosslinking reaction expressed by the reaction formula (3) to form a recording layer.

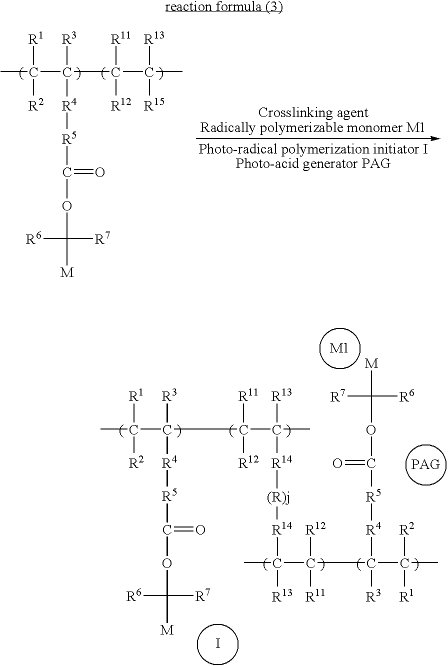

The polymeric matrix precursor composed of the copolymer expressed by the general formula (CP2) is obtained by the reaction expressed by the reaction formula (2) from the monomer expressed by the general formula (2m) and the monomer expressed by the general formula (3m). The recording layer forming solution obtained by mixing the crosslinking agent containing the crosslinking group R, radically polymerizable monomer M1, photo-radical polymerization initiator I, and photo-acid generator PAG undergoes a three-dimensional crosslinking reaction expressed by the reaction formula (4) to form a recording layer.

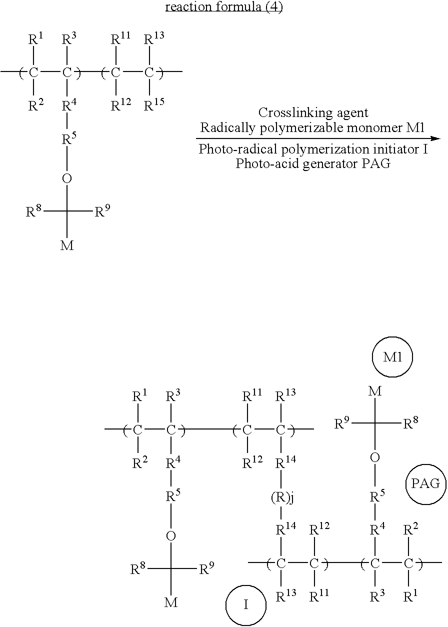

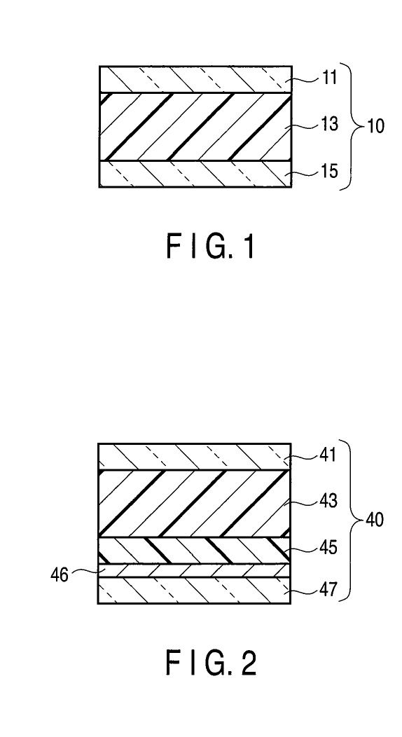

In the holographic recording medium 10 shown in FIG. 1, a recording layer 13 is exposed between a pair of transparent substrates 11 and 15. The recording layer 13 contains the above-described radically polymerizable monomer, photo-acid generator, photo-radical polymerization initiator, and polymeric matrix composed of the repeating units expressed by the general formula (1) or (2).

In the holographic recording medium 40 shown in FIG. 2, a reflecting layer 46 is provided on a transparent substrate 47, on which a recording layer 43 is provided with a gap layer 45 sandwiched therebetween. More specifically, it is a holographic recording medium having a reflecting layer. The reflecting layer 46 may be made of, for example, aluminum, and the gap layer 45 may be made of, for example, a transparent resin or glass.

A transparent substrate 41 is provided on the recording layer 43. As is the case with the transmission holographic recording medium 10 shown in FIG. 1, the recording layer 43 in the holographic recording medium 40 having a reflecting layer shown in FIG. 2 also contains the above-described radically polymerizable monomer, photo-acid generator, photo-radical polymerization initiator, and polymeric matrix composed of the repeating units expressed by the general formula (1) or (2).

In the holographic recording medium according to one embodiment, holographic recording is performed through interference between information light beam and reference light beam within the recording layer. The hologram to be recorded (holography) may be either a transmission hologram (transmission holography) or reflection hologram (reflection holography). The interference between the information light beam and reference light beam may be achieved by dual-beam or single-beam interference.

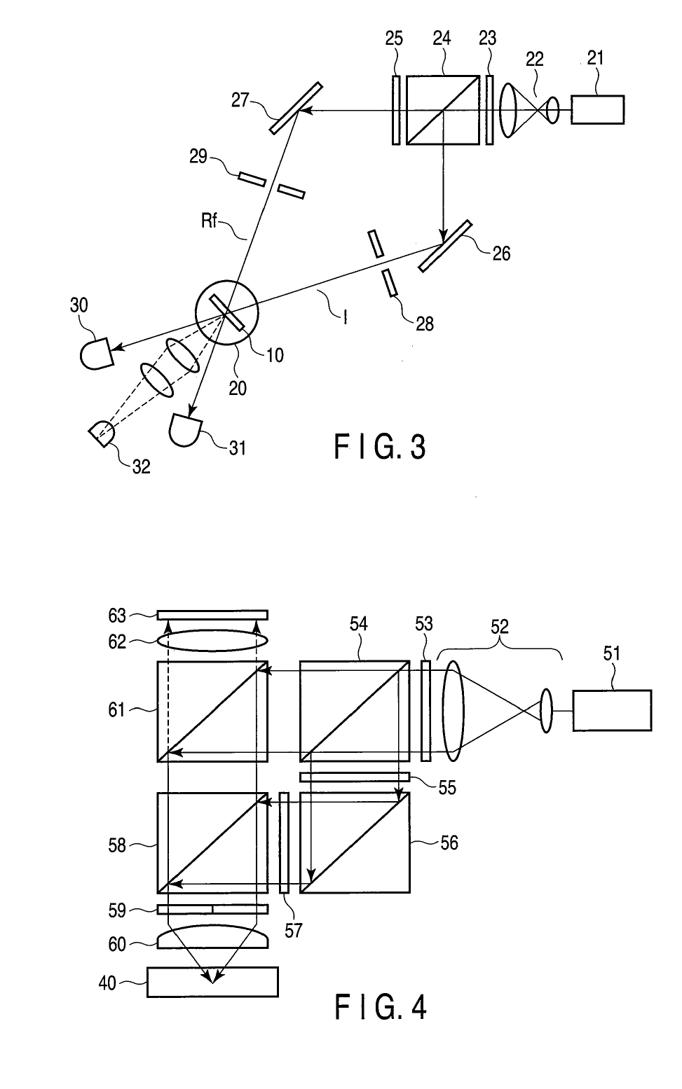

The holographic recording/reconstructing apparatus shown in FIG. 3 is a hologram type optical information recording/reconstructing apparatus based on transmission dual-beam interference.

The light beam emitted from a light source device 21 passes through a beam expander 22 and a rotating optical element 23, and is introduced to a polarizing splitter 24. The light source device 21 may be of any light source that emits light capable to interfere in the recording layer 13 of the transmission holographic recording medium 10. From the viewpoint of coherence, the light source device is preferably a linearly polarized laser. Examples of the laser include a semiconductor laser, a He—Ne laser, an argon laser, and a YAG laser.

The beam expander 22 expands the light emitted from the light source device 21 to a beam diameter suitable for holographic recording. The light beam whose beam diameter has been expanded by the beam expander 22 is optically rotated by the rotating optical element 23 so as to generate a light beam including an S-polarized light beam component and a P-polarized light beam component. The rotating optical element 23 may be, for example, a ½ wavelength plate or a ¼ wavelength plate.

Of the light beam that has passed the rotating optical element 23, the S-polarized beam is reflected by the polarizing beam splitter 24 which is utilized as information light beam I. The P-polarized light beam component passes through the polarizing beam splitter 24, and is utilized as reference light beam Rf. The direction of optical rotation of the light incident to the polarizing beam splitter 24 is controlled by the rotating optical element 23 which could make the intensity of the information light beam I and the reference light beam Rf equal to each other at the position of the recording layer 13 of the holographic recording medium 10.

The information light beam I that has been reflected by the polarizing beam splitter 24 is reflected by a mirror 26, which then passes through an electromagnetic shutter 28 to irradiate the recoding layer 13 of the transmission holographic recording medium 10 mounted on a rotating stage 20.

On the other hand, the reference light beam Rf that has passed through the polarizing beam splitter 24 is optically rotated 90° by a rotating optical element 25 to form an S-polarized light beam, and is reflected by a mirror 27. The S-polarized light beam thus formed passes through an electromagnetic shutter 29 to irradiate the recording layer 13 of the transmission holographic recording medium 10 mounted on the rotating stage 20. Within the recording layer 13, the S-polarized light beam intersects with the information light beam I to generate interference fringes, whereby a transmission hologram is formed in a refractive index modulating region (not shown).

In order to reconstruct the recorded information, the electromagnetic shutter 28 is closed to shut off the information light beam I and allows only the reference light beam Rf to be irradiated on to the transmission hologram (not shown) formed within the recording layer 13 of the transmission holographic recording medium 10. When passing through the transmission holographic recording medium 10, the reference light beam Rf is partially diffracted by the transmission hologram, and the diffracted light is detected by a photo detector 30. In order to detect light transmitting through the medium, a photo detector 31 is provided.

In order to expose the recording medium to light after holographic recording, an ultraviolet light source device 32 and an ultraviolet photoirradiation optical system may be provided as shown. It leads to greater stability when unreacted radically polymerizable monomers are polymerized with this system. The ultraviolet light source device 32 may include any light source which emits light for polymerizing the unreacted radically polymerizable monomers. Taking the efficiency of emitting ultraviolet light into account, preferable examples of the light source include a xenon lamp, a mercury lamp, a high pressure mercury lamp, a mercury xenon lamp, a gallium nitride-based light emitting diode, a gallium nitride-based semiconductor laser, an excimer-laser, the third harmonic (355 nm) generated from an Nd:YAG laser, and the fourth harmonic (266 nm) generated from an Nd:YAG laser.

FIG. 4 shows a schematic view of the reflection holographic recording/reconstructing apparatus according to one embodiment. As is the case with the transmission holographic recording/reconstructing apparatus, it is preferable that a light source device 51 used herein include a laser that emits linearly polarized coherent light. Examples of the laser include a semiconductor laser, a He—Ne laser, an argon laser, and a YAG laser.

The light beam emitted from the light source device 51 is expanded by a beam expander 52 to an intended beam diameter, and is incident on a rotating optical element 53 in the form of a parallel light beam. The rotating optical element 53 may be, for example, a ½ wavelength plate or a ¼ wavelength plate. The rotating optical element 53 rotates the polarization plane of the light beam, thereby generating light that includes a polarized component (P-polarized light beam component) whose polarization plane is let us say parallel with the figure (FIG. 4) and another polarized component (S-polarized light beam component) whose polarization plane is vertical to the figure. The light containing the P-polarized light beam component and S-polarized light beam component may be generated through the use of a circularly polarized or elliptically polarized light beam.

The S-polarized light beam component of the light beam that has passed through the rotating optical element 53 is reflected by the polarizing beam splitter 54, and is incident on a transmission spatial light modulator 55. The P-polarized light beam component of the light beam that has passed through the rotating optical element 53 passes through the polarizing beam splitter 54, and is utilized as reference light beam, as will be described later.

The transmission spatial light modulator 55 comprises a large number of pixels that are arranged in a matrix as in, for example, a transmission liquid crystal display. The light emitted from each pixel can be switched to the P-polarized or S-polarized light beam. In this manner, the transmission spatial light modulator 55 emits information light beam provided with a two-dimensional distribution of polarization planes corresponding to the information that is intended to be recorded.

The information light beam that has passed through the transmission spatial light modulator 55 is incident on a polarizing beam splitter 56. The polarizing beam splitter 56 selectively reflects the S-polarized light beam component of the information light beam, and transmits the P-polarized light beam component. The S-polarized light beam component reflected by the polarizing beam splitter 56 passes through an electromagnetic shutter 57 as information light beam provided with a two-dimensional intensity distribution, The information light beam is then incident on a polarizing beam splitter 58. The information light beam is reflected by the polarizing beam splitter 58, which is then incident on a split wave plate 59.

The so-called split wave plate 59 has different optical characteristics on its right-half and on its left-half. The plane of polarization of the beam which is incident on the right-half of the split wave plate 59 is rotated +45°. On the other hand, the plane of polarization beam that is incident on the left-half of the split wave plate 59 is rotated −45°. For the polarized beam, where plane of rotation is rotated +45° to the S-polarized light beam (or the polarized beam whose plane of rotation is rotated −45° to the P-polarized beam) we refer to as A-polarized component hereinafter. Likewise, for the polarized beam where the plane of rotation is rotated −45° to the S-polarized beam (or the polarized beam whose plane of rotation is rotated +45° to the P-polarized beam), we refer to B-polarized beam hereinafter. A half-wave plate, for example, is used for each half of the split wave plate 59.

The A- and B-polarized beam components which had transmitted through the split wave plate 59 are incident on the holographic recording medium 40 through an objective lens 60. The two beams pass through the first transparent substrate 41, recording layer 43, and gap layer 45, and are focused on the reflecting layer 46 on the second transparent substrate 47.

On the other hand, the P-polarized light beam (the reference light beam) that has transmitted though the polarizing beam splitter 54 is partly reflected by a beam splitter 61 and passes through the polarizing beam splitter 58. The reference light beam that has passed through the polarizing beam splitter 58 is incident on the split wave plate 59. The plane of polarization of the light beam, which is incident on the right-half of the split wave plate 59, is rotated by +45° and is converted to B-polarized light beam as it passes through the split wave plate 59. On the contrary, the light beam component which is incident on the left-half of the split wave plate 59, is rotated −45° and is converted to A-polarized light beam as it passes through the split wave plate 59. The A- and B-polarized light beams are incident on the holographic recording medium 40 through the objective lens 60, which then passes through the first transparent substrate 41, the recording layer 43, and the gap layer 45, and are focused on the reflecting layer 46 on the transparent substrate 47.

In this manner, information light beam, as the A-polarized light beam, and reference light beam, as the B-polarized light beam, exit from the right-half of the split wave plate 59. From the left-half of the split wave plate 59, information light beam as the B-polarized component and reference light beam as the A-polarized component exit. The information light beam and reference light beam are focused on the reflecting layer 46 of the holographic recording medium 40 having a reflecting layer.

The information light beam, which is directly incident on to the recording layer 43 that has passed through the transparent substrate 41, and the reference light beam, which is incident on to the recording layer 43 after being reflected by the reflecting layer 46, interfere each other. Such interference also occurs between the reference light beam which is directly incident on to the recording layer 43 and information light beam that has been reflected. In this manner, distribution of optical properties that corresponds to the information light beam is generated within the recording layer 43. On the other hand, no interference occurs between information light beam as direct light and information light beam as reflected light, or between reference light beam as direct light and reference light beam as reflected light.

An ultraviolet light source device and an ultraviolet photoirradiation optical system may be provided also in the reflection holographic recording/reconstructing apparatus as shown in FIG. 4. It leads to greater stability of the hologram.

The information recorded on the holographic recording medium 40 having a reflecting layer can be read out as follows.

When the electromagnetic shutter 57 is closed, only the reference light beam, which is P-polarized, is incident on the split wave plate 59. The plane of rotation of the reference beam that is incident on the right-half of the split wave plate 59 is rotated +45° as it passes through to form a B-polarized light beam. On the other hand, of the reference beam that is incident on the left-half of the split wave plate 59 is rotated −45° as it passes through to form an A-polarized light beam. Thereafter, the A- and B-polarized light beams are incident on to the holographic recording medium 40 via the objective lens 60, which then pass through the transparent substrate 41, the recording layer 43, and the gap layer 45, and are focused on the reflecting layer 46 provided on the transparent substrate 47.

Distribution of optical properties corresponding to the information that is intended to be recorded is formed in the recording layer 43 of the holographic recording medium 40 having a reflecting layer. Accordingly, a fraction of the A- and B-polarized components that are incident on the holographic recording medium 40 having a reflecting layer, is diffracted by the above-stated region (not shown) where the distribution of optical properties are modulated. The diffracted light, which is the reconstruction of the information light beam, exit from the holographic recording medium 40 having a reflecting layer.

The reconstructed light beam outgoing from the holographic recording medium 40 having a reflecting layer is collimated by the objective lens 60, and is incident on the split wave plate 59. The B-polarized light beam incident on the right-half of the split wave plate 59 exits therefrom as a P-polarized light beam component, and the A-polarized light beam incident on the left-half of the split wave plate 59 exits therefrom as a P-polarized light beam component. In this manner, the reconstructed light beam is obtained as a P-polarized light beam component.

Thereafter, the reconstructed light beam passes through the polarizing beam splitter 58. The reconstructed light beam that has transmitted through the polarizing beam splitter 58 partly transmits through the beam splitter 61, and forms an image on a two-dimensional photo detector 63 via an imaging lens 62 so as to reconstruct the image that had been displayed on the transmission spatial light modulator 55. In this manner, the information that had been recorded on the holographic recording medium 40 having a reflecting layer is read out.

On the other hand, the remaining portion of the A- and B-polarized light beam that is incident on the holographic recording medium 40 through the split wave plate 59, is reflected back by the reflecting layer 46, and exits from the holographic recording medium 40. The A- and B-polarized components as the reflected light are collimated by the objective lens 60. When A-polarized component passes through the right-half of the split wave plate 59 it is converted to an S-polarized light beam. Likewise, as the B-polarized component passes through the left-half of the split wave plate 59 it is converted to an S-polarized light beam.

Since the S-polarized light beam component outgoing from the split wave plate 59 is reflected by the polarizing beam splitter 61, it will not reach to the two-dimensional photo detector 63. Accordingly, the recording/reconstructing apparatus enables to achieve the reconstruction with excellent SN ratio.

The holographic recording medium according to one embodiment is suitable for multiplex information recording/reconstruction. The geometry of multiplex information recording/reconstruction can either be a transmission-type a reflection-type.

It is possible, if necessary, to illuminate the recording layer with a uniform light after the entire recording is completed. It is also possible to diffuse oxygen into the recording layer of the holographic recording medium under an oxygen-rich atmosphere after the entire recording to quench any radical species within the holographic recording medium.

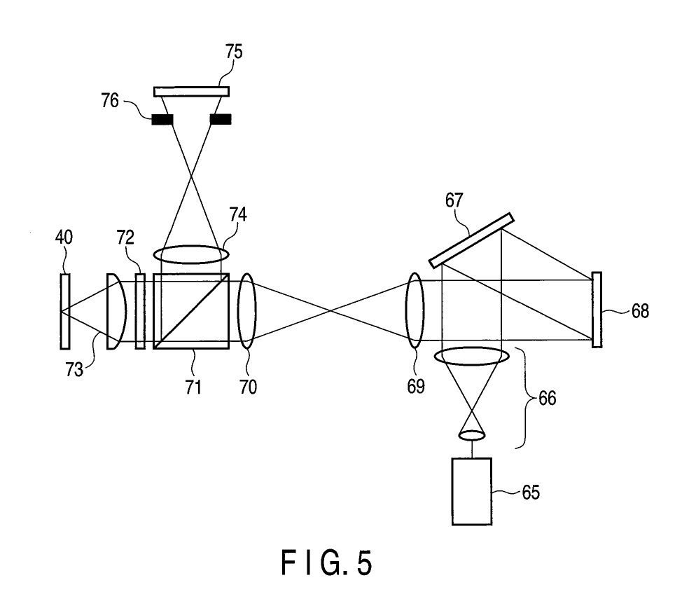

FIG. 5 shows a schematic view of the optical recording/reconstructing apparatus based on coaxial interference geometry. The recording/reconstructing apparatus shown employs coaxial interference geometry to record a hologram, wherein information light beam and modulated reference light beam are generated under a single spatial light modulator.

A light source device 65 used herein is preferably a linearly polarized laser from the viewpoint of, for example, coherence, as is the case with the above-described transmission holographic recording/reconstructing apparatus and reflection holographic recording/reconstructing apparatus. Specific examples of the laser include a semiconductor laser, an He—Ne laser, an argon laser, and a YAG laser. The light source device 65 is capable of adjusting its emitting wavelength.

A beam expander 66 expands and collimates the emitted light beam from the light source device 65. The collimated light beam is then irradiated on to a mirror 67 which reflects the irradiated beam on to a reflection spatial light modulator 68. The reflection spatial light modulator 68 comprises a numerous of pixels that are arrayed in a two-dimensional lattice. Each pixel on the reflection spatial light modulator 74 can independently change the direction of the reflection or the polarization rotation of the reflected light. By utilizing this spatial light modulator 74, information light beam having information as a two-dimensional pattern and spacially modulated reference light beam are simultaneously generated. The reflection spatial light modulator 68 may be, for example, a digital mirror device, a reflection liquid crystal device, or a reflection modulation element based on a magneto-optical effect.

In the example shown, a digital mirror device is used as the reflection spatial light modulator 68. The recording light beam reflected by the reflection spatial light modulator 68 is incident on a polarizing beam splitter 71 through imaging lenses 69 and 70. The polarizing direction of the recording light is adjusted when it is emitted from the light source device 65 so as to transmit through a polarizing beam splitter 71.

The recording light that has transmitted through the polarizing beam splitter 71 passes through a polarization rotating optical element 72, and is irradiated by an objective lens 73 over the holographic recording medium 40 having a reflecting layer. The recording light is focused on the surface of the reflecting layer 46 of the holographic recording medium 40 having a reflecting layer so as to minimize the beam diameter. The polarization rotating optical element 72 may be, for example, a ¼ wavelength plate or a ½ wavelength plate.

The reconstruction of the information beam is retrieved by the following procedures. When the reference beam which had been spatially modulated by the reflection spatial light modulator 68 passes through the holographic recording medium 40, the spatially modulated reference beam is partly diffracted by the refractive index modulated region to form a reconstructed information beam. The reconstructed light beam is reflected by the reflective layer 46 which then passes through the objective lens 73 and the polarization rotating optical element 72. When passing through the polarization rotating optical element 72, the plane of polarization of the reconstructed light beam is rotated so that the direction of the polarization is different from the original reference beam. The reconstructed and rotated information light beam is reflected by the polarizing beam splitter 71. It is desirable that the angle of rotation is controlled in such a way so that the reflection of the reconstructed information beam reaches the maximum at the polarizing beam splitter 71. The reconstructed information light beam reflected by the polarizing beam splitter 71 forms an image on a two-dimensional photo-detector through an imaging lens 74. In order to improve the SN ratio of the signal, an iris 76 may be arranged.

The holographic recording medium according to one embodiment includes a specific polymeric matrix in the recording layer, which allows the holographic recording medium to exhibit a higher sensitivity compared with the conventional recording medium. It is also advantageous that difference in sensitivity from positions to positions can be lowered. In addition, the holographic recording medium has excellent storage stability.

For example, when the recording layer is composed of a polymeric matrix containing the repeating unit expressed by the general formula (1), an acid is generated from the photo-acid generator PAG upon irradiation with the recording light, and, as shown by the reaction formula (5A), a specific molecular group is dissociated from the main chain. In addition to the photo-radical polymerization initiator I and photo-acid generator PAG, a radically polymerizable monomer Ml is dispersed in the recording layer. The radically polymerizable monomer that had originally been dispersed in the recording layer is referred to as the first monomer.

Through the above-described dissociation of the molecular group, a new ethylenically unsaturated bond is formed within the molecular group containing M, and a new vinyl-M as a polymerizable monomer is generated (Case 1). The new vinyl-M can be expressed as (R⁶═C(R⁷)-M) or (R⁷═C(R⁶)-M), and is referred to as the second monomer.

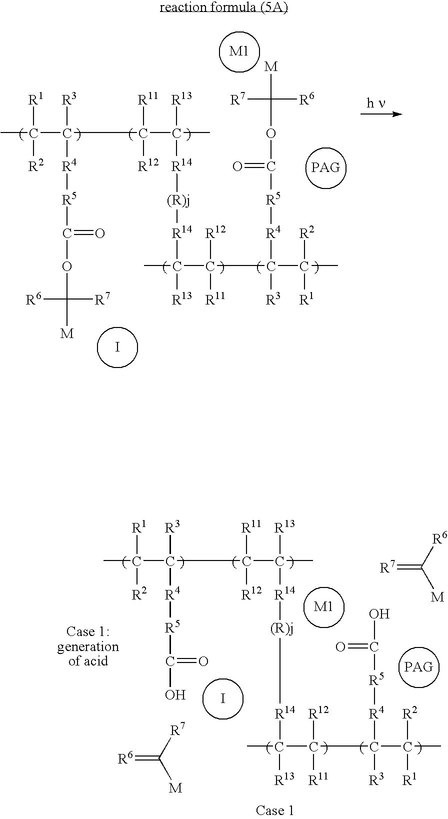

When the light irradiated over the recording layer is absorbed by the photo-radical polymerization initiator I, initiating radicals are generated from the photo-radical polymerization initiator. As a result of this, as expressed by the reaction formula (5B), the radically polymerizable monomer Ml that had originally been dispersed in the recording layer initiates polymerization (Case 2).

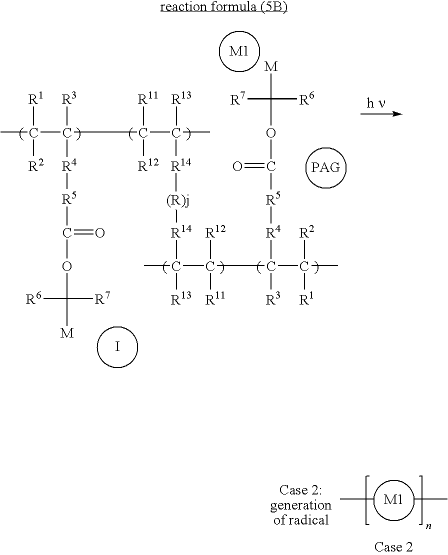

In many cases, the reactions of Case 1 and Case 2 are likely to occur simultaneously. Accordingly, in the recording layer irradiated with recording light, the reaction expressed by the reaction formula (5C) is likely to proceed (Case 3).

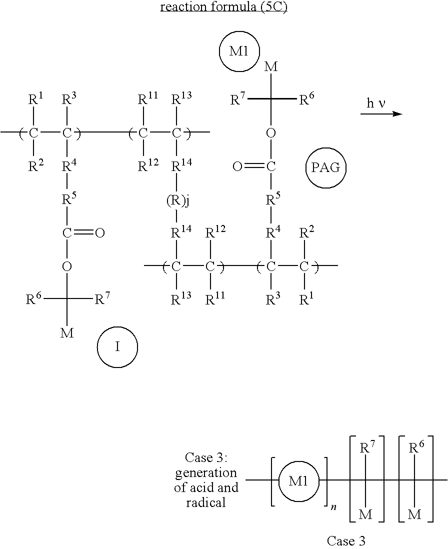

More specifically, when recording light beam is irradiated on to the recording layer containing a polymeric matrix composed of the repeating unit expressed by the general formula (1), a photo-radical polymerization initiator, a radically polymerizable monomer, and a photo-acid generator, the photo-radical polymerization initiator I initiates the polymerization of the radically polymerizable monomer which is referred to as the first monomer M1, as shown by Case 2. At the same time, acid is generated from the photo-acid generator PAG as shown by Case 1, and thus a vinyl-M as the second monomer is generated.

When the reaction, the reaction that occurs within the recording layer irradiated under recording light, is eliminated to Case 1, it undergoes a multiple steps including acid generation from the photo-acid generator, generation of the second monomer from the repeating unit expressed by the general formula (1), and polymerization of the second monomer. Therefore, deterioration in sensitivity (delay in time of reaction after irradiation of recording light) is inevitable. On the other hand, in the holographic recording medium according to one embodiment, the first monomer is preliminary dispersed within the polymeric matrix, therefore Case 2 simultaneously proceeds.

As shown in Case 2, the first monomer is polymerized immediately after the irradiation of the recording light on to the recording layer. The second monomer desorbed from the matrix and produced is fed into the recording layer thereafter, as shown in Case 1. In this manner, polymerization of the monomers is further promoted.

As for the case with a recording layer containing a polymeric matrix composed of the repeating unit expressed by the general formula (2), the reaction before and after the photoirradiation follows the same process as described above. More specifically, an acid is generated from the photo-acid generator PAG upon irradiation with the recording light, and, as shown in the reaction formula (6A), a specific molecular group is dissociated from the main chain. In the recording layer, a radically polymerizable monomer M1 is present in addition to the photo-radical polymerization initiator I and photo-acid generator PAG. The radically polymerizable monomer that had been dispersed preliminarily in the recording layer is referred to as the first monomer.

Through the above-described dissociation of the molecular group, a new ethylenically unsaturated bond is formed within the molecular group containing M, and a new vinyl-M as a polymerizable monomer is generated (Case 1). The new vinyl-M can be expressed as (R⁸═C(R⁹)-M) or (R⁹═C(R⁸)-M), and is referred to as the second monomer.

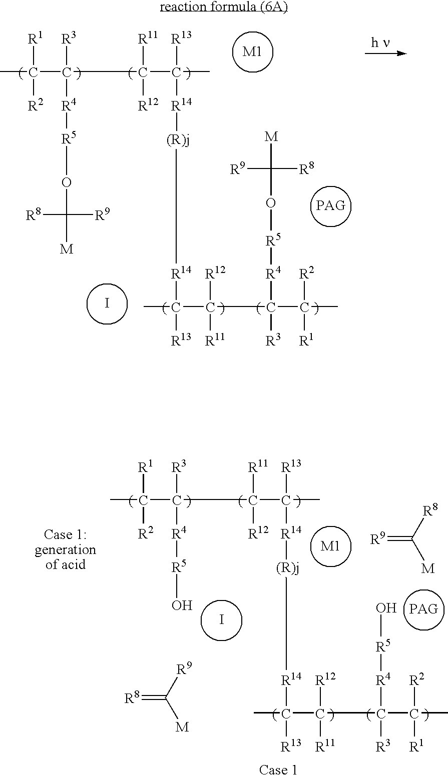

When the light irradiated on to the recording layer is absorbed by the photo-radical polymerization initiator I, initiating radicals are generated from the photo-radical polymerization initiator. As a result of this, as expressed by the reaction formula (6B), the radically polymerizable monomer M1 that had originally been dispersed in the recording layer initiates polymerization (Case 2).

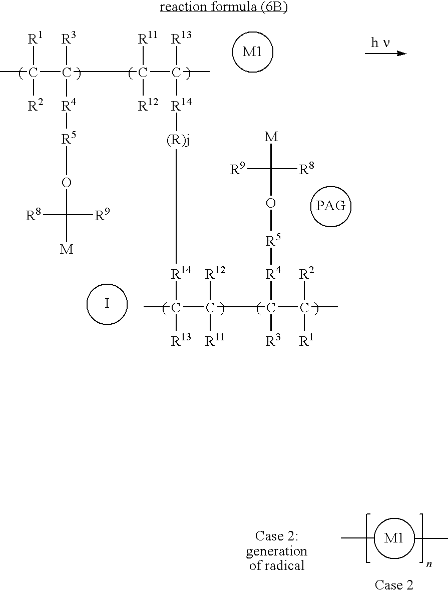

In many cases, the reactions of Case 1 and Case 2 are likely to occur simultaneously. Accordingly, in the recording layer irradiated with recording light beam, the reaction expressed by the reaction formula (6C) is likely to proceed (Case 3).

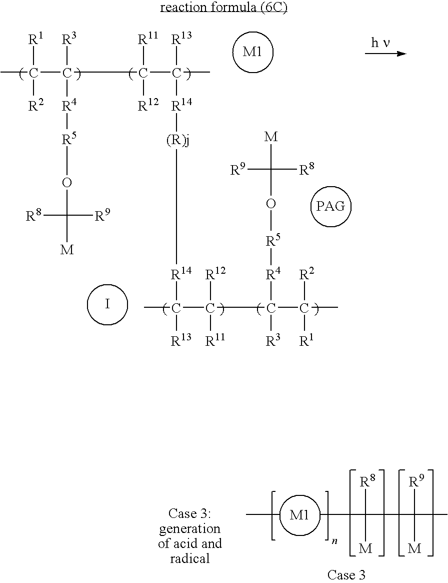

More specifically, when recording light beam is irradiated on to the recording layer containing a polymeric matrix composed of the repeating unit expressed by the general formula (2), a photo-radical polymerization initiator, a radically polymerizable monomer, and a photo-acid generator, the photo-radical polymerization initiator I initiates the polymerization of the radically polymerizable monomer which is referred to as the first monomer M1, as shown in Case 2. At the same time, acid is generated from the photo-acid generator PAG as shown in Case 1, and thus a vinyl-M as the second monomer is generated.

If the reaction that occurs within the recording layer was solely Case 1, after the irradiation of the recording light beam, deterioration in sensitivity is inevitable. Sensitivity here refers to the delay in time of reaction after irradiation of recording light beam. This is because the reaction in Case 1 follows multiple steps, including acid generation from the photo-acid generator, generation of the second monomer from the repeating unit expressed by the general formula (2), and polymerization of the second monomer. On the other hand, in the holographic recording medium according to one embodiment, the first monomer is preliminary dispersed within the polymeric matrix, so that Case 2 simultaneously proceeds.

As shown in Case 2, the first monomer immediately initiates to polymerize after irradiation of the recording layer with the recording light beam. The second monomer desorbed from the matrix and generated is then fed into the recording layer thereafter. In this manner, polymerization of the monomers is further promoted.

In the holographic recording medium known in the prior art, there contains, for example, N-vinylcarbazole, vinylnaphthalene, bromostyrene, chlorostyrene, tribromophenyl acrylate, trichlorophenyl acrylate, tribromophenyl methacrylate, and trichlorophenyl methacrylate in the recording layer. In such recording layer, the concentration of the polymerizable monomer that can be dispersed within the matrix cannot exceed the solubility of the polymerizable monomer in the matrix. If the amount of the polymerizable monomer dispersed in the matrix exceeds the solubility, the polymerizable monomer precipitates within the matrix, which results in an optically opaque holographic recording medium. Furthermore, the polymerizable monomer is unevenly dispersed within the matrix, which consequences in variation in the performance of the holographic recording medium from positions to positions.

As a matter of course, the solubility of the polymerizable monomer dispersed within the matrix decreases as it polymerizes. One must consider this fact when setting an irradiation program.

The holographic recording medium according to one embodiment includes a polymeric matrix composed of a polymer having, in the side chain thereof, a specific molecular group which can be dissociated by acid. In other words, the second polymerizable monomer is chemically bonded to an end of the side chain of the polymeric matrix in a dissociative manner. As a result of this, the polymerizable monomer is fixed within the matrix at a high density without precipitation in the recording layer. The second polymerizable monomer fixed within the matrix can be, as described above, dispersed and diffused within the matrix by exposure to photoirradiation.

Furthermore, because second polymerizable monomer is supplied from the matrix, the concentration of the polymerizable monomer is kept constant within the recording throughout the holographic recording process. The constant concentration of the polymerizable monomer within the matrix allows the polymerization reaction fo to proceed at a constant rate after exposure.

Accordingly, one need not to consider the monomer concentration that is dispersed in the matrix when setting the exposure program which allows more simple recording of a hologram.

Specific examples of the present invention are described below.

### EXAMPLE 1

Firstly, a slightly excessive amount of acryloyl chloride was dissolved and allowed to react with α-methyl-2-naphthalenemethanol in benzene under the presence of pyridine. After filtration and column chromatography, 1-(2′-naphthalene)ethyl acrylate expressed by the chemical formula (A-1) was obtained. The 1-(2′-naphthalene)ethyl acrylate corresponds to the monomer expressed by the general formula (1m). The reaction is expressed by the reaction formula below.

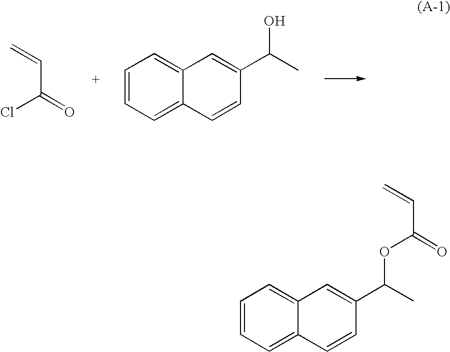

The 1-(2′-naphthalene)ethyl acrylate obtained was copolymerized with glycidyl methacrylate in benzene under nitrogenous atmosphere using azobisisobutyronitrile (AIBN). The glycidyl methacrylate corresponds to the monomer expressed by the general formula (3m). After the reaction for 1 hour, a polymeric matrix precursor 1 was obtained. The reaction is expressed by the reaction formula below.

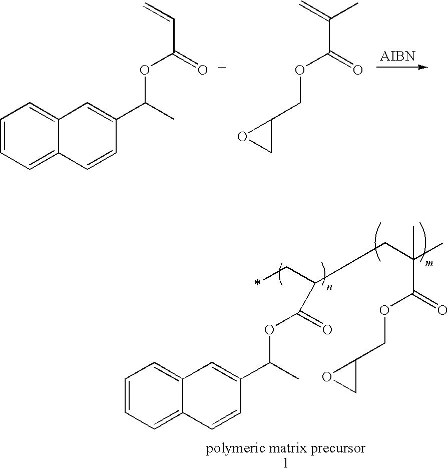

The polymeric matrix precursor 1, 2-vinylnaphthalene as a radically polymerizable monomer, IRGACURE-784 (CGI-784) as a photo-radical polymerization initiator, isopropyl thioxanthone as a photo-acid generator, and a 1:1 (weight ratio) mixture of aluminum tris(ethyl acetyl acetate) and triphenylsilanol as a curing catalyst were dissolved in 1,6-hexanediol diglycidyl ether to obtain a recording layer forming solution.

The amount of the radically polymerizable monomer was 10% by weight with reference to the recording layer forming solution. The amount of the photo-radical polymerization initiator was 0.3% by weight, and the amount of the photo-acid generator was 3% by weight with reference to the recording layer forming solution. The amount of the 1:1 mixture of aluminum tris(ethyl acetyl acetate) and triphenyl silanol was 10% by weight with reference to the recording layer forming solution.

The recording layer forming solution was poured into a gap formed by two glass substrates arranged with a PTFE sheet spacer therebetween. The assembly was heated at 60° C. to obtain a sample of a holographic recording medium having a recording layer of 200-μm in thickness. Through the steps described above, the transmission holographic recording medium having the structure shown in FIG. 1 was obtained.

The polymeric matrix was three-dimensionally crosslinked, and the whole recording layer was solid. The recording layer in the holographic recording medium of the present example is likely obtained as follows: a three-dimensionally crosslinked polymeric matrix was formed by the reaction expressed by the following reaction formula, and the radically polymerizable monomer, photo-radical polymerization initiator, and photo-acid generator were dispersed within the matrix.

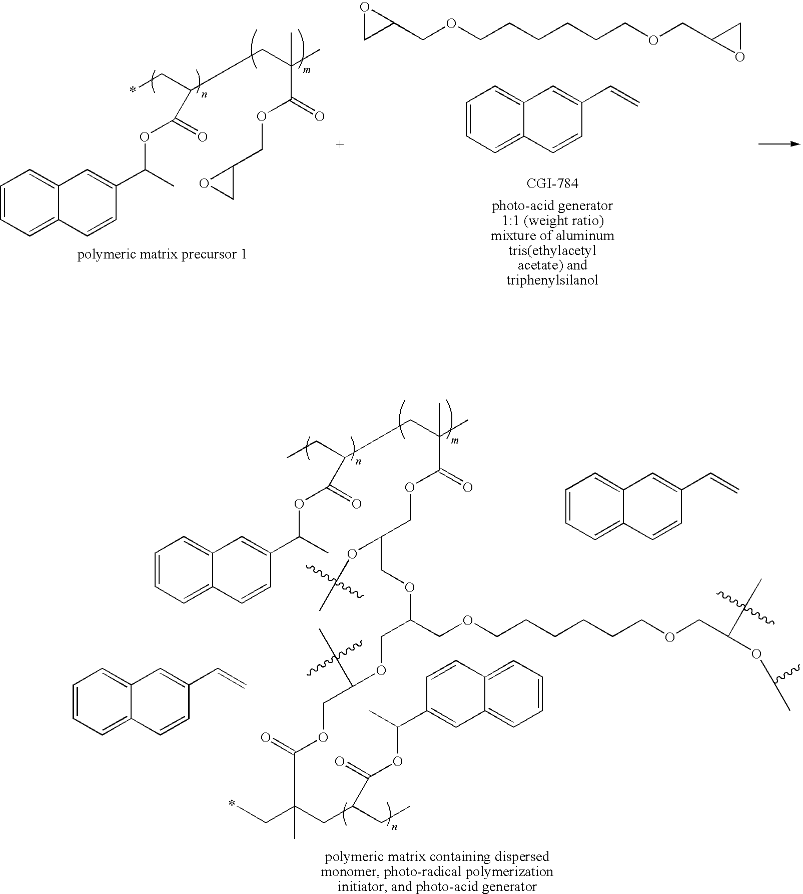

In the sample obtained, no precipitation of the monomer was visually observed in the recording layer. The transmittance of the recording layer was measured with the holographic recording apparatus shown in FIG. 3 and found to be 92%, and the transmittance did not deteriorate even after a lapse of one month.

The sample obtained was mounted on the rotating stage 20 of the holographic recording apparatus shown in FIG. 3, and holograms were recorded. The light source device 21 was a semiconductor laser having a wavelength of 405 nm. Holograms were recorded angularly multiplexed at multiple positions on the sample, and the sample was evaluated using the M/# (M number) expressing the recording dynamic range. M/# is defined by the following formula using ηᵢ. ηᵢ is the diffraction efficiency from the i-th hologram when n pages of holograms are recorded in one region within the recording layer of a holographic recording medium until recording is no longer possible. Holograms are recorded angularly multiplexed by irradiating the transmission holographic recording medium 10 with predetermined light beam with the rotating stage 20 driven.

In usual cases, when holograms are recorded angularly multiplexed, the irradiation energy increases as multiplexing recording proceeds. This is because the concentration of the polymerizable monomer contained in the recording layer decreases as multiplexing recording proceeds. For the sample of Comparative Example, angular multiplexing recording of holograms was performed with equal exposure periods from the first to the last page of the multiplexing recording.

$$M / \# = {\sum }_{i = 1}^{n} \sqrt{η} i \qquad Formula ( 1 )$$

The diffraction efficiency η is defined as the light intensity Iₜ, detected by the photo detector 31, and the light intensity I_{d}, detected by the photo detector 30, when the transmission holographic optical recording medium 10 is solely irradiated with the reference light beam Rf. More specifically, the diffraction efficiency is expressed by η=I_{d}/(Iₜ+I_{d}).

The higher the M/#, the larger the recording dynamic range and the better the multiplexing recording performance of the holographic recording medium.

In the present example, M/# was measured three times at multiple positions on the sample, and the value was 9.8±0.8. The smaller the difference between the values, the smaller the variation in the performance of the holographic recording medium. If the difference between the average of the three measurements and the highest value was below 10% of the average of the three measurements, the variation of the holographic recording medium is defined as small.

Using the holographic recording apparatus shown in FIG. 3, the diffraction efficiency of the last page was determined as 2.5%.

As described above, holograms were recorded angularly multiplexed under equal exposure. When the holographic recording media is sensitive enough, diffraction light can still be detected by the photo detector 30 when reconstructing. Conventional holographic recording medium lacks such sensitivity; therefore recording a hologram on the last angle of angular multiplexing method was impossible if the exposure intensities on each angle were equal. In the present example, it was confirmed that a hologram was recorded on the last page, which indicates that this holographic recording medium of the present example is highly sensitive. Accordingly, the holographic recording medium of the present example has high sensitivity and small variation in the sensitivity characteristics. In addition, the fact that the transmittance did not vary even after a month which indicates that the holographic recording medium has excellent storage stability.

More examples are given below, where the substituents in the general formulae (1) and (2) differ, and copolymers as the polymeric matrix precursors were synthesized. The polymeric matrix precursors obtained were used to fabricate the holographic recording media of Examples 2 to 18.

Firstly, according to the reaction formula shown below, the compounds expressed by the chemical formulae (A-2), (A-3), (A-4), (A-5), (A-6), (A-7), (A-8), and (A-9) were synthesized.

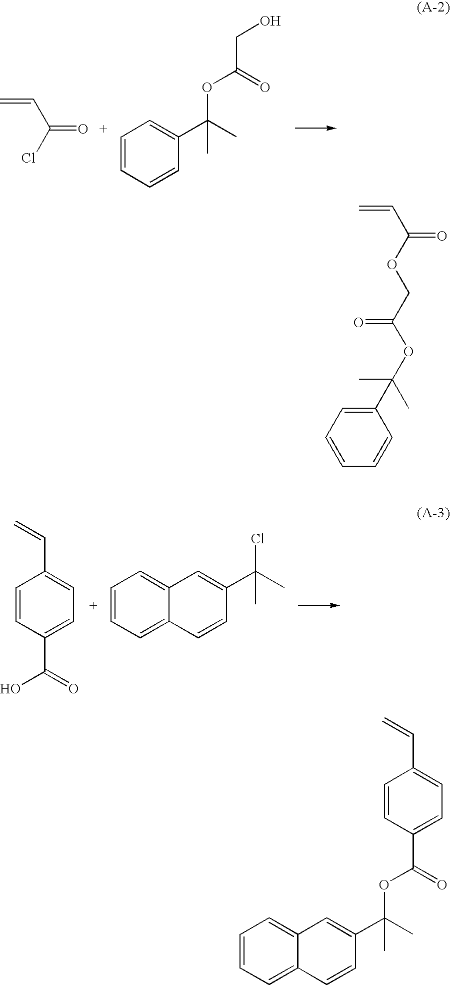

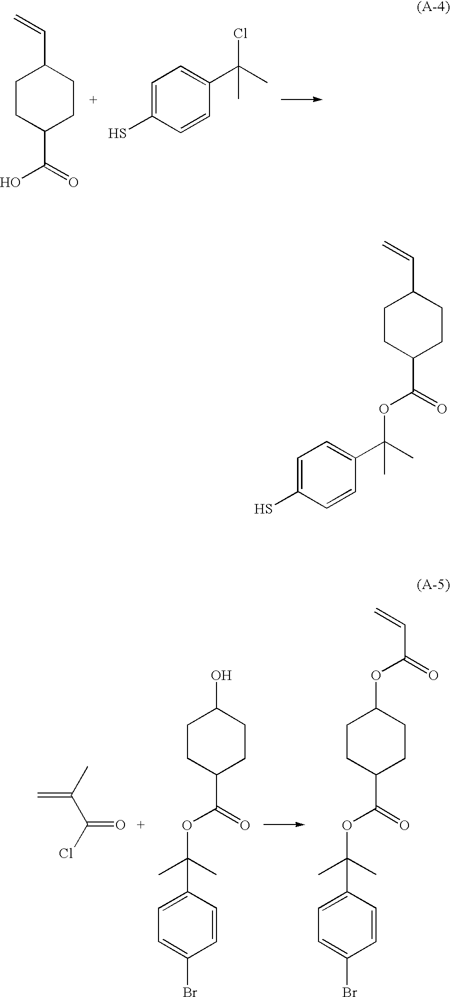

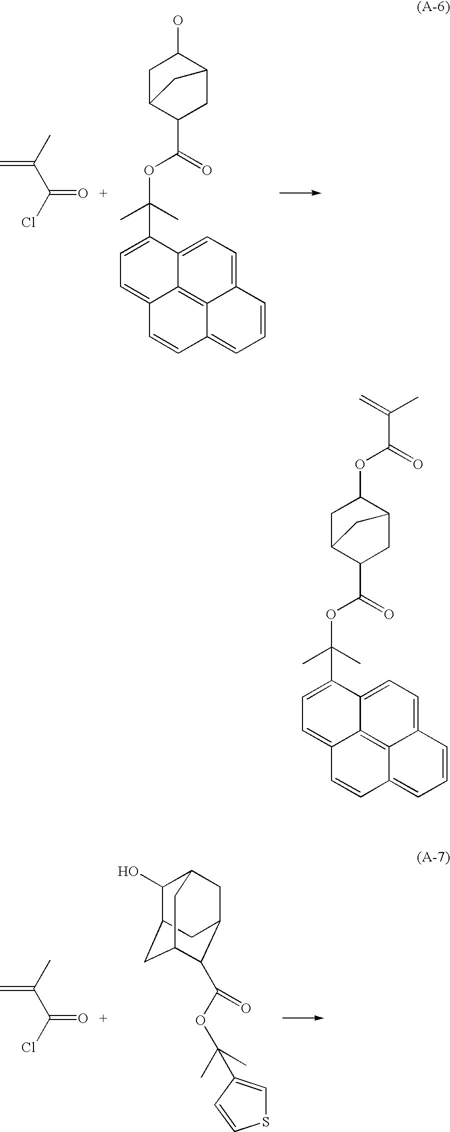

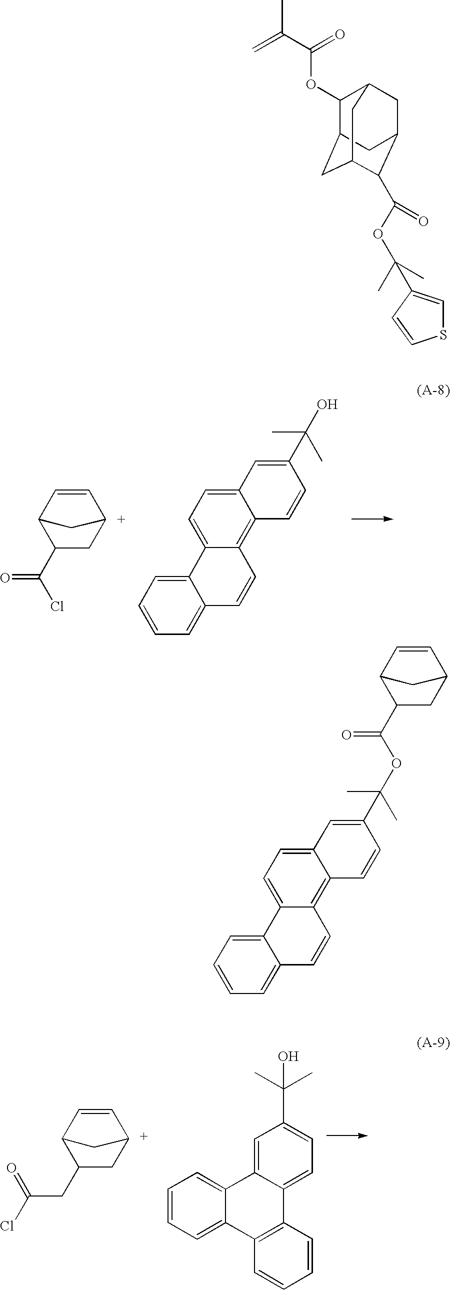

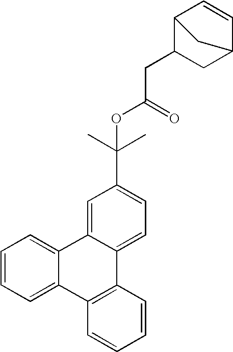

In addition, according to the reaction shown below, the compounds expressed by the chemical formulae (B-1), (B-2), (B-3), (B-4), (B-5), (B-6), (B-7), (B-8), and (B-9) were synthesized.

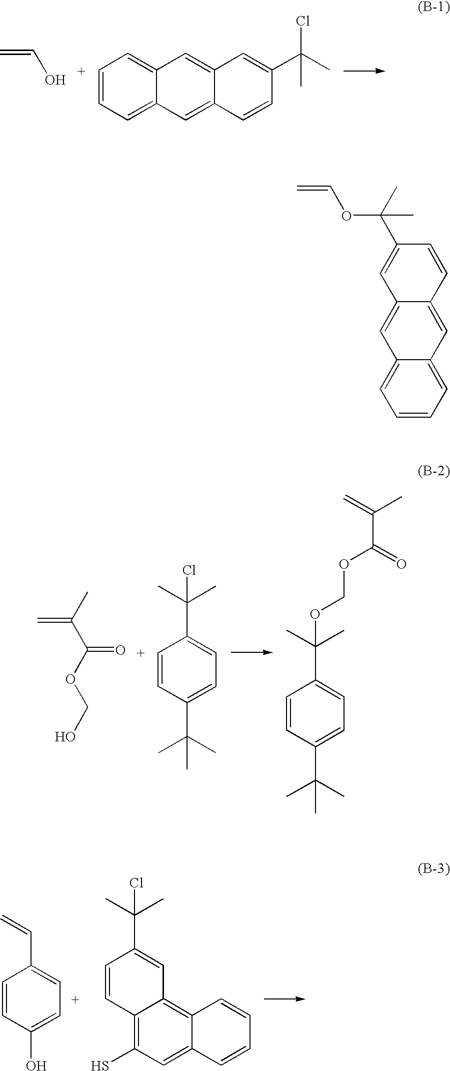

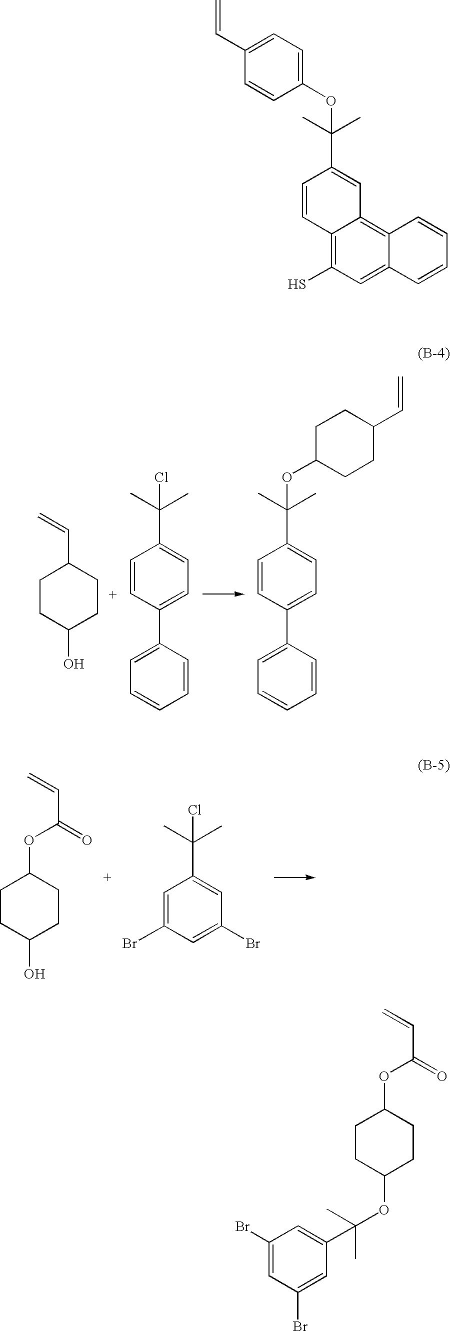

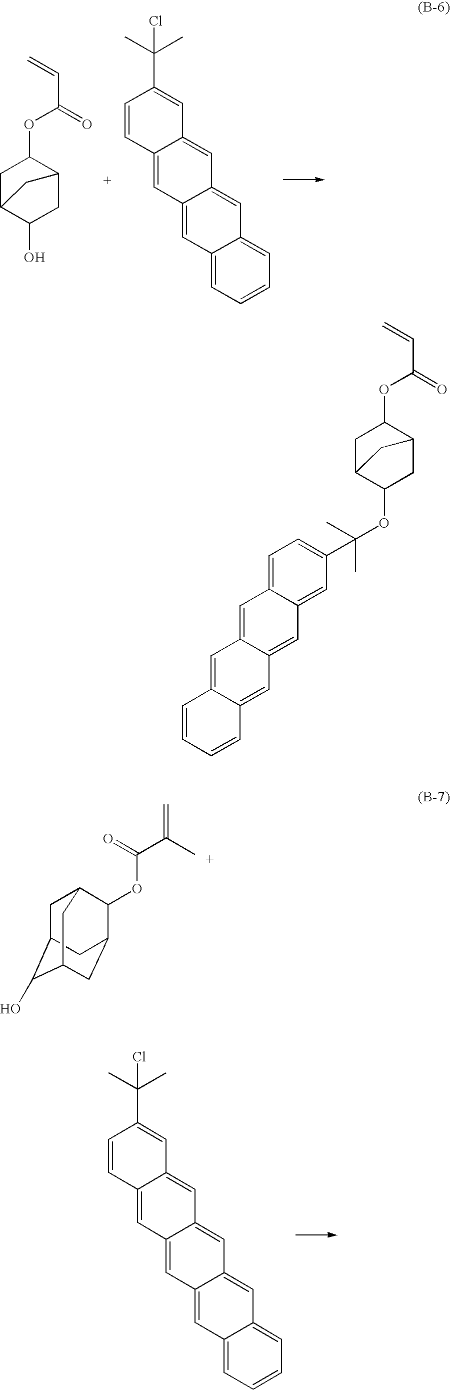

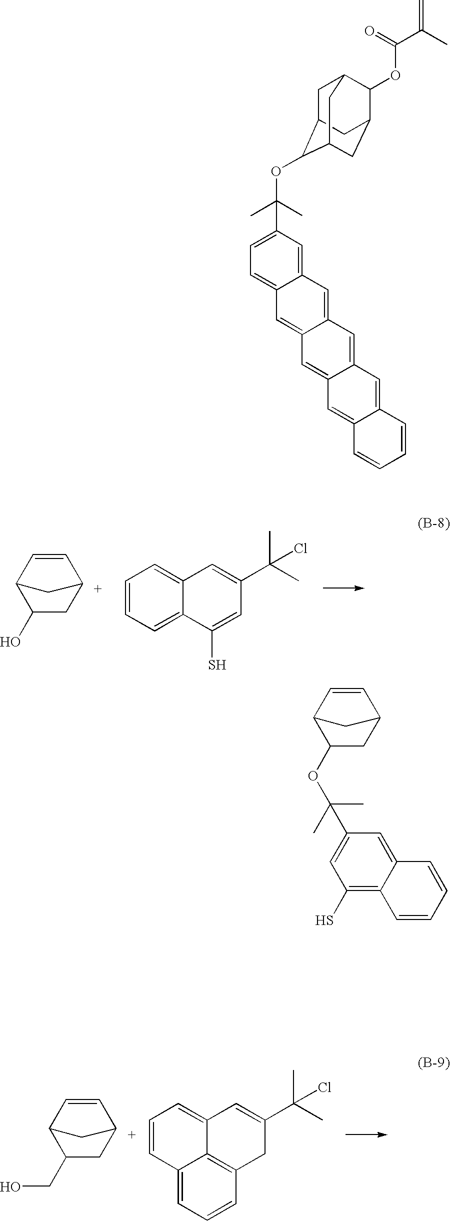

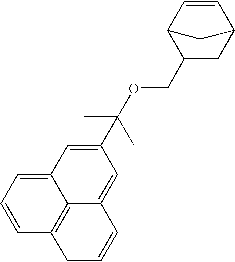

A copolymer as a polymeric matrix precursor was synthesized in the same manner as Example 1, except that the monomers expressed by the chemical formulae (A-2) to (A-9), and chemical formulae (B-1) to (B-9) were respectively used in place of the monomer expressed by the chemical formula (A-1). A recording layer forming solution was prepared in the same manner as described above, using the polymeric matrix precursor obtained.

Further, the samples of holographic recording media of Examples 2 to 18 were respectively fabricated in the same manner as Example 1, except that the obtained recording layer forming solution stated above was used instead. The recording layer of the holographic recording media of Examples 2 to 9 contains the polymeric matrix composed of the repeating unit expressed by the general formula (1). The recording layer of the holographic recording media of Examples 10 to 18 contains the polymeric matrix composed of the repeating unit expressed by the general formula (2).

The holographic recording media of the respective examples were evaluated in the same manner as described above. Specifically, holograms were recorded multiplexed three times, and the respective M/# were determined. Further, the diffraction efficiency of the last page was determined. In addition, the transmittance of the recording layer one month after the fabrication of the media was determined. The results obtained are summarized in Table 1.

### COMPARATIVE EXAMPLE 1

To 10 g of 1,6-hexanediol diglycidyl ether as a polymeric matrix precursor, an appropriate amount of a 1:1 (weight ratio) mixture of aluminum tris(ethyl acetyl acetate) and triphenylsilanol as a curing catalyst was added, to which 0.04 g of IRGACURE-784 (CGI-784) as a photo-radical polymerization initiator and 1 g of 2-vinylnaphthalene as a polymerizable monomer were added and dissolved therein, and thus a recording layer forming solution for the holographic recording medium of Comparative Example was prepared.

A multiple samples of the holographic recording medium of Comparative Example 1 were made in the same manner as Example 1, except that the obtained recording layer forming solution stated above was used instead. In the recording layer of the holographic recording medium of Comparative Example, the polymeric matrix does not contain the repeating unit expressed by the general formula (1) or (2).

Although the polymeric matrix was three-dimensionally crosslinked and the whole recording layer was made solid, precipitations were observed in the recording layer for all of the samples. A portion of the samples was chosen, and the glass substrate was removed to analyze the precipitate in the recording layer by use of NMR. As a result of this, the precipitate was found to be 2-vinylnaphthalene which was dispersed into the recording layer as a polymerizable monomer.

The transmittance of the recording layer was measured in the same manner as Example 1, and was found to be 31%. The light beam that had entered into the recording layer was evidently scattered within the recording layer, and the scattering source is likely to be the precipitated polymerizable monomer.

The samples were tested to multiplex recording, three times in the same manner as Example 1, and the respective M/# were determined. The values greatly varied according to the positions ranging within 5.1±4.0.

In usual cases, when holograms are recorded angularly multiplexed, the irradiation increases as multiplexing recording proceeds. This is because the concentration of the polymerizable monomer contained in the recording layer decreases as multiplexing recording proceeds. Angular multiplexing recording of holograms was performed with equal exposure periods from the first to the last page of the multiplexing recording.

The hologram obtained by angular multiplexing recording was reconstructed using the apparatus. A strong reconstructed light beam was obtained in the first half of the angular multiplex recording, but the intensity of the reconstructed light beam decreased as recording proceeds, and was hardly detected by the photo detector 30 at the final angle. No diffraction light was detected from the holographic recording medium of Comparative Example. This fact indicates that the diffraction efficiency of the last page was 0%, or not available (N.A.).

The results of Examples and Comparative Examples are summarized in Table 1 together with the monomers used.

TABLE 1

| | | Transmittance | | Diffraction |
|---|---|---|---|---|
| | | after one | | efficiency |
| | Monomer | month | M/# (—) | of last page |
| Comp. Ex. 1 | — | 31 | 5.1 ± 4.0 | N.A. |
| Example 1 | (A-1) | 92 | 9.8 ± 0.8 | 2.5 |
| Example 2 | (A-2) | 89 | 4.1 ± 0.4 | 0.5 |
| Example 3 | (A-3) | 83 | 9.2 ± 0.3 | 2.6 |
| Example 4 | (A-4) | 85 | 5.7 ± 0.2 | 0.8 |
| Example 5 | (A-5) | 93 | 8.1 ± 0.7 | 1.5 |
| Example 6 | (A-6) | 63 | 8.9 ± 0.6 | 2.4 |
| Example 7 | (A-7) | 94 | 7.2 ± 0.3 | 1.3 |
| Example 8 | (A-8) | 88 | 5.9 ± 0.7 | 0.8 |
| Example 9 | (A-9) | 91 | 3.8 ± 0.3 | 0.5 |
| Example 10 | (B-1) | 85 | 7.5 ± 0.3 | 1.6 |
| Example 11 | (B-2) | 92 | 3.7 ± 0.5 | 0.2 |
| Example 12 | (B-3) | 83 | 5.2 ± 0.3 | 0.7 |
| Example 13 | (B-4) | 79 | 8.6 ± 0.2 | 2.1 |
| Example 14 | (B-5) | 92 | 3.9 ± 0.3 | 0.5 |
| Example 15 | (B-6) | 77 | 4.7 ± 0.1 | 0.6 |
| Example 16 | (B-7) | 72 | 2.1 ± 0.1 | 0.2 |
| Example 17 | (B-8) | 84 | 5.3 ± 1.0 | 0.7 |
| Example 18 | (B-9) | 75 | 6.9 ± 0.3 | 1 |

The transmittance of the recording layer of 70% or more suggests the absence of precipitation of the monomer. Regarding the M/#, the difference between the average of three measurements and the highest measurement must be less than 10% of the arithmetic average of the three measurement values, and the diffraction efficiency of the last page is regarded as good if it is 0.1% or more. More specifically, when the diffraction efficiency of the last page is 0.1% or more, the sensitivity is high, and when the difference between the average of three measurement values and the highest measurement value is less than 10% of the arithmetic average of the three measurement values, the variation in sensitivity characteristics is small. In addition, the fact that the transmittance of the recording layer after a lapse of one month was 70% or more indicates that the recording layer has excellent storage stability.

As shown in Table 1, the recording layers of the holographic recording media of examples contain the polymeric matrix composed of the repeating unit expressed by the general formula (1) or (2), thus the recording layers exhibit high sensitivity and small variation in sensitivity characteristics. In addition, they exhibit good storage stability.

On the other hand, in the recording layer of the holographic recording medium of Comparative Example 1, the polymeric matrix does not contain the repeating unit expressed by the general formula (1) or (2), thus the recording medium exhibits low sensitivity and a wide variation in sensitivity characteristics. In addition, the result indicates the recording layer has poor storage stability.

According to the present invention, provided is a holographic recording medium which exhibits high sensitivity and small variation in its sensitivity characteristics, and has excellent storage stability.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A holographic recording medium comprising a recording layer comprising a radically polymerizable monomer having an ethylenically unsaturated bond, a photo-acid generator, a photo-radical polymerization initiator, and polymeric matrix, the polymeric matrix having a repeating unit expressed by the general formula (1) or (2); 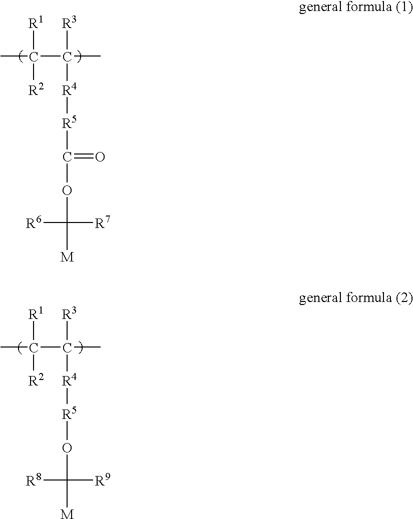
wherein R¹, R², and R³ each include a hydrogen atom or a hydrocarbon group having 10 or less carbon atoms,
R⁴ and R⁵ each include a single bond or a secondary hydrocarbon group having 20 or less carbon atoms,
R⁶ includes a hydrocarbon group having 10 or less carbon atoms, and R⁷ includes a hydrogen atom or a hydrocarbon group having 10 or less carbon atoms,
R⁸ and R⁹ each include a hydrocarbon group having 10 or less carbon atoms, and
M includes an aromatic group.

2. The medium according to claim 1, wherein M in the general formula is selected from the group consisting of benzene, naphthalene, anthracene, tetracene, pentacene, triphenyl, chrysene, phenanthrene, pyrene, thiophene, and phenalene.

3. The medium according to claim 1, wherein M in the general formula is naphthalene.

4. The medium according to claim 1, wherein R¹ in the general formula is selected from the group consisting of a hydrogen atom, a methyl group, an ethyl group, a propyl group, an isopropyl group, a butyl group, a sec-butyl group, a tert-butyl group, a cyclohexyl group, an adamantyl group, and a phenyl group.

5. The medium according to claim 1, wherein R² in the general formula is selected from the group consisting of a hydrogen atom, a methyl group, an ethyl group, a propyl group, an isopropyl group, a butyl group, a sec-butyl group, a tert-butyl group, a cyclohexyl group, an adamantyl group, and a phenyl group.

6. The medium according to claim 1, wherein R³ in the general formula is selected from the group consisting of a hydrogen atom, a methyl group, an ethyl group, a propyl group, an isopropyl group, a butyl group, a sec-butyl group, a tert-butyl group, a cyclohexyl group, an adamantyl group, and a phenyl group.

7. The medium according to claim 1, wherein R⁴ in the general formula is selected from the group consisting of a methylene group, an ethylene group, a propylene group, a butylene group, a pentamethylene group, a hexamethylene group, a heptamethylene group, an octamethylene group, a cyclohexylene group, an adamantylene group, and a phenylene group.

8. The medium according to claim 1, wherein R⁵ in the general formula is selected from the group consisting of a methylene group, an ethylene group, a propylene group, a butylene group, a pentamethylene group, a hexamethylene group, a heptamethylene group, an octamethylene group, a cyclohexylene group, an adamantylene group, and a phenylene group.

9. The medium according to claim 1, wherein R⁶ in the general formula is selected from the group consisting of a methyl group, an ethyl group, a propyl group, an isopropyl group, a butyl group, a sec-butyl group, a tert-butyl group, a cyclohexyl group, and a phenyl group.

10. The medium according to claim 1, wherein R⁷ in the general formula is selected from the group consisting of a hydrogen atom, a methyl group, an ethyl group, a propyl group, an isopropyl group, a butyl group, a sec-butyl group, a tert-butyl group, a cyclohexyl group, an adamantyl group, and a phenyl group.

11. The medium according to claim 1, wherein R⁸ in the general formula is selected from the group consisting of a methyl group, an ethyl group, a propyl group, an isopropyl group, a butyl group, a sec-butyl group, a tert-butyl group, a cyclohexyl group, and a phenyl group.

12. The medium according to claim 1, wherein R⁹ in the general formula is selected from the group consisting of a methyl group, an ethyl group, a propyl group, an isopropyl group, a butyl group, a sec-butyl group, a tert-butyl group, a cyclohexyl group, and a phenyl group.

13. A holographic recording medium comprising a recording layer comprising a radically polymerizable monomer having an ethylenically unsaturated bond, a photo-acid generator, a photo-radical polymerization initiator, and polymeric matrix, the radically polymerizable monomer being selected from the group consisting of unsaturated carboxylic acid, unsaturated carboxylic acid ester, unsaturated carboxylic acid amide, and vinyl compounds, the polymeric matrix having a repeating unit expressed by the general formula (1) or (2); 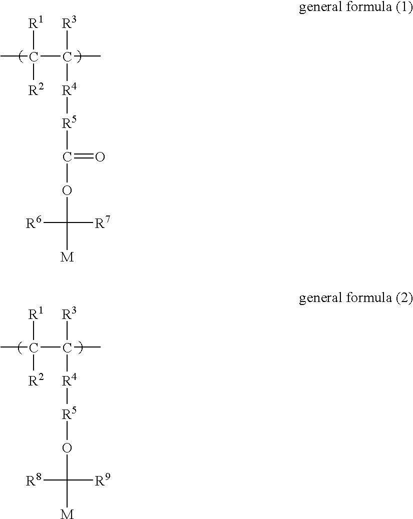
wherein R¹, R², and R³ each include a hydrogen atom or a hydrocarbon group having 10 or less carbon atoms,
R⁴ and R⁵ each include a single bond or a secondary hydrocarbon group having 20 or less carbon atoms,
R⁶ includes a hydrocarbon group having 10 or less carbon atoms, and R⁷ includes a hydrogen atom or a hydrocarbon group having 10 or less carbon atoms,
R⁸ and R⁹ each include a hydrocarbon group having 10 or less carbon atoms, and,
M includes an aromatic group.

14. The medium according to claim 13, wherein the radically polymerizable monomer is selected from the group consisting of N-vinylcarbazole, vinylnaphthalene, bromostyrene, chlorostyrene, tribromophenyl acrylate, trichlorophenyl acrylate, tribromophenyl methacrylate, and trichlorophenyl methacrylate.

15. The medium according to claim 13, wherein M in the general formula is naphthalene.

16. The medium according to claim 13, further comprising:
a photo-acid generator selected from the group consisting of aryl onium salts, naphthoquinone diazide compounds, diazonium salts, sulfonate compounds, sulfonium compounds, sulfamide compounds, iodonium compounds, and sulfonyldiazomethane compounds.

17. The medium according to claim 13, wherein the photo-radical polymerization initiator is selected from the group consisting of benzoin ether, benzyl ketal, benzyl, acetophenone derivatives, aminoacetophenones, benzophenone derivatives, acylphosphine oxides, triazines, imidazole derivatives, organic azido compounds, titanocenes, organic peroxides, and thioxanthone derivatives.

18. A holographic recording medium comprising a recording layer comprising a radically polymerizable monomer having an ethylenically unsaturated bond, a photo-acid generator, a photo-radical polymerization initiator, and a three-dimensionally crosslinked polymeric matrix, the polymeric matrix having a repeating unit expressed by the general formula (3) and at least one of a repeating unit expressed by the general formula (1) and a repeating unit expressed by the general formula (2); 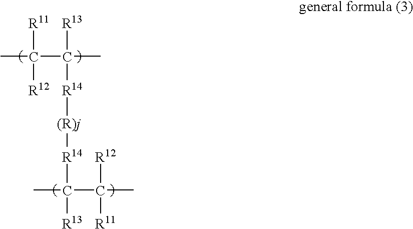
wherein R¹¹, R¹², and R¹³ may be the same or different from each other, and each include a hydrogen atom or a hydrocarbon group having 10 or less carbon atoms; R includes a crosslinking agent containing a crosslinking group, and j represent 0 or 1, 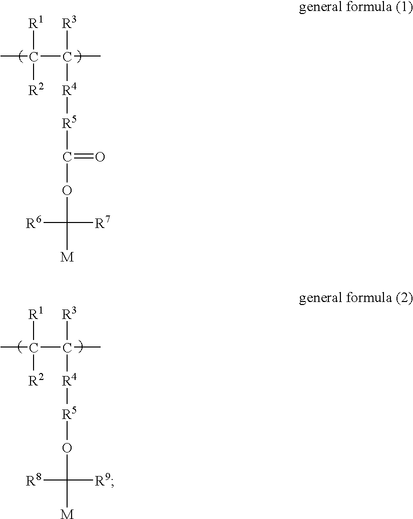
wherein R¹, R², and R³ each include a hydrogen atom or a hydrocarbon group having 10 or less carbon atoms,
R⁴ and R⁵ each include a single bond or a secondary hydrocarbon group having 20 or less carbon atoms,
R⁶ includes a hydrocarbon group having 10 or less carbon atoms, and R⁷ includes a hydrogen atom or a hydrocarbon group having 10 or less carbon atoms,
R⁸ and R⁹ each include a hydrocarbon group having 10 or less carbon atoms, and
M includes an aromatic.

19. The medium according to claim 18, wherein the three-dimensionally crosslinked polymeric matrix is expressed by the general formula (MT1).

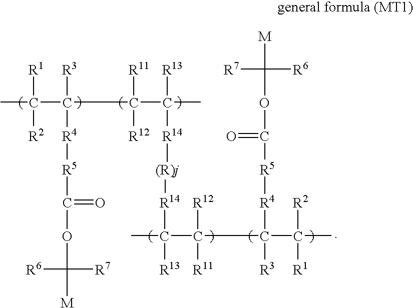

20. The medium according to claim 18, wherein the three-dimensionally crosslinked polymeric matrix is expressed by the general formula (MT2). [chemical structure]
